(19) United States
(12) Patent Application Publication
(10) Pub. No.: US 2026/0090231 A1
(43) Pub. Date: Mar. 26, 2026

(54) DISPLAY DEVICE AND ELECTRONIC APPARATUS

(71) Applicant: Sony Semiconductor Solutions Corporation, Kanagawa (JP)

(72) Inventors: Shoji Sudo, Tokyo (JP); Daichi IMABAYASHI, Kanagawa (JP)

(21) Appl. No.: 18/844,700

(22) PCT Filed: Mar. 23, 2023
(86) PCT No.: PCT/JP2023/011545

§ 371 Date: Apr. 25, 2025

(30) Foreign Application Priority Data
Apr. 4, 2022 (JP) 2022-062616

(51) Int. Cl. H10K 59/70; H10K 59/35

(52) U.S. Cl. CPC H10K 59/70; H10K 59/353

(57) ABSTRACT

Provided is a display device capable of suppressing a decrease in light emission luminance.

The display device includes a plurality of inorganic light emitting diodes arranged two-dimensionally and a plurality of organic light emitting diodes arranged two-dimensionally. At least one of the organic light emitting diodes is provided on an upper portion of or above at least one of the inorganic light emitting diodes or on a lower portion of or below at least one of the inorganic light emitting diodes.

### TECHNICAL FIELD

The present disclosure relates to a display device and an electronic apparatus including the display device.

### BACKGROUND ART

A display device in which a plurality of light emitting diode (LED) elements is two-dimensionally arranged on a substrate has widely been known. Patent Literature 1 discloses an integrated multicolor micro LED display chip in which an inorganic LED and an organic LED are integrated in a single chip.

### CITATION LIST

### Patent Document

Patent Document 1: WO 2018/191551 A

### SUMMARY OF THE INVENTION

### Problems to be Solved by the Invention

In a display device in which a plurality of LEDs is two-dimensionally arranged on a substrate, light emission luminance may be reduced.

An object of the present disclosure is to provide a display device capable of suppressing a decrease in light emission luminance and an electronic apparatus including the display device.

### Solutions to Problems

In order to solve the above problem, a first display device according to the present disclosure includes:
a plurality of inorganic light emitting diodes arranged two-dimensionally; and
a plurality of organic light emitting diodes arranged two-dimensionally, in which
at least one of the organic light emitting diodes is provided on an upper portion of or above at least one of the inorganic light emitting diodes or on a lower portion of or below at least one of the inorganic light emitting diodes.

A second display device according to the present disclosure includes:
a plurality of first light emitting diodes arranged two-dimensionally; and
a plurality of second light emitting diodes arranged two-dimensionally, in which
the plurality of first light emitting diodes includes a plurality of inorganic light emitting diodes,
the plurality of second light emitting diodes include at least one type of a plurality of organic light emitting diodes, a plurality of quantum dot light emitting diodes, and a plurality of perovskite light emitting diodes, and
at least one of the second light emitting diodes is provided on an upper portion of or above at least one of the first light emitting diodes, or on a lower portion of or below at least one of the first light emitting diodes.

A third display device according to the present disclosure includes:
a plurality of first light emitting diodes arranged two-dimensionally;
a plurality of second light emitting diodes arranged two-dimensionally; and
a plurality of third light emitting diodes arranged two-dimensionally, in which
the second light emitting diodes are provided on an upper portion of or above the first light emitting diodes,
the third light emitting diodes are provided on an upper portion of or above the second light emitting diodes, and
at least one kind of light emitting diodes among three kinds of light emitting diodes including the first light emitting diodes, the second light emitting diodes, and the third light emitting diodes are inorganic light emitting diodes, and the remaining light emitting diodes among the three kinds of light emitting diodes are at least one kind of organic light emitting diodes, quantum dot light emitting diodes, and perovskite light emitting diodes.

An electronic apparatus according to the present disclosure includes the first display device, the second display device, or the third display device according to the present disclosure.

### BRIEF DESCRIPTION OF DRAWINGS

FIG. 1 is a plan view illustrating an example of a configuration of a display device according to a first embodiment.

FIG. 2 is an enlarged plan view illustrating a part of a display region of the display device according to the first embodiment.

FIG. 3 is a sectional view taken along line III-III of FIG. 2.

FIG. 4 is a cross-sectional view illustrating one example of a configuration of a display device according to a modification of the first embodiment.

FIG. 5 is a cross-sectional view illustrating another example of the configuration of the display device according to the modification of the first embodiment.

FIG. 6 is a cross-sectional view illustrating an example of a configuration of a display device according to a second embodiment.

FIG. 7 is a cross-sectional view illustrating one example of a configuration of a display device according to a modification of the second embodiment.

FIG. 8 is a cross-sectional view illustrating another example of the configuration of the display device according to the modification of the second embodiment.

FIG. 9 is a cross-sectional view illustrating an example of a configuration of a display device according to a third embodiment.

FIG. 10 is a cross-sectional view illustrating an example of a configuration of a display device according to a modification of the third embodiment.

FIG. 11 is a cross-sectional view illustrating an example of a configuration of a display device according to a fourth embodiment.

FIG. 12 is a cross-sectional view illustrating an example of a configuration of a display device according to a modification of the fourth embodiment.

FIG. 13 is a cross-sectional view illustrating an example of a configuration of a display device according to a fifth embodiment.

FIG. 14 is a cross-sectional view illustrating an example of a configuration of a display device according to a modification of the fifth embodiment.

FIG. 15 is a cross-sectional view illustrating an example of a configuration of a display device according to a modification of the fifth embodiment.

FIG. 16 is a cross-sectional view illustrating an example of a configuration of a display device according to a sixth embodiment.

FIG. 17 is a cross-sectional view illustrating one example of a configuration of a display device according to a modification of the sixth embodiment.

FIG. 18 is a cross-sectional view illustrating another example of the configuration of the display device according to the modification of the sixth embodiment.

FIG. 19 is a cross-sectional view illustrating an example of a configuration of a display device according to a seventh embodiment.

FIG. 20 is a cross-sectional view illustrating an example of a configuration of a display device according to a modification of the seventh embodiment.

FIG. 21 is a cross-sectional view illustrating an example of a configuration of a display device according to an eighth embodiment.

FIG. 22 is a cross-sectional view illustrating an example of a configuration of a display device according to a modification of the eighth embodiment.

FIG. 23 is an enlarged plan view illustrating a part of a display region of a display device according to a ninth embodiment.

FIG. 24 is a cross-sectional view taken along line XXIV-XXIV of FIG. 23.

FIG. 25 is a cross-sectional view illustrating one example of a configuration of a display device according to a modification of the ninth embodiment.

FIG. 26 is a cross-sectional view illustrating another example of a configuration of a display device according to a modification of the ninth embodiment.

FIG. 27 is a cross-sectional view illustrating an example of a configuration of a display device according to a 10th embodiment.

FIG. 28 is a cross-sectional view illustrating one example of a configuration of a display device according to a modification of the 10th embodiment.

FIG. 29 is a cross-sectional view illustrating another example of a configuration of a display device according to a modification of the 10th embodiment.

FIG. 30 is a cross-sectional view illustrating an example of a configuration of a display device according to an 11th embodiment.

FIG. 31 is a cross-sectional view illustrating an example of a configuration of a display device according to a modification of the 11th embodiment.

FIG. 32 is a cross-sectional view illustrating an example of a configuration of a display device according to a 12th embodiment.

FIG. 33 is a cross-sectional view illustrating an example of a configuration of a display device according to a modification of the 12th embodiment.

FIG. 34 is an enlarged plan view illustrating a part of a display region of a display device according to a 13th embodiment.

FIG. 35 is a cross-sectional view taken along line XXXV-XXXV of FIG. 34.

FIG. 36 is a cross-sectional view illustrating an example of a configuration of a display device according to a modification of the 13th embodiment.

FIG. 37 is a cross-sectional view illustrating an example of a configuration of a display device according to a 14th embodiment.

FIGS. 38A, 38B, and 38C are conceptual diagrams illustrating a relationship among a normal line LN passing through a center of a light emitting unit, a normal line LN′ passing through a center of a lens member, and a normal line LN″ passing through a center of a wavelength selection unit, respectively.

FIG. 39 is a conceptual diagram illustrating a relationship among the normal line LN passing through the center of the light emitting unit, the normal line LN′ passing through the center of the lens member, and the normal line LN″ passing through the center of the wavelength selection unit.

FIGS. 40A and 40B are conceptual diagrams illustrating a relationship among the normal line LN passing through the center of the light emitting unit, the normal line LN′ passing through the center of the lens member, and the normal line LN″ passing through the center of the wavelength selection unit, respectively.

FIG. 41 is a conceptual diagram illustrating a relationship among the normal line LN passing through the center of the light emitting unit, the normal line LN′ passing through the center of the lens member, and the normal line LN″ passing through the center of the wavelength selection unit.

FIG. 42A is a front view illustrating an example of an external appearance of a digital still camera. FIG. 42B is a rear view illustrating an example of an external appearance of the digital still camera.

FIG. 43 is a perspective view illustrating an example of an external appearance of a head-mounted display.

FIG. 44 is a perspective view illustrating an example of an external appearance of a television device.

FIG. 45 is a perspective view illustrating an example of an external appearance of a see-through head-mounted display.

FIG. 46 is a perspective view illustrating an example of an external appearance of a smartphone.

FIG. 47A is a view illustrating an example of an internal state of a vehicle from a rear side to a front side of the vehicle. FIG. 47B is a diagram illustrating an example of an internal state of the vehicle from an oblique rear to an oblique front of the vehicle.

FIG. 48 is a plan view illustrating an example of arrangement of inorganic layers of an inorganic LED and organic layers of an organic LED.

FIG. 49 is a plan view illustrating an example of arrangement of filter units.

FIG. 50 is an enlarged plan view illustrating a part of a display region of a display device according to a 15th embodiment.

FIG. 51 is a cross-sectional view taken along line LI-LI in FIG. 50.

FIG. 52 is a plan view illustrating a process of forming the organic layer of the organic LED.

FIG. 53 is a plan view illustrating a process of forming the organic layer of the organic LED.

FIG. 54 is a plan view illustrating an example of a configuration of a display device according to a modification of the 15th embodiment.

FIG. 55 is a plan view illustrating a process of forming the organic layer of the organic LED.

FIG. 56 is a plan view illustrating an example of a configuration of a display device according to a modification of the 15th embodiment.

FIG. 57 is a plan view illustrating a process of forming the organic layer of the organic LED.

FIG. 58 is an enlarged plan view illustrating a part of a display region of a display device according to a 16th embodiment.

FIG. 59 is a cross-sectional view taken along line LIX-LIX of FIG. 58.

FIG. 60 is a cross-sectional view illustrating a resonance effect of the display device according to the first embodiment.

FIG. 61 is a cross-sectional view illustrating an example of a configuration of a display device according to a 17th embodiment.

FIG. 62 is a cross-sectional view illustrating a resonance effect of the display device according to the 17th embodiment.

FIG. 63 is a cross-sectional view illustrating one example of a configuration of a display device according to a modification of the 17th embodiment.

FIG. 64 is a cross-sectional view illustrating another example of the configuration of the display device according to the modification of the 17th embodiment.

FIG. 65 is a graph illustrating a calculation result of transmittance by Simulations 1 to 5.

FIG. 66 is a graph illustrating a calculation result of reflectance by Simulations 1 to 5.

FIG. 67 is a cross-sectional view illustrating a waveguide mode of the display device according to the first embodiment.

FIG. 68 is a cross-sectional view illustrating an example of a configuration of a display device according to a 18th embodiment.

FIG. 69 is a plan view illustrating an example of a configuration of a wall portion.

FIG. 70 is a cross-sectional view illustrating one example of a configuration of a display device according to a modification of the 18th embodiment.

FIG. 71 is a plan view illustrating an example of a configuration of a wall portion.

FIG. 72 is a cross-sectional view illustrating another example of the configuration of the display device according to the modification of the 18th embodiment.

FIG. 73 is a cross-sectional view illustrating still another example of the configuration of the display device according to the modification of the 18th embodiment.

FIG. 74 is a cross-sectional view illustrating yet still another example of the configuration of the display device according to the modification of the 18th embodiment.

FIG. 75 is a cross-sectional view illustrating a further example of the configuration of the display device according to the modification of the 18th embodiment.

FIG. 76 is a cross-sectional view illustrating an example of a configuration of a display device according to a 19th embodiment.

FIG. 77 is a cross-sectional view illustrating one example of a configuration of a display device according to a modification of the 19th embodiment.

FIG. 78 is a cross-sectional view illustrating another example of the configuration of the display device according to the modification of the 19th embodiment.

FIG. 79 is a cross-sectional view illustrating an example of a configuration of a display device according to a 20th embodiment.

### MODE FOR CARRYING OUT THE INVENTION

A first display device according to the present disclosure includes a plurality of two-dimensionally arranged inorganic LEDs and a plurality of two-dimensionally arranged organic LEDs, and at least one organic LED is provided on an upper portion of or above at least one inorganic LED or on a lower portion of or below at least one inorganic LED.

Here, the configuration in which the at least one organic LED is provided on the at least one inorganic LED also includes a configuration in which the at least one inorganic LED and the at least one organic LED provided thereon share a first electrode or a second electrode. The configuration in which the at least one organic LED is provided on the lower portion of at least one inorganic LED also includes a configuration in which at least one organic LED and at least one inorganic LED provided on the lower portion of at least one organic LED share the first electrode or the second electrode. The first electrode may be an anode and the second electrode may be a cathode.

A light emission color of the inorganic LED may be, for example, red, blue, green, or yellow. The light emission color of the organic LED may be, for example, red, blue, green, or yellow. Light that can be emitted by the inorganic LED and the organic LED is not limited to visible light, and for example, the LEDs may be capable of emitting infrared rays, ultraviolet rays, or the like.

The light emission colors of the inorganic LED and the organic LED may be different. For example, the emission light of the inorganic LED may be blue light, and the light emission color of the organic LED may be green light or red light. The emission light of the inorganic LED may be blue light and green light, and the light emission color of the organic LED may be red light.

The luminous efficiency of the inorganic LED varies depending on a light emission wavelength peak of the inorganic LED, and the inorganic LED having a shorter light emission wavelength has a higher luminous efficiency. On the other hand, a lifetime of the organic LED varies depending on the emission wavelength peak of the organic LED, and the organic LED having a longer emission wavelength peak has a longer drive lifetime. In consideration of the above viewpoints, a peak wavelength of the emission light of the inorganic LED is preferably shorter than a peak wavelength of the emission light of the organic LED.

At least two organic LEDs may be provided on an upper portion of or above one inorganic LED or on a lower portion of or below one inorganic LED. For example, a first organic LED capable of emitting red light and a second organic LED capable of emitting green light may be provided on an upper portion of or above an inorganic LED capable of emitting blue light, or on a lower portion of or below one inorganic LED.

The first display device may further include a color conversion layer. The color conversion layer may be a color filter, a dielectric multilayer film structure, or a quantum dot layer, or two or more kinds thereof may be combined. The color conversion layer can perform color conversion on light emitted from the plurality of organic LEDs, and can transmit light emitted from the plurality of inorganic light emitting diodes without color conversion. For example, the color conversion layer may be capable of performing color conversion on yellow light emitted from the plurality of organic LEDs into red light and green light, and may be capable of transmitting blue light emitted from the plurality of inorganic light emitting diodes without color conversion.

The plurality of organic LEDs may include a plurality of first organic LEDs and a plurality of second organic LEDs, one first organic LED and one second organic LED may be provided on an upper portion of or above the one inorganic LED or on a lower portion of or below the inorganic LED, and light emission colors of the first organic LED, the second organic LED and the inorganic LED may be different. For example, the light emission color of the first organic LED may be red, the light emission color of the second organic LED may be green, and the light emission color of the inorganic LED may be blue. The light emission color of the first organic LED and the second organic LED may be yellow, and the light emission color of the inorganic LED may be blue.

The color conversion layer may include a plurality of first color conversion units and a plurality of second color conversion units, the first color conversion unit may perform color conversion on light emitted from the first organic LED, and the second color conversion unit may perform color conversion on light emitted from the second organic LED. For example, the first color conversion unit may be a magenta filter unit, and may perform color conversion on yellow light emitted from the first organic LED into red light, and the second color conversion unit may be a cyan filter unit, and may perform color conversion on yellow light emitted from the second organic LED into green light.

The color conversion layer may perform color conversion on light emitted from a plurality of organic LEDs, and the plurality of organic LEDs may share an organic layer including a light emitting layer. The organic layer shared by the plurality of organic LEDs may be capable of emitting yellow light.

The inorganic LED may emit a first light having a first peak wavelength and a second light having a second peak wavelength, and the organic LED may emit a third light having a third peak wavelength. The inorganic LED may include a first light emitting layer capable of emitting a first light having a first peak wavelength and a second light emitting layer capable of emitting a second light having a second peak wavelength. The first peak wavelength and the second peak wavelength may be shorter than the third peak wavelength. The first light may be blue light, the second light may be green light, and the third light may be red light.

The at least two inorganic LEDs may be provided on an upper portion of or above the one organic LED, or on a lower portion of or below the one organic LED. In this case, the at least two inorganic LEDs may share one first electrode or one second electrode. The first display device may further include a color conversion layer, and the color conversion layer may perform color conversion on the first light and the second light emitted from the plurality of inorganic LEDs, and may transmit the light emitted from the plurality of organic LEDs without color conversion.

The plurality of organic LEDs may share one first electrode or one second electrode. The plurality of inorganic LEDs may share one first electrode or one second electrode. The organic LED and the inorganic LED may share one first electrode or one second electrode. The first electrode may be an anode and the second electrode may be a cathode.

The first display device may further include a first reflection layer. The first reflection layer may be provided between at least one inorganic light emitting diode and at least one organic light emitting diode. The first reflection layer may include a dielectric multilayer film, a metal layer, or a laminate thereof.

The first display device may further include a second reflection layer. The second reflection layer may be provided on an upper portion of or above the light emitting diode provided on the upper side of the organic light emitting diode and the inorganic light emitting diode. The second reflection layer may include a dielectric multilayer film, a metal layer, or a laminate thereof.

The reflectance of each of the first and second reflection layers at at least one of the peak wavelength of the inorganic light emitting diode and the peak wavelength of the organic light emitting diode may be independently 50% or more, 60% or more, 70% or more, 80% or more, or 90% or more. The transmittances of the first and second reflection layers at the peak wavelength of at least one of the peak wavelength of the inorganic light emitting diode and the peak wavelength of the organic light emitting diode may be each independently 50% or more, 60% or more, 70% or more, 80% or more, or 90% or more.

The light emission colors of at least one organic light emitting diode and at least one inorganic light emitting diode may be different. In this case, the reflectance of each of the first and second reflection layers at the spectral peak of light of at least one color among different light emission colors may be independently 50% or more, 60% or more, 70% or more, 80% or more, or 90% or more. The transmittances of the first and second reflection layers at the spectral peaks of light of at least one of the different light emission colors may each independently be 50% or more, 60% or more, 70% or more, 80% or more, or 90% or more.

In a case where at least one organic light emitting diode is provided above at least one inorganic light emitting diode, the first reflection layer may be capable of transmitting light incident from the at least one inorganic light emitting diode and may be capable of reflecting light incident from the at least one organic light emitting diode. Similarly, the second reflection layer may transmit light incident from the at least one inorganic light emitting diode and may reflect light incident from the at least one organic light emitting diode.

In a case where at least one organic light emitting diode is provided above at least one inorganic light emitting diode, the first and second reflection layers may be capable of reflecting and transmitting light incident from the at least one inorganic light emitting diode at a constant ratio, and may be capable of reflecting and transmitting light incident from the at least one organic light emitting diode at a constant ratio. In this case, it is preferable that the reflectances of the first and second reflection layers at the peak wavelength of the incident light from the inorganic light emitting diode are each independently 5% or more and 50% or less, and the reflectances of the first and second reflection layers at the peak wavelength of the incident light from the organic light emitting diode are each independently 50% or more.

In a case where at least one organic light emitting diode is provided below at least one inorganic light emitting diode, the first reflection layer may be capable of transmitting light incident from the at least one organic light emitting diode and may be capable of reflecting light incident from the at least one inorganic light emitting diode. Similarly, the second reflection layer may be capable of transmitting light incident from the at least one organic light emitting diode and reflecting light incident from the at least one inorganic light emitting diode.

In a case where at least one organic light emitting diode is provided below at least one inorganic light emitting diode, the first and second reflection layers may be capable of reflecting and transmitting light incident from the at least one organic light emitting diode at a constant ratio, and may be capable of reflecting and transmitting light incident from the at least one inorganic light emitting diode at a constant ratio. In this case, it is preferable that the reflectances of the first and second reflection layers at the peak wavelength of the incident light from the organic light emitting diode are each independently 5% or more and 50% or less, and the reflectances of the first and second reflection layers at the peak wavelength of the incident light from the inorganic light emitting diode are each independently 50% or more.

A second display device according to the present disclosure may include a plurality of first light emitting diodes arranged two-dimensionally, and a plurality of second light emitting diodes arranged two-dimensionally, in which the plurality of first light emitting diodes may include a plurality of inorganic light emitting diodes, the plurality of second light emitting diodes may include at least one type of a plurality of organic light emitting diodes, a plurality of quantum dot light emitting diodes, and a plurality of perovskite light emitting diodes, and at least one of the second light emitting diodes may be provided on an upper portion of or above at least one of the first light emitting diodes, or on a lower portion of or below at least one of the first light emitting diodes.

In the second display device, the configuration in which at least one second light emitting diode is provided on an upper portion of at least one first light emitting diode also includes a configuration in which at least one first light emitting diode and at least one second light emitting diode provided on an upper portion thereof share a first electrode or a second electrode. The configuration in which at least one second light emitting diode is provided below a lower portion of at least one first light emitting diode also includes a configuration in which at least one first light emitting diode and at least one second light emitting diode provided below a lower portion thereof share a first electrode or a second electrode. The first electrode may be an anode and the second electrode may be a cathode.

A third display device according to the present disclosure may include a plurality of first light emitting diodes arranged two-dimensionally, a plurality of second light emitting diodes arranged two-dimensionally, and a plurality of third light emitting diodes arranged two-dimensionally, in which the second light emitting diode may be provided on an upper portion thereof or above the first light emitting diode, the third light emitting diode may be provided on an upper portion of or above the second light emitting diode, at least one light emitting diode among three kinds of light emitting diodes including the first light emitting diode, the second light emitting diode, and the third light emitting diode may be an inorganic light emitting diode, and the remaining light emitting diodes among the three kinds of light emitting diodes may be at least one of an organic light emitting diode, a quantum dot light emitting diode, and a perovskite light emitting diode.

In the third display device, the configuration in which the second light emitting diode is provided on an upper portion of or above the first light emitting diode includes a configuration in which the first light emitting diode and the second light emitting diode share the first electrode or the second electrode. The configuration in which the third light emitting diode is provided on an upper portion of or above the second light emitting diode also includes a configuration in which the second light emitting diode and the third light emitting diode share the first electrode or the second electrode. The first electrode may be an anode and the second electrode may be a cathode.

In the second display device and the third display device, the three light emitting diodes of the first light emitting diode, the second light emitting diode and the third light emitting diode may include a red light emitting diode, a green light emitting diode and a blue light emitting diode. The red light emitting diode is preferably a red organic light emitting diode from the viewpoint of improving the life of the display device. The blue light emitting diode is preferably a blue inorganic light emitting diode from the viewpoint of luminous efficiency of the display device.

An embodiment of the present disclosure will be described in the following order with reference to the drawings. Note that, in all the drawings of the following embodiments, the same or corresponding parts are denoted by the same reference numerals.
1 First Embodiment (Example of Display Device)
2 Second Embodiment (Example of Display Device)
3 Third Embodiment (Example of Display Device)
4 Fourth Embodiment (Example of Display Device)
5 Fifth Embodiment (Example of Display Device)
6 Sixth Embodiment (Example of Display Device)
7 Seventh Embodiment (Example of Display Device)
8 Eighth Embodiment (Example of Display Device)
9 Ninth Embodiment (Example of Display Device)
10th Embodiment (Example of Display Device)
11 11th Embodiment (Example of Display Device)
12 12th Embodiment (Example of Display Device)
13 13th Embodiment (Example of Display Device)
14 14th Embodiment (Example of Display Device)
15 15th Embodiment (Example of Display Device)
16 16th Embodiment (Example of Display Device)
17 17th Embodiment (Example of Display Device)
18 18th Embodiment (Example of Display Device)
19 19th Embodiment (Example of Display Device)
20 20th Embodiment (Example of Display Device)
21 Relationship among Normal Lines Extending through the Centers of Light Emitting Units, Lens Members, and Wavelength Selection Units
22 Example of Resonator Structure
23 Application Examples

### 1 First Embodiment

### [Outline]

In a first embodiment, an example in which one pixel is configured by providing one red organic LED and one green organic LED above one blue inorganic LED will be described. With this configuration, luminous efficiency can be improved (that is, power consumption can be reduced) as compared with a display device in which inorganic LEDs of three primary colors are two-dimensionally arranged, and a life can be prolonged as compared with a display device in which organic LEDs of three primary colors are two-dimensionally arranged. Hereinafter, the reason will be described in detail.

### (a) Influence of Miniaturization on Luminous Efficiency

When the inorganic LED is miniaturized (for example, when the inorganic LED is miniaturized to a pixel size of a microdisplay), the luminous efficiency of the inorganic LED decreases due to damage to an end surface of the inorganic LED at the time of processing the end surface of the inorganic LED. On the other hand, since the organic LED emits light in a molecular unit, a decrease in luminous efficiency due to miniaturization hardly occurs.

### (b) Difference in Luminous Efficiency Due to Light Emission Wavelength Peak of Inorganic LED

The luminous efficiency of the inorganic LED varies depending on a light emission wavelength peak of the inorganic LED, and the inorganic LED having a shorter light emission wavelength has a higher luminous efficiency. The order of the levels of luminous efficiency of the inorganic LEDs of the three primary colors is as follows.
(1) Blue inorganic LED (highest luminous efficiency)
(2) Green Inorganic LED
(3) Red inorganic LED (lowest luminous efficiency)

### (c) Difference in Driving Life Due to Emission Wavelength Peak of Organic LED

A lifetime of the organic LED varies depending on the emission wavelength peak of the organic LED, and the organic LED having a longer emission wavelength peak has a longer drive lifetime. The order of the lengths of the drive lives of the organic LEDs of the three primary colors is as follows.
(1) Red organic LED (longest drive life)
(2) Green organic LED
(3) Blue organic LED (shortest drive life)

In consideration of the above point (a), it is preferable to make the size of the inorganic LED in one pixel larger than the size of the organic LED by providing two organic LEDs above one inorganic LED.

In consideration of the point (b), the inorganic LED included in one pixel is preferably a blue inorganic LED, and in consideration of the point (c), the two organic LEDs included in one pixel are preferably a red organic LED and a green organic LED.

From the viewpoint of improving the luminous efficiency and prolonging the life, it is preferable that one red organic LED and one green organic LED are provided above one blue inorganic LED to configure one pixel.

### [Configuration of Display Device 101]

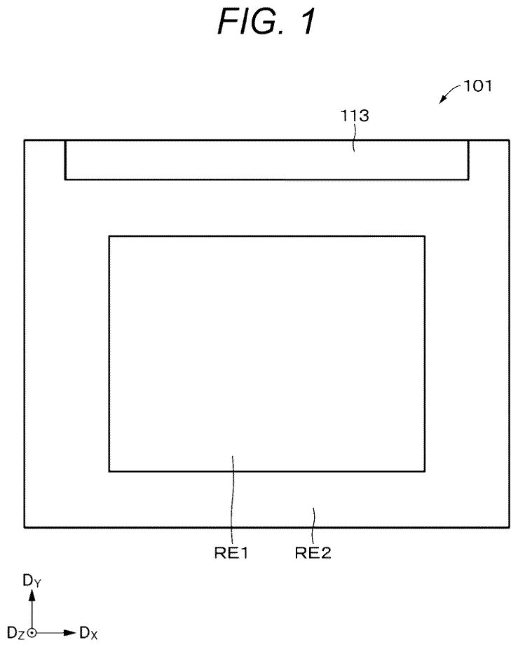

FIG. 1 is a plan view illustrating an example of a configuration of a display device 101 according to a first embodiment. The display device 101 includes a display region RE1 and a peripheral region RE2 provided around the display region RE1. The display region RE1 has a rectangular shape in plan view. In the present specification, the plan view means a plan view when an object is viewed from a direction D_{Z} (hereinafter, referred to as “front direction D_{Z}”) perpendicular to a display surface of the display device 101. In the present specification, a direction parallel to the long side of the display region RE1 is referred to as a horizontal direction D_{X}, and a direction parallel to the short side of the display region RE1 is referred to as a vertical direction D_{Y}.

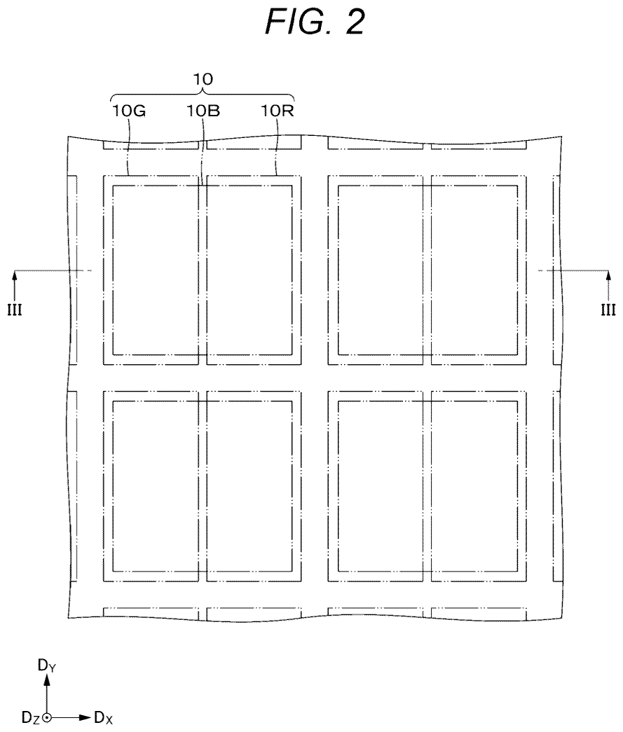

FIG. 2 is an enlarged plan view illustrating a part of the display region RE1 of the display device 101. The plurality of pixels 10 are two-dimensionally arranged in a prescribed arrangement pattern in the display region RE1. Note that FIG. 2 illustrates an example in which the plurality of pixels 10 is two-dimensionally arranged in the horizontal direction D_{X} and the vertical direction D_{Y}. A pad portion 113, a video display driver (not illustrated), and the like are provided in the peripheral region RE2. A flexible printed circuit (FPC) (not illustrated) may be connected to the pad portion 113.

Each pixel 10 includes three subpixels of a subpixel 10R, a subpixel 10G, and a subpixel 10B. The subpixel 10R can emit red light. The subpixel 10G can emit green light. The subpixel 10B can emit blue light. Red light, green light, and blue light are examples of light of a first color (first light having a first peak wavelength), light of a second color (second light having a second peak wavelength), and light of a third color (third light having a third peak wavelength), respectively. A size of the pixel 10 (an area of the pixel 10) is, for example, 10,000 μm² or less, preferably 1600 μm² or less, more preferably 225 μm² or less, still more preferably 100 μm² or less, and particularly preferably 25 μm² or less.

An area of the subpixel 10B is larger than an area of the subpixel 10R and larger than an area of the subpixel 10G. The area of the subpixel 10B is, for example, substantially equal to a sum of the area of the subpixel 10R and the area of the subpixel 10G. In the present specification, in the components of the subpixels 10R, 10G, 10B, and the like, the area of the components represents an area of the components when the components are viewed in plan.

The subpixels 10R, 10G, and 10B have, for example, a circular shape, an elliptical shape, a rectangular shape, or the like in plan view. In the present specification, a rectangular shape also contains a square shape. Note that FIG. 2 illustrates an example in which the subpixels 10R, 10G, and 10B have a rectangular shape in plan view.

The display device 101 is an example of a light emitting device. The display device 101 is a top emission type LED display device. The display device 101 may be a microdisplay. The display device 101 may be provided in a virtual reality (VR) device, a mixed reality (MR) device, an augmented reality (AR) device, an electronic view finder (EVF), a small projector, or the like.

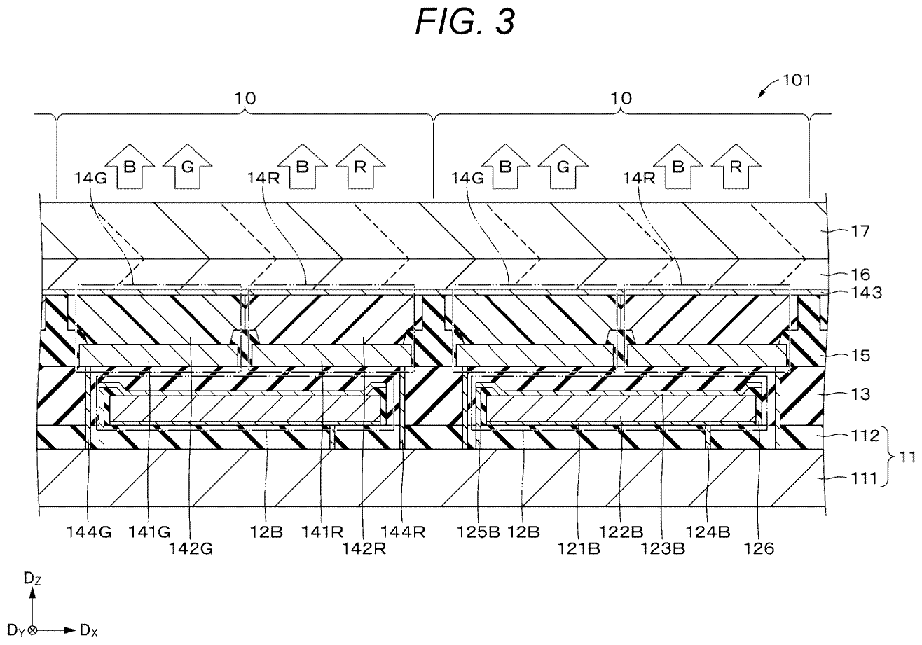

FIG. 3 is a sectional view taken along line III-III of FIG. 2. The display device 101 includes a drive substrate 11, a plurality of inorganic LEDs 12B, an insulating layer 13, a plurality of organic LEDs 14R, a plurality of organic LEDs 14G, an insulating layer 15, a protective layer 16, a substrate 17, a plurality of vias 124B, a plurality of vias 125B, a plurality of vias 144R, a plurality of vias 144G, and a plurality of insulating layers 126. In the following description, in a case where the organic LEDs 14R and 14G are collectively referred to without being particularly distinguished, they are referred to as organic LEDs 14. In FIG. 3, arrows denoted by a reference sign “R” represent red light, arrows denoted by a reference sign “G” represents green light, and arrows denoted by a reference sign “B” represents blue light.

In the following description, a surface on the top side (display surface side) of the display device 101 is referred to as a first surface, and a surface on a bottom side (opposite side to the display surface) of the display device 101 is referred to as a second surface, in each layer configuring the display device 101.

### (Drive Substrate 11)

The drive substrate 11 is a so-called backplane, and drives the plurality of inorganic LEDs 12B, the plurality of organic LEDs 14R, and the plurality of organic LEDs 14G. The drive substrate 11 includes a substrate 111 and an insulating layer 112 in order.

### (Substrate 111)

A plurality of drive circuits, a plurality of wirings (none of which are illustrated), and the like are provided on a first surface of the substrate 111. The substrate 111 may include, for example, a semiconductor that is easy to form, such as a transistor, or may include glass or resin having low moisture and oxygen permeability. Specifically, the substrate 111 may be a semiconductor substrate, a glass substrate, a resin substrate, or the like. The semiconductor substrate contains amorphous silicon, polycrystalline silicon, monocrystalline silicon, or the like, for example. The glass substrate contains, for example, high strain point glass, soda glass, borosilicate glass, forsterite, lead glass, quartz glass, or the like. The resin substrate contains, for example, at least one selected from a group including polymethyl methacrylate, polyvinyl alcohol, polyvinyl phenol, polyethersulfone, polyimide, polycarbonate, polyethylene terephthalate, polyethylene naphthalate, and the like.

### (Insulating Layer 112)

The insulating layer 112 is provided on the first surface of the substrate 111, and covers and flattens a plurality of drive circuits, a plurality of wirings, and the like. The insulating layer 112 insulates the plurality of drive circuits, the plurality of wirings, and the like provided on the first surface of the substrate 111 from the plurality of inorganic LEDs 12B.

The insulating layer 112 may be an organic insulating layer, an inorganic insulating layer, or a laminate thereof. The organic insulating layer contains, for example, at least one selected from a group including a polyimide-based resin, an acrylic resin, a novolac-based resin, and the like. The inorganic insulating layer contains, for example, at least one selected from a group including silicon oxide (SiOₓ), silicon nitride (SiNₓ), silicon oxynitride (SiOₓN_{y}), and the like.

### (Inorganic LED 12B)

The inorganic LED 12B configures the subpixel 10B. The peak wavelength of the emission light of the inorganic LED 12B is shorter than the peak wavelengths of the emission light of the organic LED 14R and the organic LED 14G. The color of the emission light of the inorganic LED 12B is different from the color of the emission light of the organic LED 14R and the organic LED 14G. The inorganic LED 12B can emit blue light.

The plurality of inorganic LEDs 12B are two-dimensionally arranged on the first surface of the drive substrate 11 in a prescribed arrangement pattern such as a matrix. One inorganic LED 12B is provided below one organic LED 14R and one organic LED 14G. The area of the inorganic LED 12B is larger than the area of the organic LED 14R and larger than the area of the organic LED 14G. The area of the inorganic LED 12B is, for example, substantially equal to the sum of the area of the organic LED 14R and the area of the organic LED 14G.

The inorganic LED 12B includes a first electrode 121B, an inorganic layer 122B, and a second electrode 123B in order on the first surface of the drive substrate 11. The inorganic LED 12B may include a substrate between the first electrode 121B and the inorganic layer 122B or between the inorganic layer 122B and the second electrode 123B as necessary.

### (Inorganic Layer 122B)

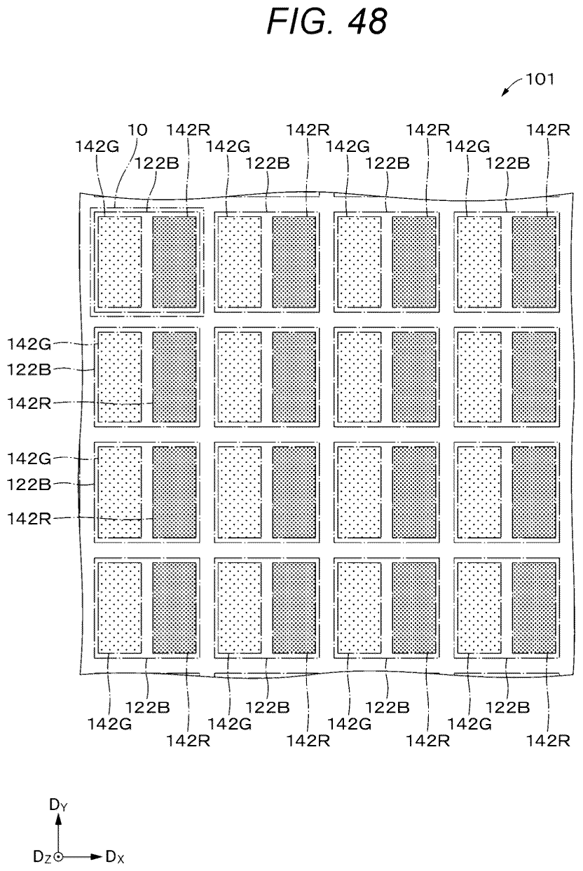

The inorganic layer 122B includes an inorganic light emitting layer. As illustrated in FIG. 48, the inorganic layer 122B is individually provided for each pixel 10 in the display region RE1. The inorganic layer 122B is, for example, a compound semiconductor laminate, and includes a first compound semiconductor layer, an inorganic light emitting layer (inorganic active layer), and a second compound semiconductor layer in this order on the first surface of the first electrode 121B.

### (First Compound Semiconductor Layer, Second Compound Semiconductor Layer)

The first compound semiconductor layer has p-type, and the second compound semiconductor layer has n-type. The first compound semiconductor layer and the second compound semiconductor layer include a compound semiconductor. Examples of the compound semiconductor include an AlInGaN-based compound semiconductor, an InGaN-based compound semiconductor, a GaN-based compound semiconductor, an AlGaN-based compound semiconductor, a ZnSe-based compound semiconductor, a ZnO-based compound semiconductor, and a perovskite semiconductor.

A p-type impurity is added to the first compound semiconductor layer. The p-type impurity contains, for example, at least one selected from a group including zinc (Zn), magnesium (Mg), beryllium (Be), cadmium (Cd), calcium (Ca), barium (Ba), oxygen (O), and the like.

An n-type impurity is added to the second compound semiconductor layer. The n-type impurity contains, for example, at least one selected from a group including silicon (Si), selenium (Se), germanium (Ge), tin (Sn), carbon (C), titanium (Ti), and the like.

### (Inorganic Light Emitting Layer)

The inorganic light emitting layer can emit blue light. The inorganic light emitting layer is provided between the second compound semiconductor layer and the first compound semiconductor layer.

The inorganic light emitting layer contains a compound semiconductor. The compound semiconductor includes, for example, materials exemplified as the materials of the second compound semiconductor layer and the first compound semiconductor layer. The inorganic light emitting layer may include a single compound semiconductor layer, or may have a single quantum well structure (SQW structure) or a multiple quantum well structure (MQW structure).

### (First Electrode 121B)

The first electrode 121B is provided on the second surface side of the inorganic layer 122B. FIG. 3 shows an example in which the first electrode 121B is in contact with the entire second surface of the inorganic layer 122B, but the first electrode 121B may be in contact with a part (for example, a central portion) of the second surface of the inorganic layer 122B. The first electrode 121B is separately provided in the plurality of inorganic LEDs 12B (that is, the plurality of pixels 10) in the display region RE1. That is, the first electrode 121B is divided between the inorganic LEDs 12B adjacent in the in-plane direction (that is, between the pixels 10 adjacent in the in-plane direction) in the display region RE1. The first electrode 121B is an anode. In the present specification, the in-plane direction represents a direction horizontal to the first surface of the drive substrate 11.

The first electrode 121B includes, for example, at least one metal (including an alloy) selected from a group including gold (Au), silver (Ag), palladium (Pd), platinum (Pt), nickel (Ni), Al (aluminum), Ti (titanium), tungsten (W), vanadium (V), chromium (Cr), copper (Cu), Zn (zinc), tin (Sn), and indium (In).

The first electrode 121B has, for example, a single layer configuration or a multilayer configuration. Examples of the multilayer configuration include Ti/Au, Ti/Al, Ti/Pt/Au, Ti/Al/Au, Ni/Au, AuGe/Ni/Au, Ni/Au/Pt, Ni/Pt, Pd/Pt, Ag/Pd, and the like. In a case where the first electrode 121B has a multilayer configuration, the layer before “/” in the multilayer configuration is located closer to the inorganic light emitting layer. This also applies to an example in which the second electrode 123B has a multilayer configuration.

### (Second Electrode 123B)

The second electrode 123B is provided on the first surface side of the inorganic layer 122B. Although FIG. 3 shows an example in which the second electrode 123B is in contact with substantially the entire first surface of the inorganic layer 122B, the second electrode 123B may be in contact with a part (for example, a central portion) of the first surface of the inorganic layer 122B. The second electrode 123B is separately provided in the plurality of inorganic LEDs 12B (that is, the plurality of pixels 10) in the display region RE1. That is, the second electrode 123B is divided between the inorganic LEDs 12B adjacent in the in-plane direction (that is, between the pixels 10 adjacent in the in-plane direction) in the display region RE1. The second electrode 123B is a cathode.

The second electrode 123B is preferably a transparent electrode. The second electrode 123B preferably contains, for example, a transparent conductive material. The transparent conductive material is, for example, indium oxide, indium-tin oxide (ITO: Indium Tin Oxide, Sn-doped In₂O₃, crystalline ITO and amorphous ITO), indium-zinc oxide (IZO), indium-gallium oxide (IGO), indium-doped gallium-zinc oxide (IGZO, In-GaZnO₄), IFO (F-doped In₂O₃), tin oxide (SnO₂), ATO (Sb-doped SnO₂), FTO (F-doped SnO₂), zinc oxide (Zno, Al-doped ZnO, B-doped ZnO, Ga-doped ZnO), antimony oxide, spinel type oxide, or oxide having a YbFe₂O₄ structure. The second electrode 123B may be a transparent conductive layer using gallium oxide, titanium oxide, niobium oxide, nickel oxide, or the like as a base layer.

The second electrode 123B may contain an opaque conductive material (metal). The opaque conductive material contains, for example, at least one metal selected from a group including palladium (Pd), platinum (Pt), nickel (Ni), aluminum (Al), titanium (Ti), gold (Au), and silver (Ag).

The second electrode 123B may have a single-layer configuration or a multilayer configuration (for example, Ti/Pt/Au).

### (Vias 124B, 125B)

The plurality of vias 124B is provided inside the insulating layer 112. The plurality of vias 125B is provided inside the laminated insulating layers 112 and 13. The via 124B is a connection member that electrically connects the first electrode 121B of the inorganic LED 12B and the drive circuit or wiring of the drive substrate 11. The via 125B is a connection member that electrically connects the second electrode 123B of the inorganic LED 12B and the drive circuit or wiring of the drive substrate 11. The vias 124 and 126B contain, for example, at least one metal selected from a group including copper (Cu), titanium (Ti), and the like.

A plurality of bumps may be provided instead of the plurality of vias 124. In this case, a pad may be provided on the first surface of the substrate 111, and the first electrode 121B of the inorganic LED 12B may be connected to the pad through the bump.

### (Insulating Layer 126)

The insulating layer 126 covers from a peripheral edge portion of the first surface of the first electrode 121B to a side surface (end surface) of the first electrode 141R. This can prevent the first electrode 121B and the second electrode 123B from coming into contact with each other on a side surface (end surface) of the inorganic LED 12B. Furthermore, the insulating layer 126 can also suppress contact between the via 125B and the side surface of the inorganic LED 12B. Here, the peripheral edge portion of the first surface of the first electrode 121B refers to a region having a predetermined width from the peripheral edge of the first surface of the first electrode 121B toward the inside. The insulating layer 126 may be an organic insulating layer, an inorganic insulating layer, or a laminate thereof. The organic insulating layer may contain a material exemplified as the organic insulating layer of the insulating layer 112. The inorganic insulating layer may contain the material exemplified as the inorganic insulating layer of the insulating layer 112.

### (Organic LEDs 14R, 14G)

The organic LED 14R configures a subpixel 10R. The organic LED 14G configures a subpixel 10G. The peak wavelengths of the emission light of the organic LED 14R and the organic LED 14G are longer than the peak wavelength of the emission light of the inorganic LED 12B. The color of the emission light of the organic LED 14R and the organic LED 14G is different from the color of the emission light of the inorganic LED 12B. In addition, the color of the emission light of the organic LED 14R and the color of the emission light of the organic LED 14G are also different. The organic LED 14R can emit red light. The organic LED 14G can emit green light.

The plurality of organic LEDs 14R and the plurality of organic LEDs 14G are provided in the same layer. The plurality of organic LEDs 14R and the plurality of organic LEDs 14G are provided on a layer different from the plurality of inorganic LEDs 12B. The plurality of organic LEDs 14R and the plurality of organic LEDs 14G are two-dimensionally arranged on the first surface of the insulating layer 13 in a prescribed arrangement pattern such as a matrix. One organic LED 14R and one organic LED 14G are provided above one inorganic LED 12B. The organic LED 14R and the organic LED 14G can transmit light emitted from the inorganic LED 12B. The area of the organic LED 14R is smaller than the area of the inorganic LED 12B, and the area of the organic LED 14G is smaller than the area of the inorganic LED 12B. The area of the organic LED 14R and the area of the organic LED 14G may be the same or different.

The organic LED 14R includes a first electrode 141R, an organic layer 142R, and a second electrode 143 in this order on the first surface of the insulating layer 13. The organic LED 14G includes a first electrode 141G, an organic layer 142G, and a second electrode 143 in this order on the first surface of the insulating layer 13. In the following description, the first electrodes 141R and 141G will be referred to as a first electrode 141 when they are collectively referred without being particularly distinguished. In addition, in a case where the organic layers 142R and 142G are collectively referred to without being particularly distinguished, they are referred to as an organic layer 142.

### (Organic Layers 142R, 142G)

The organic layer 142 includes an organic light emitting layer. The organic layer 142 may be configured by a laminate including an organic light emitting layer, and in this case, some layers (for example, electron injection layers) of the laminate may be inorganic layers. The organic layer 142R can emit red light by recombination of holes injected from the first electrode 141R and electrons injected from the second electrode 143. The organic layer 142G can emit green light by recombination of holes injected from the first electrode 141G and electrons injected from the second electrode 143.

The organic layer 142R is provided between the first electrode 141R and the second electrode 143. Similarly, the organic layer 142G is provided between the first electrode 141R and the second electrode 143. The organic layer 142 is separately provided by the plurality of organic LEDs 14 in the display region RE1. More specifically, as illustrated in FIG. 48, the organic layer 142R and the organic layer 142G are individually provided for each pixel 10 in the display region RE1. The organic layers 142 adjacent in an in-plane direction may be divided, may be in contact, or may be isolated.

The organic layer 142R includes, for example, a hole injection layer, a hole transport layer, a red organic light emitting layer, an electron transport layer, and an electron injection layer in this order from the first electrode 141R to the second electrode 143. The organic layer 142G includes, for example, a hole injection layer, a hole transport layer, a green organic light emitting layer, an electron transport layer, and an electron injection layer in this order from the first electrode 141G to the second electrode 143. In the following description, in a case where the red organic light emitting layer and the green organic light emitting layer are collectively referred to without being particularly distinguished, they are simply referred to as organic light emitting layers.

The hole injection layer can enhance hole injection efficiency into the organic light emitting layer and suppress leakage. The hole transport layer can enhance hole transport efficiency to the organic light emitting layer. The electron injection layer can enhance electron injection efficiency into the organic light emitting layer. The electron transport layer can enhance electron transport efficiency to the organic light emitting layer.

When an electric field is applied to the red organic light emitting layer, recombination of holes injected from the first electrode 141R and electrons injected from the second electrode 143 occurs, and the red organic light emitting layer can emit red light. The green organic light emitting layer can emit green light according to a principle similar to that of the red organic light emitting layer.

### (First Electrodes 141R, 141G)

The first electrode 141 is provided on the first surface side of the organic layer 142. The first electrode 141 is separately provided in the plurality of organic LEDs 14 in the display region RE1. That is, the first electrode 141 is divided between the organic LEDS 14 adjacent in the in-plane direction in the display region RE1. The first electrode 141 is an anode. When a voltage is applied between the first electrode 141 and the second electrode 143, holes are injected from the first electrode 141 into the organic layer 142.

The first electrode 141 may include, for example, a metal layer or a transparent conductive oxide layer, or may include a metal layer and a transparent conductive oxide layer. In a case where the first electrode 141 includes a metal layer and a transparent conductive oxide layer, the transparent conductive oxide layer is preferably provided on the organic layer 142 side from the viewpoint of adjoining a layer having a high work function to the organic layer 142.

The metal layer also has a function as a reflection layer that reflects light emitted from the organic layer 142. The metal layer contains, for example, at least one metal element selected from a group including chromium (Cr), gold (Au), platinum (Pt), nickel (Ni), copper (Cu), molybdenum (Mo), titanium (Ti), tantalum (Ta), aluminum (Al), magnesium (Mg), iron (Fe), tungsten (W), and silver (Ag). The metal layer may contain the above-described at least one metal element as a constituent element of an alloy. Specific examples of the alloy include an aluminum alloy and a silver alloy. Specific examples of the aluminum alloy include AlNd and AlCu, for example.

A base layer (not illustrated) may be provided adjacent to the second surface side of the metal layer. The base layer is for improving crystal orientation properties of the metal layer during formation of the metal layer. The base layer contains, for example, at least one metal element selected from a group including titanium (Ti) and tantalum (Ta). The base layer may contain the above-described at least one metal element as a constituent element of an alloy.

The transparent conductive oxide layer contains a transparent conductive oxide. The transparent conductive oxide contains, for example, at least one selected from a group including an indium-containing transparent conductive oxide (hereinafter, referred to as an “indium-based transparent conductive oxide”), a tin-containing transparent conductive oxide (hereinafter, referred to as a “tin-based transparent conductive oxide”), and a zinc-containing transparent conductive oxide (hereinafter, referred to as a “zinc-based transparent conductive oxide”).

The indium-based transparent conductive oxide includes, for example, indium tin oxide (ITO), indium zinc oxide (IZO), indium gallium oxide (IGO), indium gallium zinc oxide (IGZO) or fluorine-doped indium oxide (IFO). Among these transparent conductive oxides, indium tin oxide (ITO) is particularly preferable. This is because indium tin oxide (ITO) has a particularly low barrier for hole injection into the organic layer 142 as a work function, so that the drive voltage of the display device 101 can be particularly reduced. The tin-based transparent conductive oxide contains, for example, tin oxide, antimony-doped tin oxide (ATO), or fluorine-doped tin oxide (FTO). The zinc-based transparent conductive oxide contains, for example, zinc oxide, aluminum-doped zinc oxide (AZO), boron-doped zinc oxide, or gallium-doped zinc oxide (GZO).

### (Second Electrode 143)

The second electrode 143 is provided on the first surface side of the organic layer 142. The second electrode 143 is shared by the plurality of organic LEDs 14 in the display region RE1. That is, the second electrode 143 is connected between the organic LEDs 14 adjacent in the in-plane direction in the display region RE1. The second electrode 143 is a cathode. When a voltage is applied between the first electrode 141 and the second electrode 143, electrons are injected from the second electrode 143 into the organic layer 142. The second electrode 143 has translucency to each light emitted from the inorganic layer 122B, the organic layer 142R, and the organic layer 142G. The second electrode 143 is preferably a transparent electrode having transparency to visible light. In the present specification, visible light refers to light in a wavelength range of 360 nm or more and 830 nm.

The second electrode 143 preferably includes a material having as high translucency as possible and a small work function in order to enhance luminous efficiency. The second electrode 143 is configured by, for example, at least one layer of a metal layer or a transparent conductive oxide layer. More specifically, the second electrode 143 is configured by a single layer film of a metal layer or a transparent conductive oxide layer or by a laminated film of a metal layer and a transparent conductive oxide layer. In a case where the second electrode 143 is configured by a laminated film, the metal layer may be provided on the organic layer 142 side, or the transparent conductive oxide layer may be provided on the organic layer 142 side, but from the viewpoint of adjoining a layer having a low work function to the organic layer 142, the metal layer is preferably provided on the organic layer 142 side.

The metal layer contains, for example, at least one metal element selected from a group including magnesium (Mg), aluminum (Al), silver (Ag), calcium (Ca), and sodium (Na). The metal layer may contain the above-described at least one metal element as a constituent element of an alloy. A specific example of the alloy includes an MgAg alloy, an MgAl alloy, an AlLi alloy, or the like. The transparent conductive oxide layer contains a transparent conductive oxide. As the transparent conductive oxide, a material similar to the transparent conductive oxide of the first electrode 141 described above can be exemplified.

### (Vias 144R, 144G)

The plurality of vias 144R and 144G is provided inside the laminated insulating layer 112 and insulating layer 13. The via 144R is a connection member that electrically connects the first electrode 141R of the organic LED 14R and the drive circuit or wiring of the drive substrate 11. The via 144G is a connection member that electrically connects the first electrode 141G of the organic LED 14G and the drive circuit or wiring of the drive substrate 11. The vias 144R and 144G contain, for example, at least one metal selected from a group including copper (Cu), titanium (Ti), and the like.

### (Insulating Layer 13)

The insulating layer 13 is provided on the first surface of the drive substrate 11 so as to cover the first surface and the side surface of the inorganic LED 12B. The insulating layer 13 insulates between the inorganic LEDs 12B adjacent in the in-plane direction. In addition, the insulating layer 13 insulates between the inorganic LED 12B and the organic LED 14R adjacent in the front direction D_{Z} (thickness direction of the display device 101), and insulates between the inorganic LED 12B and the organic LED 14G adjacent in the front direction D_{Z}. The insulating layer 13 has translucency to blue light emitted from the inorganic LED 12B. As a material of the insulating layer 13, a material similar to that of the insulating layer 112 can be exemplified.

### (Insulating Layer 15)

The insulating layer 15 is provided between the first electrodes 141 adjacent in the in-plane direction. As a result, the insulating layer 15 can insulate between the first electrodes 141 adjacent in the in-plane direction. The insulating layer 15 may cover from a peripheral edge portion of the first surface of the first electrode 141 to a side surface (end surface) of the first electrode 141. Here, the peripheral edge portion of the first surface of the first electrode 141 refers to a region having a predetermined width from the peripheral edge of the first surface of the first electrode 141 toward the inside. The insulating layer 15 may or may not be provided between the organic layers 142 adjacent in the in-plane direction.

### (Protective Layer 16)

The protective layer 16 protects the plurality of organic LEDs 14R and 14G. In addition, the protective layer 16 has a function as an adhesive layer that bonds the drive substrate 11 provided with the plurality of inorganic LEDs 12B, the plurality of organic LEDs 14R, 14G, and the like to the substrate 17. The protective layer 16 has translucency to light of each color emitted from the inorganic LED 12B and the organic LEDs 14R and 14G. The protective layer 16 contains, for example, at least one selected from a group including a thermosetting resin, an ultraviolet curable resin, and the like.

### (Substrate 17)

The substrate 17 is provided on the first surface of the protective layer 16. The substrate 17 seals the plurality of inorganic LEDs 12B, the plurality of organic LEDs 14R, 14G, and the like provided on the drive substrate 11. The substrate 17 has translucency to light of each color emitted from the inorganic LED 12B and the organic LEDs 14R and 14G. The substrate 17 is, for example, a glass substrate or a resin substrate.

### [Operations and Effects]

In the display device 101 according to the first embodiment, each pixel 10 includes one inorganic LED 12B and two organic LEDs 14R and 14G provided above the one inorganic LED 12B. As a result, an aperture ratio of the inorganic LED 12B can be expanded as compared with the aperture ratios of the organic LEDs 14R and 14G. Therefore, it is possible to suppress a decrease in luminous efficiency due to end surface damage (end surface processing damage of the inorganic LED 12B) that remarkably appears when the pitch of the pixels 10 is narrowed.

In the display device 101 according to the first embodiment, each pixel 10 includes one inorganic LED 12B and two organic LEDs 14R and 14G. Therefore, the luminous efficiency can be improved (that is, the power consumption can be reduced) as compared with the display device in which the inorganic LEDs of the three primary colors are two-dimensionally arranged, and the life can be extended as compared with the display device in which the organic LEDs of the three primary colors are two-dimensionally arranged.

### [Modifications]

### (Modification 1)

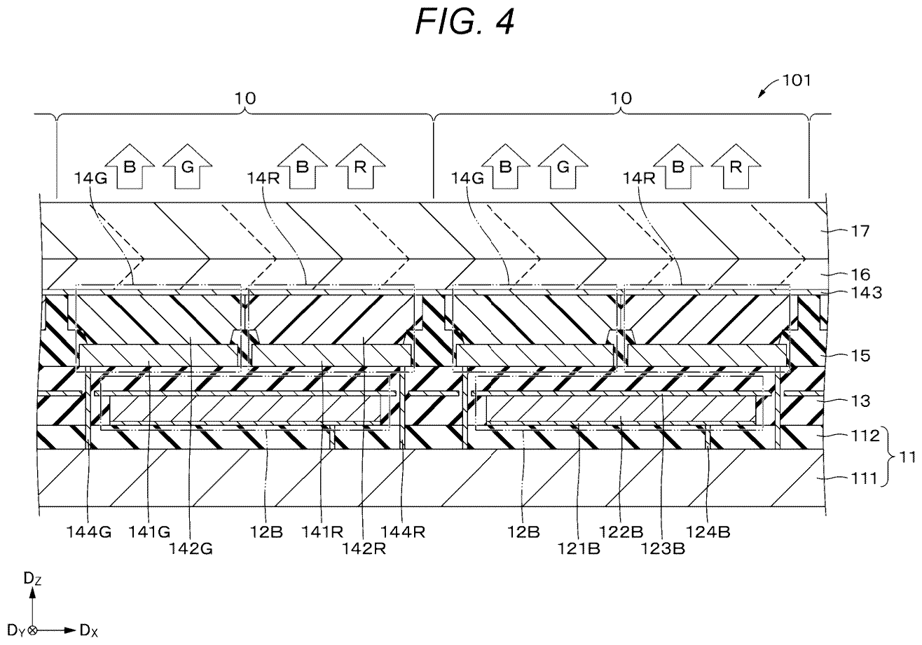

In the first embodiment, as illustrated in FIG. 3, an example has been described in which the second electrode 123B is separately provided in the plurality of inorganic LEDs 12B (that is, the plurality of pixels 10) in the display region RE1. However, the configuration of the second electrode 123B is not limited to this example, and for example, as illustrated in FIG. 4, the second electrode 123B may be shared by a plurality of inorganic LEDs 12B (that is, a plurality of pixels 10) in the display region RE1. That is, the second electrode 123B may be connected between the inorganic LEDs 12B adjacent in the in-plane direction (that is, between the pixels 10 adjacent in the in-plane direction) in the display region RE1. In this case, the insulating layer 126 (see FIG. 3) may be provided or may not be provided. A peripheral edge portion of the second electrode 123B may be connected to an auxiliary electrode provided in the peripheral region RE2. The auxiliary electrode may be connected to a wiring or the like of the drive substrate 11 through a connection member such as a via.

In the display device 101 according to the modification, the second electrode 123B may not be patterned, and the via 125 may not be provided for each pixel 10. Therefore, the configuration of the display device 101 can be further simplified.

### (Modification 2)

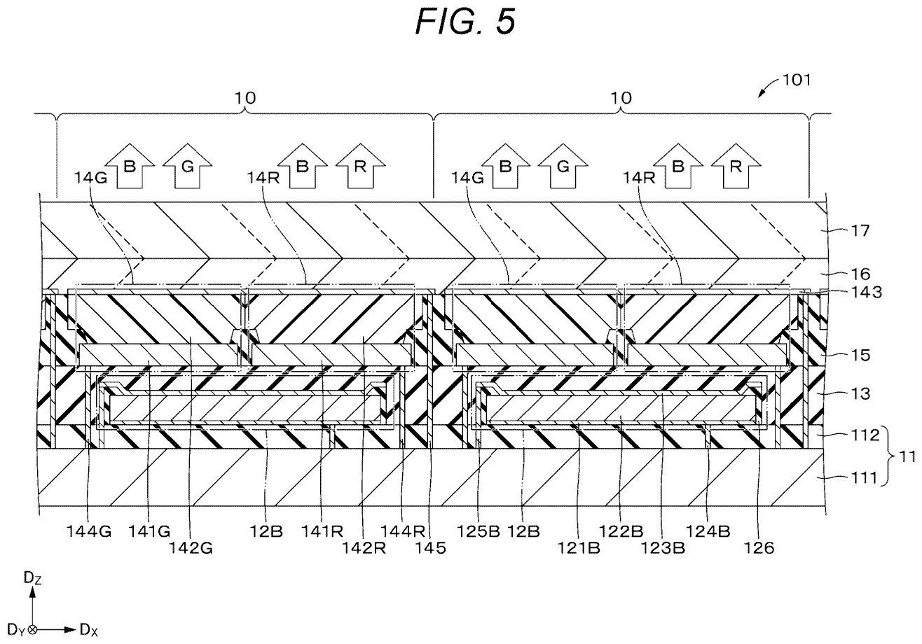

In the first embodiment, as illustrated in FIG. 3, an example in which the second electrode 143 is shared by the plurality of organic LEDs 14 in the display region RE1 has been described. However, the configuration of the second electrode 143 is not limited thereto, and for example, as illustrated in FIG. 5, the second electrode 143 may be separately provided in a plurality of pixels in the display region RE1. That is, the second electrode 143 may be divided between the pixels 10 adjacent in the in-plane direction in the display region RE1. Each of the divided second electrodes 143 may be connected to a drive circuit or wiring of the drive substrate 11 by a via 145.

### 2 Second Embodiment

### [Configuration of Display Device 102]

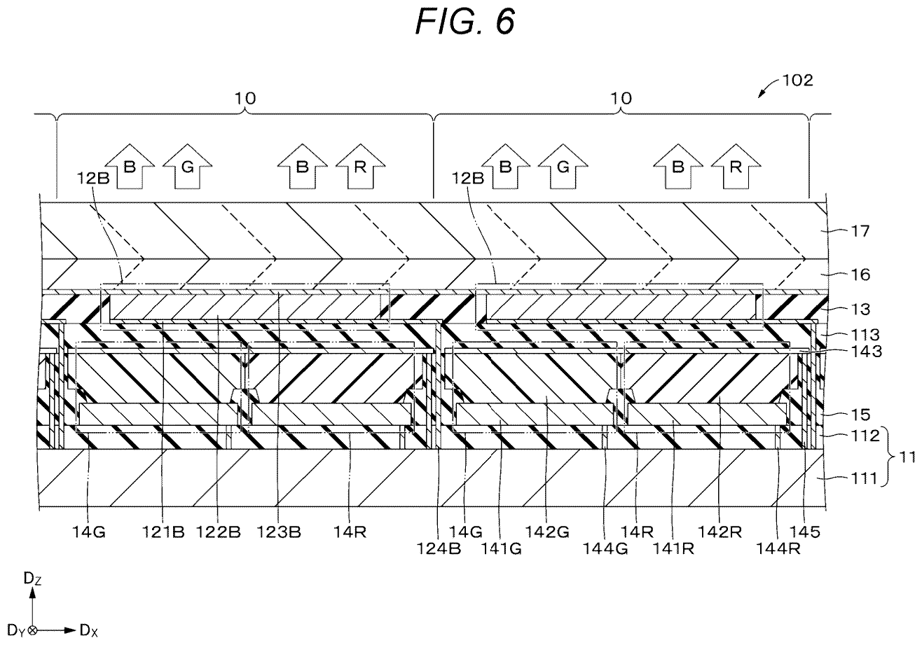

FIG. 6 is a cross-sectional view illustrating an example of a configuration of a display device 102 according to a second embodiment. The display device 102 is different from the display device 101 according to the first embodiment in that lamination positions of a plurality of inorganic LEDs 12B and a plurality of organic LEDs 14R, 14G are interchanged, and two organic LEDs 14R, 14G are provided below one inorganic LED 12B in each pixel 10.

The inorganic LED 12B has translucency to red light and green light emitted from the organic LEDs 14R and 14G, respectively.

The second electrode 123B is shared by the plurality of inorganic LEDs 12B (that is, the plurality of pixels 10) in the display region RE1. That is, the second electrode 123B is connected between the inorganic LEDs 12B adjacent in the in-plane direction (that is, between the pixels 10 adjacent in the in-plane direction) in the display region RE1. In this case, the insulating layer 126 (see FIG. 3) may be provided or may not be provided.

The plurality of second electrodes 143 are separately provided in the plurality of pixels 10 in the display region RE1. That is, the second electrode 143 is divided between the pixels 10 adjacent in the in-plane direction in the display region RE1. Each of the divided second electrodes 143 is connected to a drive circuit or wiring of the drive substrate 11 by the via 145.

### [Operations and Effects]

In the display device 102 according to the second embodiment, each pixel 10 includes one inorganic LED 12B and two organic LEDS 14R and 14G provided below the one inorganic LED 12B. Therefore, an effect similar to that of the first embodiment may be obtained.

### [Modifications]

### (Modification 1)

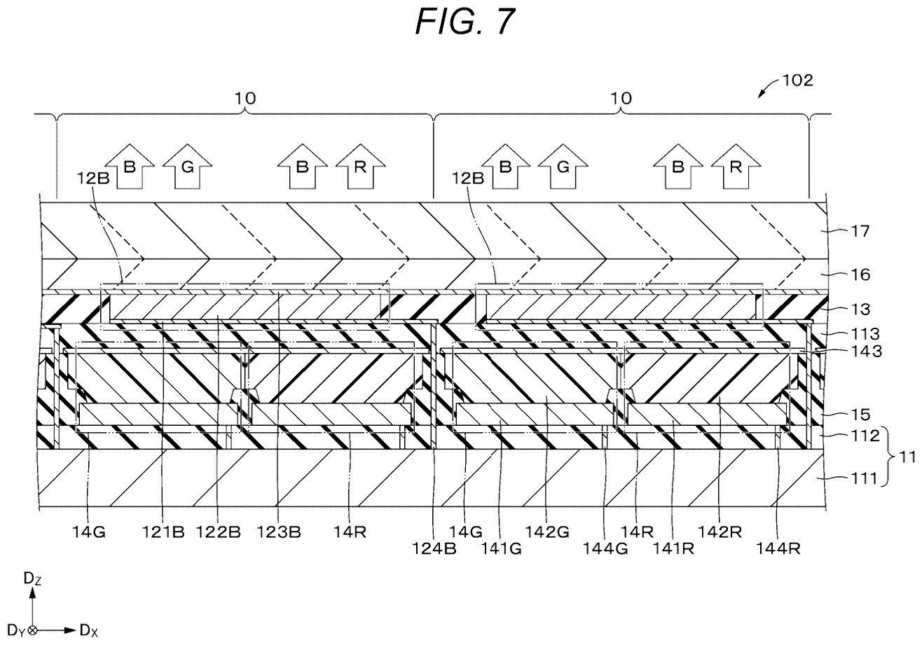

In the second embodiment, as illustrated in FIG. 6, an example in which the second electrode 143 is separately provided in the plurality of pixels 10 in the display region RE1 has been described. However, the configuration of the second electrode 143 is not limited to this example, and for example, the second electrode 143 may be shared by a plurality of pixels 10 in the display region RE1 as illustrated in FIG. 7. That is, the second electrode 143 may be connected between the pixels 10 adjacent in the in-plane direction in the display region RE1. A peripheral edge portion of the second electrode 123B may be connected to an auxiliary electrode provided in the peripheral region RE2. The auxiliary electrode may be connected to a wiring or the like of the drive substrate 11 through a connection member such as a via.

In the display device 201 according to the modification, the second electrode 143 may not be patterned, and the via 145 may not be provided for each pixel 10. Therefore, the configuration of the display device 101 can be further simplified.

### (Modification 2)

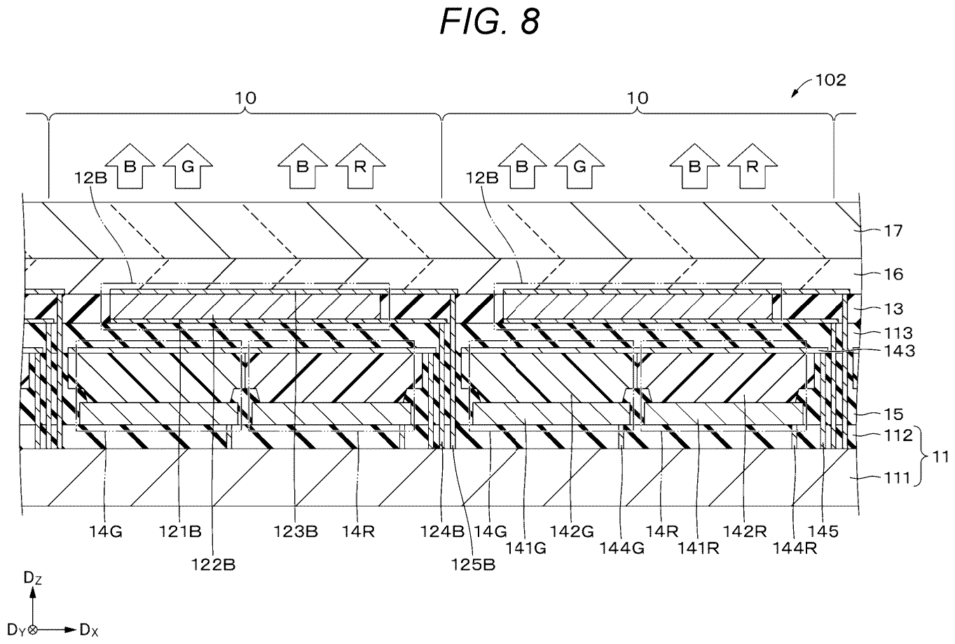

In the first embodiment, as illustrated in FIG. 6, an example in which the second electrode 123B is shared by the plurality of inorganic LEDs 12B in the display region RE1 has been described. However, the configuration of the second electrode 123B is not limited to this example, and for example, as illustrated in FIG. 8, the second electrode 123B may be separately provided in the plurality of inorganic LEDs 12B (that is, the plurality of pixels 10) in the display region RE1. That is, the second electrode 123B may be divided between the inorganic LEDs 12B adjacent in the in-plane direction (that is, between the pixels 10 adjacent in the in-plane direction) in the display region RE1.

### 3 Third Embodiment

### [Configuration of Display Device 103]

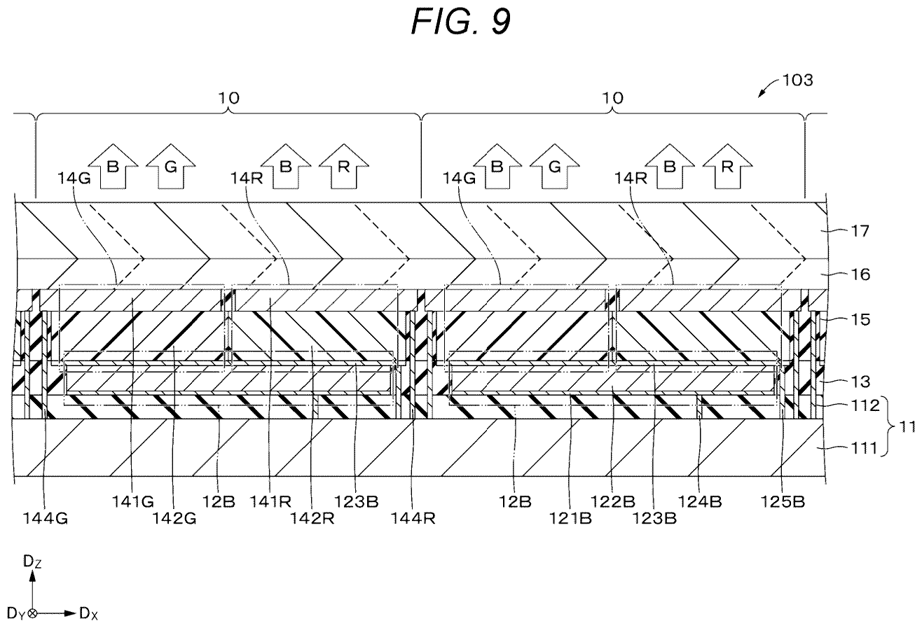

FIG. 9 is a cross-sectional view illustrating an example of a configuration of a display device 103 according to the third embodiment. The display device 103 is different from the display device 101 according to the first embodiment in that one inorganic LED 12B and two organic LEDs 14R and 14G included in each pixel 10 share the second electrode 123B.

The organic LED 14R includes a second electrode 123B, an organic layer 142R, and a first electrode 141 in order on the first surface of the inorganic layer 122B. The organic LED 14G includes a second electrode 123B, an organic layer 142G, and a first electrode 141 in order on the first surface of the inorganic layer 122B. The insulating layer 13 is provided on the first surface of the drive substrate 11 so as to expose the first main surface of the inorganic LED 12B, that is, the first surface of the second electrode 123B.

### [Operations and Effects]

In the display device 103 according to the third embodiment, one inorganic LED 12B and two organic LEDS 14R and 14G included in each pixel 10 share the second electrode 123B. As a result, the second electrode 143 in the display device 101 according to the first embodiment can be omitted. Therefore, the configuration of the display device 103 can be simplified as compared with the configuration of the display device 101.

### [Modifications]

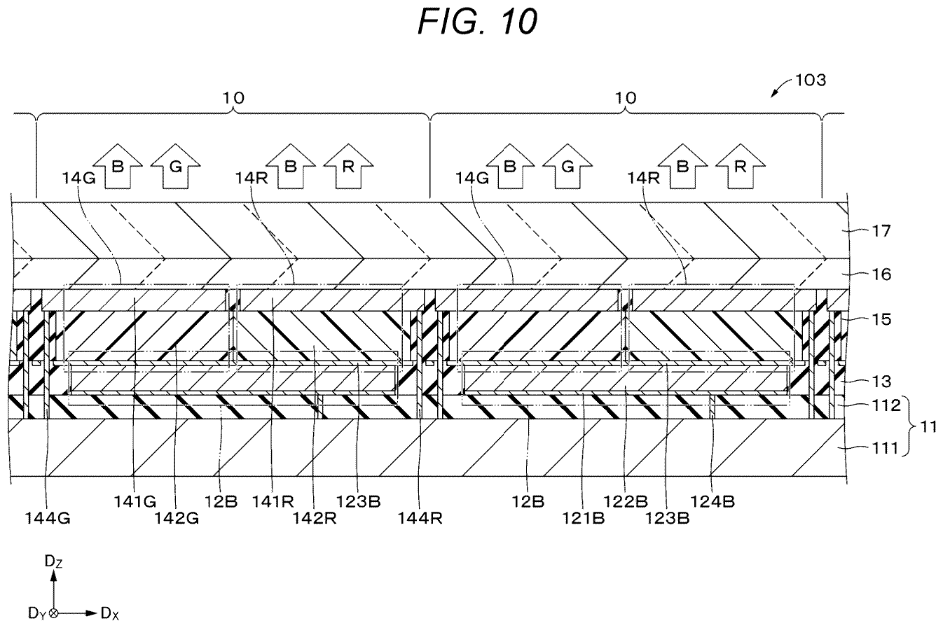

In the third embodiment, as illustrated in FIG. 9, an example in which the second electrode 123B is separately provided in the plurality of pixels 10 in the display region RE1 has been described. However, the configuration of the second electrode 123B is not limited thereto, and for example, as illustrated in FIG. 10, the second electrode 123B may be shared by a plurality of pixels 10 in the display region RE1. That is, the second electrode 123B may be connected between the pixels 10 adjacent in the in-plane direction in the display region RE1.

### 4 Fourth Embodiment

[Configuration of display device 104]

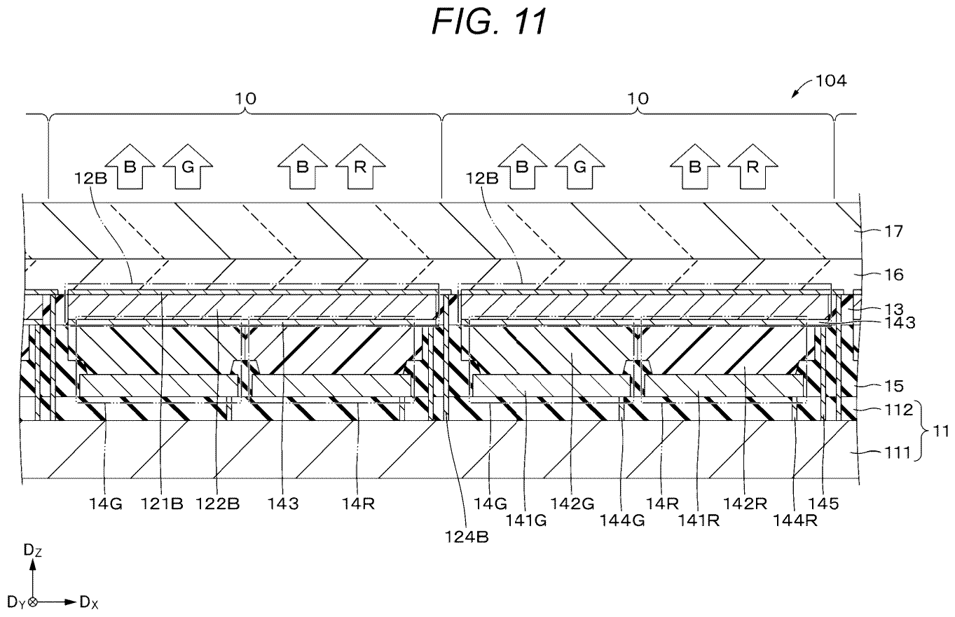

FIG. 11 is a cross-sectional view illustrating an example of a configuration of a display device 104 according to a fourth embodiment. The display device 104 is different from the display device 102 according to the second embodiment in that two organic LEDs 14R and 14G and one inorganic LED 12B included in each pixel 10 share the second electrode 143.

The inorganic LED 12B includes a second electrode 143, an inorganic layer 122B, and a first electrode 121B in order on the first surfaces of the organic layers 142R and 142G.

### [Operations and Effects]

In the display device 104 according to the fourth embodiment, two organic LEDs 14R and 14G and one inorganic LED 12B included in each pixel 10 share the second electrode 143. As a result, the second electrode 123B in the display device 102 according to the second embodiment can be omitted. Therefore, the configuration of the display device 104 can be simplified as compared with the configuration of the display device 102.

### [Modifications]

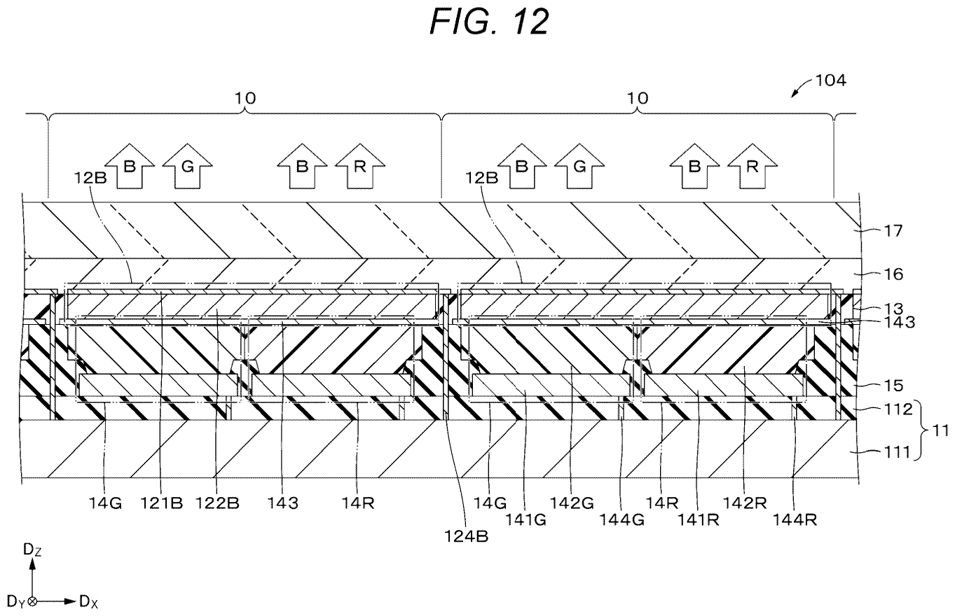

In the fourth embodiment, as illustrated in FIG. 11, an example in which the second electrode 143 is separately provided in the plurality of pixels 10 in the display region RE1 has been described. However, the configuration of the second electrode 143 is not limited thereto, and for example, the second electrode 143 may be shared by a plurality of pixels 10 in the display region RE1 as illustrated in FIG. 12. That is, the second electrode 143 may be connected between the pixels 10 adjacent in the in-plane direction in the display region RE1.

### 5 Fifth Embodiment

### [Configuration of Display Device 105]

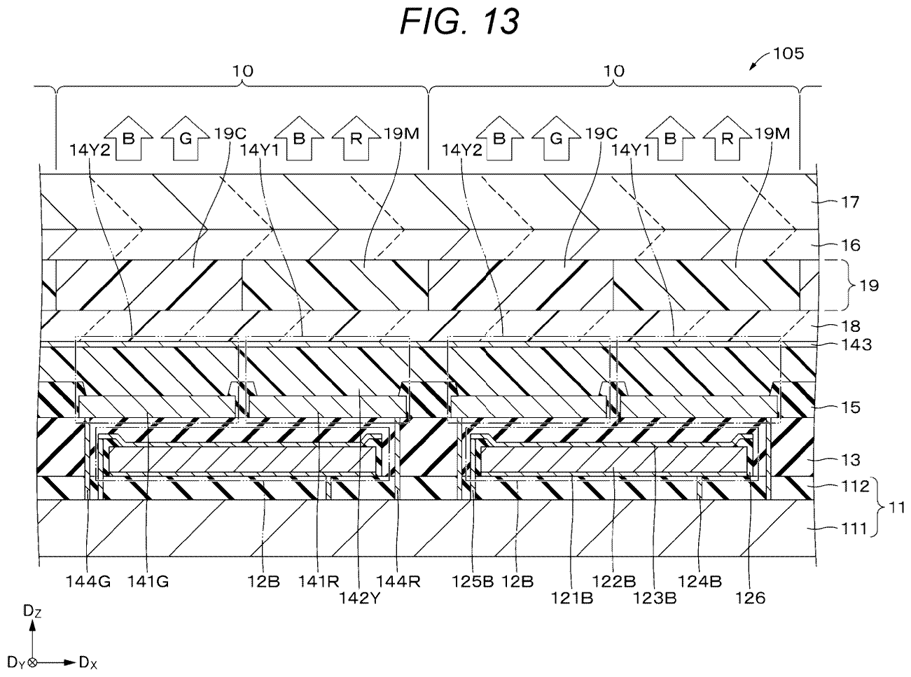

FIG. 13 is a cross-sectional view illustrating an example of a configuration of a display device 105 according to a fifth embodiment. The display device 105 is different from the display device 101 according to the first embodiment in that organic LEDs 14Y1 and 14Y2 are provided instead of the organic LEDs 14R and 14G, and a protective layer 18 and a color filter 19 are further provided. In the following description, in a case where the organic LEDs 14Y1 and 14Y2 are collectively referred to without being particularly distinguished, they are referred to as an organic LED 14Y.

### (Organic LEDs 14Y1, Y2)

A peak wavelength of the emission light of the organic LED 14Y is longer than a peak wavelength of the emission light of the inorganic LED 12B. A color of the emission light of the organic LED 14Y is different from a color of the emission light of the inorganic LED 12B. The organic LED 14Y can emit yellow light.

The plurality of organic LEDs 14Y are provided in a layer different from the plurality of inorganic LEDs 12B. The plurality of organic LEDs 14Y is two-dimensionally arranged on the first surface of the insulating layer 13 in a prescribed arrangement pattern such as a matrix. The two organic LEDs 14Y1 and Y2 are provided above one inorganic LED 12B. The organic LEDs 14Y1 and Y2 can transmit light emitted from the inorganic LED 12B. The areas of the organic LEDs 14Y1 and Y2 are smaller than the area of the inorganic LED 12B. The areas of the organic LEDs 14Y1 and Y2 may be the same or different. One pixel 10 includes two organic LEDs 14Y1 and Y2.

The organic LED 14Y1 is different from the organic LED 14R of the first embodiment in that an organic layer 142Y is provided instead of the organic layer 142R. That is, the organic LED 14Y1 includes the first electrode 141, the organic layer 142Y, and the second electrode 143 in order on the first surface of the insulating layer 13.

The organic LED 14Y2 is different from the organic LED 14G of the first embodiment in that an organic layer 142Y is provided instead of the organic layer 142G. That is, the organic LED 14Y2 includes the first electrode 141, the organic layer 142Y, and the second electrode 143 in order on the first surface of the insulating layer 13.

### (Organic Layer 142Y)

The organic layer 142Y includes an organic light emitting layer. The organic layer 142 may be configured by a laminate including an organic light emitting layer, and in this case, a part of the laminate may be an inorganic layer (for example, an electron injection layer). The organic layer 142Y can emit yellow light by recombination of holes injected from the first electrode 141 and electrons injected from the second electrode 143.

The organic layer 142Y is shared by the plurality of organic LEDs 14Y in the display region RE1. That is, the organic layer 142Y is connected between the organic LEDs 14Y adjacent in the in-plane direction in the display region RE1.

The organic layer 142Y may be an organic layer including a single-layer light emitting unit, an organic layer including a two-layer light emitting unit (an organic layer having a tandem structure), or an organic layer having a structure other than these.

The organic layer 142Y including a single-layer light emitting unit includes, for example, a hole injection layer, a hole transport layer, a yellow organic light emitting layer, an electron transport layer, and an electron injection layer in this order from the first electrode 141 toward the second electrode 143. Alternatively, the organic layer 142Y including a single-layer light emitting unit includes, for example, a hole injection layer, a hole transport layer, a green organic light emitting layer, a light emission separation layer, a red organic light emitting layer, an electron transport layer, and an electron injection layer in this order from the first electrode 141 toward the second electrode 143. In this configuration, the lamination positions of the green organic light emitting layer and the red organic light emitting layer may be interchanged.

The organic layer 142Y having two light-emitting units includes, for example, a hole injection layer, a hole transport layer, a green organic light emitting layer, an electron transport layer, a charge generation layer, a hole transport layer, a red organic light emitting layer, an electron transport layer, and an electron injection layer in this order from the first electrode 141 to the second electrode 143. In this configuration, the lamination positions of the green organic light emitting layer and the red organic light emitting layer may be interchanged.

Since the layers other than the yellow organic light emitting layer and the charge generation layer are as described in the first embodiment, the description of the layers other than the yellow organic light emitting layer and the charge generation layer is omitted. When an electric field is applied to the yellow organic light emitting layer, recombination of holes injected from the first electrode 141 and electrons injected from the second electrode 143 occurs, and the yellow organic light emitting layer can emit yellow light. The charge generation layer can individually supply electrons and holes to two light emitting layers sandwiching the charge generation layer.

### (Protective Layer 18)

The protective layer 18 is provided on the first surface of the second electrode 143 and covers the plurality of organic LEDs 14Y. The protective layer 18 can block the plurality of organic LEDs 14Y from the outside air, and can suppress moisture infiltration into the plurality of organic LEDs 14Y from the external environment. Furthermore, in a case where the second electrode 143 includes a metal layer, the second electrode 143 may have a function of suppressing oxidation of the metal layer.

The protective layer 18 includes, for example, an inorganic material or a polymer resin having low hygroscopicity. The protective layer 18 may have a single layer structure or a multilayer structure. In a case where the thickness of the protective layer 18 is increased, it is preferable to have a multilayer structure. This is for alleviating the internal stress in the protective layer 18. The inorganic material includes, for example, at least one selected from a group including silicon oxide (SiOₓ), silicon nitride (SiNₓ), silicon oxynitride (SiOₓN_{y}), titanium oxide (TiOₓ), aluminum oxide (AlOₓ), and the like. The polymer resin contains, for example, at least one selected from a group including a thermosetting resin, an ultraviolet curable resin, and the like.

### (Color Filter 19)

The color filter 19 is an example of the color conversion layer. The color filter 19 is provided above the plurality of organic LEDs 14R, 14G. More specifically, the color filter 19 is provided on the first surface of the protective layer 18. The color filter 19 is, for example, an on-chip color filter (OCCF). The color filter 19 includes, for example, a plurality of filter units 19M and a plurality of filter units 19C.

The plurality of filter units 19M and 19C are two-dimensionally arranged in the in-plane direction. The filter units 19M and 19C are examples of color conversion units. The filter unit 19M has a magenta color. The filter unit 19C has a cyan color. The filter unit 19M is provided above the organic LED 14Y1 of the two organic LEDs 14Y1 and 14Y2 included in each pixel 10. The filter unit 19C is provided above the organic LED 14Y2 of the two organic LEDs 14Y1 and 14Y2 included in each pixel 10.

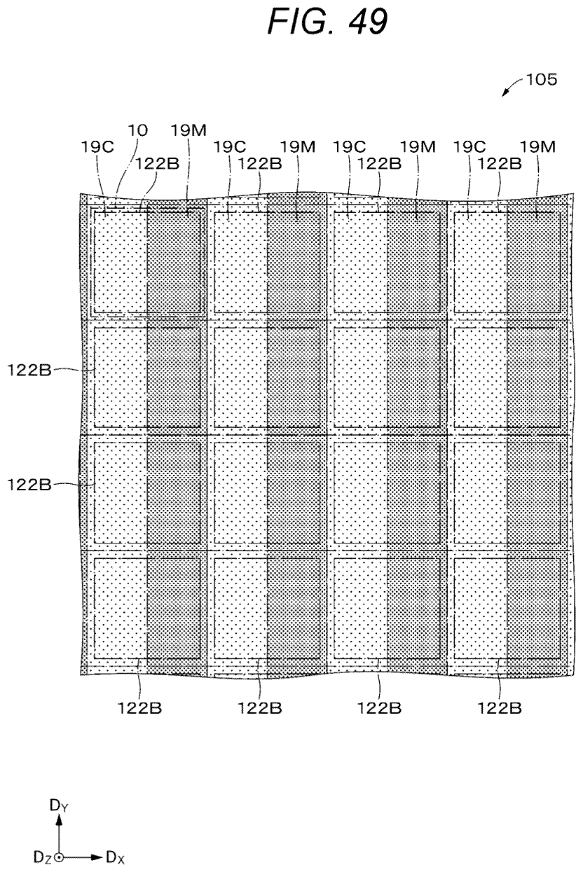

The plurality of filter units 19M and 19C is not limited to the two-dimensional arrangement, and may be arranged one-dimensionally in the horizontal direction D_{X}, for example. FIG. 49 is a plan view illustrating an example of one-dimensional arrangement of the filter units 19M and 19C. The filter unit 19M may have a linear shape extending in the vertical direction D_{Y}. The plurality of filter units 19M may be arranged in a stripe shape. As illustrated in FIG. 49, the filter unit 19M is individually provided for each column of the subpixels 10R in the display region RE1. The filter unit 19Y may have a linear shape extending in the vertical direction D_{Y}. The plurality of filter units 19Y may be arranged in a stripe shape. As illustrated in FIG. 49, the filter unit 19Y is individually provided for each column of the subpixels 10G in the display region RE1. The linear filter units 19M and 19Y are alternately arranged in the horizontal direction D_{X}.

The filter unit 19M transmits red light contained in yellow light emitted from the organic LED 14Y1 and blue light emitted from the inorganic LED 12B, and absorbs green light contained in yellow light emitted from the organic LED 14Y1. The filter unit 19C transmits green light contained in yellow light emitted from the organic LED 14Y2 and blue light emitted from the inorganic LED 12B, and absorbs red light contained in yellow light emitted from the organic LED 14Y2.

The filter unit 19M includes, for example, a magenta color resist. The filter unit 19C includes, for example, a cyan color resist.

The color filter 19 may further include a light absorbing portion such as a black matrix portion as necessary. The light absorbing portion is provided between the adjacent filter units 19M and 19C.

### (Subpixels 10R, 10G, and 10B)

The subpixel 10R includes a filter unit 19M and an organic LED 14Y1. The subpixel 10G includes a filter unit 19C and an organic LED 14Y2. Similarly to the pixel in the first embodiment, the subpixel 10G includes the inorganic LED 12B.

### [Operations and Effects]

In the display device 105 according to the fifth embodiment, the plurality of organic LEDs 14Y1 and 14Y2 shares one organic layer 142Y. Therefore, it is not necessary to divide the organic layer 142Y for each of the plurality of subpixels 10R and 10G using a mask or the like. Therefore, even in a case where miniaturization of the subpixels 10R and 10G has progressed, deterioration in manufacturability of the organic LEDs 14Y1 and 14Y2 can be suppressed. In addition, the manufacturing cost of the display device 105 can be reduced.

### [Modifications]

### (Modification 1)

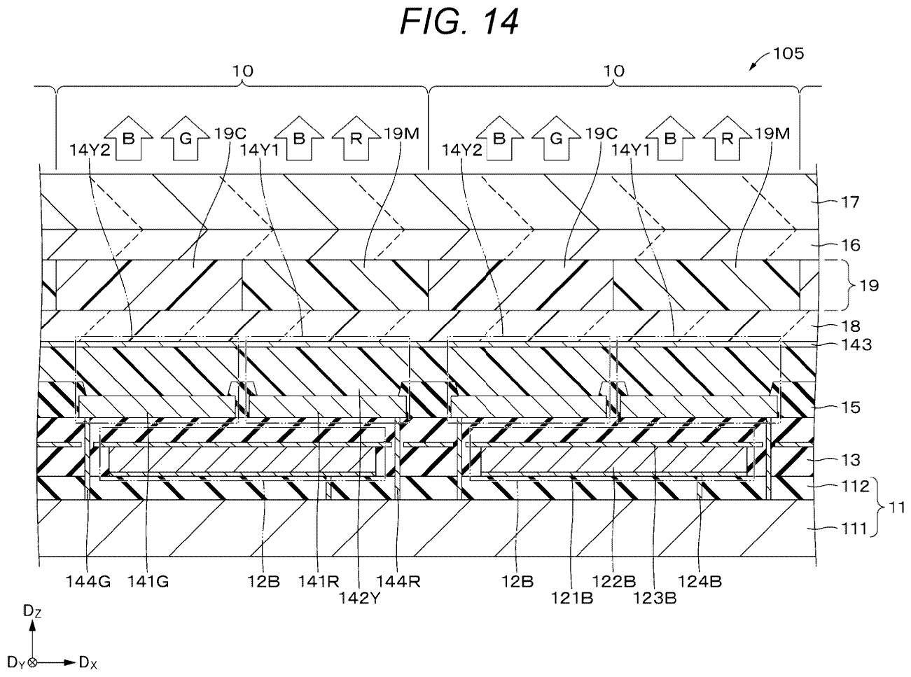

In the fifth embodiment, as illustrated in FIG. 13, an example has been described in which the second electrode 123B is separately provided in the plurality of inorganic LEDs 12B (that is, the plurality of pixels 10) in the display region RE1. However, the configuration of the second electrode 123B is not limited to this example, and for example, as illustrated in FIG. 14, the second electrode 123B may be shared by the plurality of inorganic LEDs 12B (that is, the plurality of pixels 10) in the display region RE1. That is, the second electrode 123B may be connected between the inorganic LEDs 12B adjacent in the in-plane direction (that is, between the pixels 10 adjacent in the in-plane direction) in the display region RE1.

### (Modification 2)

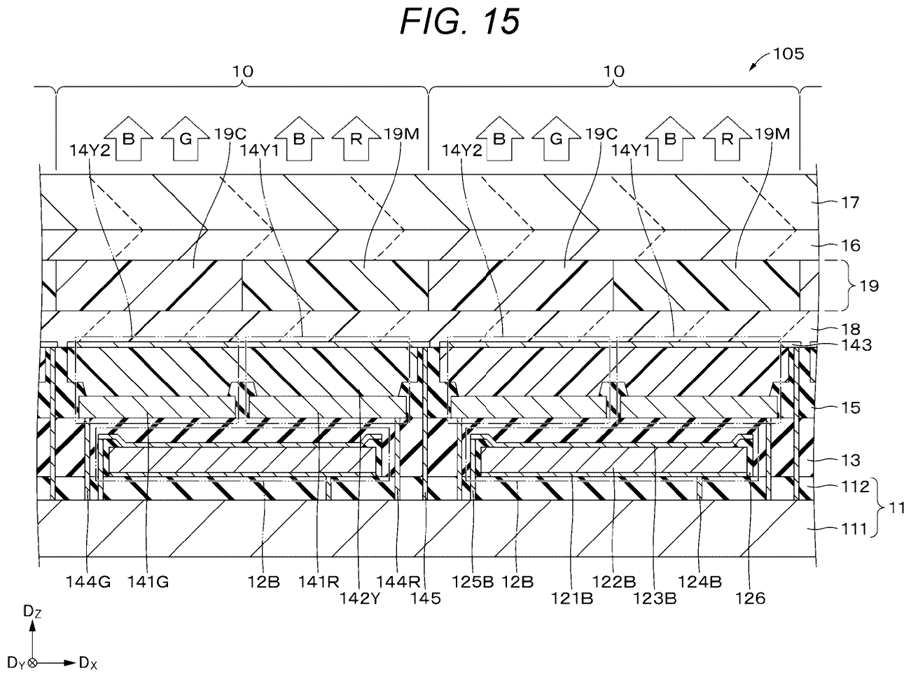

In the fifth embodiment, as illustrated in FIG. 13, an example in which the second electrode 143 is shared by the plurality of organic LEDs 14 in the display region RE1 has been described. However, the configuration of the second electrode 143 is not limited to this example, and for example, as illustrated in FIG. 15, a plurality of second electrodes 143 may be separately provided in a plurality of pixels 10 in the display region RE1. That is, the second electrode 143 may be divided between the pixels 10 adjacent in the in-plane direction in the display region RE1. Each of the divided second electrodes 143 may be connected to a drive circuit or wiring of the drive substrate 11 by a via 145.

The organic layer 142Y has a plurality of holes. Each hole is provided at a position between the pixels 10 and penetrates in the thickness direction of the organic layer 142Y. The via 145 of each pixel 10 passes through the hole.

### (Modification 3)

In the fifth embodiment, an example in which the display device 105 includes the color filter 19 as the color conversion layer has been described, but the display device 105 may include a dielectric multilayer film or a quantum dot layer as the color conversion layer.

### 6 Sixth Embodiment

### [Configuration of Display Device 106]

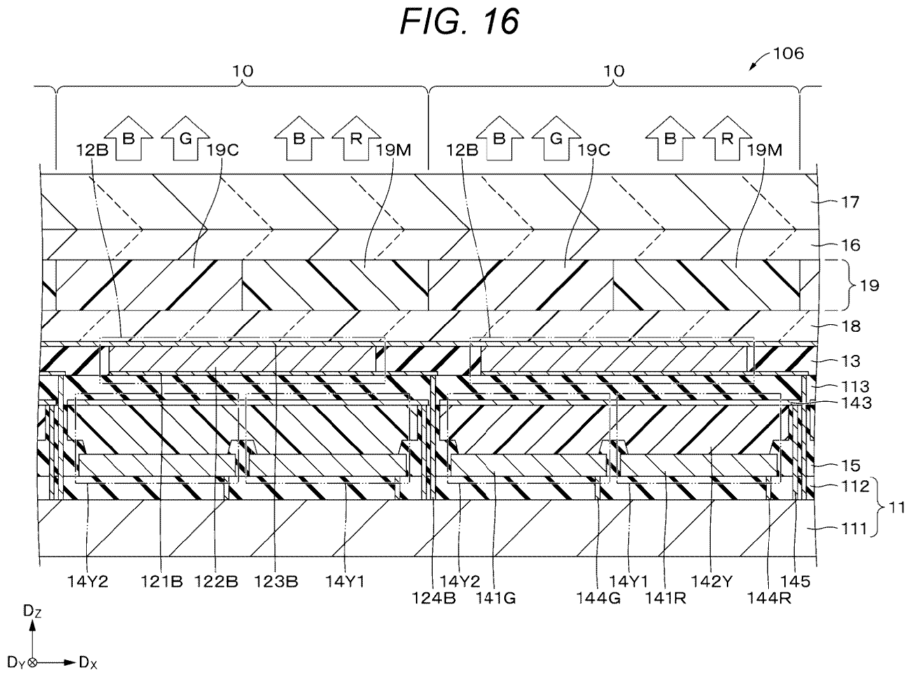

FIG. 16 is a cross-sectional view illustrating an example of a configuration of a display device 106 according to a sixth embodiment. The display device 106 is different from the display device 105 according to the fifth embodiment in that lamination positions of a plurality of inorganic LEDs 12B and a plurality of organic LEDs 14Y1 and 14Y2 are interchanged, and two organic LEDs 14Y1 and 14Y2 are provided below one inorganic LED 12B in each pixel 10.

The inorganic LED 12B has translucency to yellow light emitted from each of the organic LEDs 14Y1 and 14Y2.

The first electrode 121B is shared by the plurality of inorganic LEDs 12B (that is, the pixel 10) in the display region RE1. That is, the first electrode 121B is connected between the inorganic LEDs 12B adjacent in the in-plane direction (that is, between the pixels 10 adjacent in the in-plane direction) in the display region RE1.

The plurality of second electrodes 143 are separately provided in the plurality of pixels 10 in the display region RE1. That is, the second electrode 143 is divided between the pixels 10 adjacent in the in-plane direction in the display region RE1. Each of the divided second electrodes 143 may be connected to a drive circuit or wiring of the drive substrate 11 by a via 145.

The organic layer 142Y has a plurality of holes. Each hole is provided at a position between the pixels 10 and penetrates in the thickness direction of the organic layer 142Y. The vias 124B and 145 of each pixel 10 pass through the holes.

### [Operations and Effects]

In a display device 601 according to the sixth embodiment, similarly to the display device 105 according to the fifth embodiment, the plurality of organic LEDS 14Y1 and 14Y2 share one organic layer 142Y. Therefore, an effect similar to that of the display device 105 according to the fifth embodiment can be obtained.

### [Modifications]

### (Modification 1)

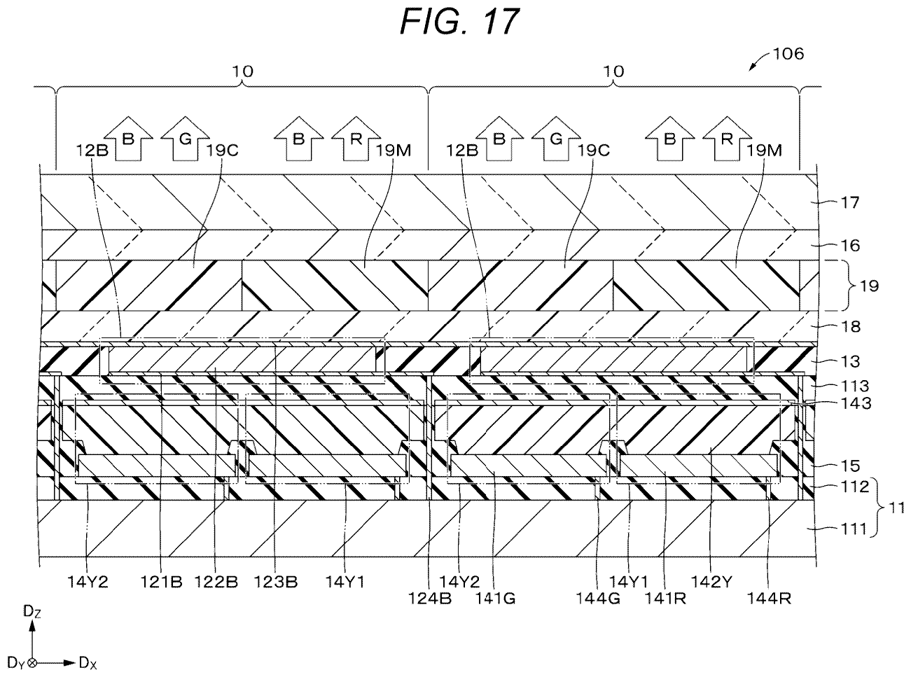

In the sixth embodiment, as illustrated in FIG. 16, an example in which the second electrode 143 is separately provided in the plurality of pixels 10 in the display region RE1 has been described. However, the configuration of the second electrode 143 is not limited to this example, and for example, the second electrode 143 may be shared by a plurality of pixels 10 in the display region RE1 as illustrated in FIG. 17. That is, the second electrode 143 may be connected between the pixels 10 adjacent in the in-plane direction in the display region RE1.

### (Modification 2)

In the sixth embodiment, as illustrated in FIG. 16, an example in which the second electrode 123B is shared by the plurality of inorganic LEDs 12B in the display region RE1 has been described. However, the configuration of the second electrode 123B is not limited to this example, and for example, as illustrated in FIG. 18, the second electrode 123B may be separately provided in the plurality of inorganic LEDs 12B (that is, the plurality of pixels 10) in the display region RE1. That is, the second electrode 123B may be divided between the inorganic LEDs 12B adjacent in the in-plane direction (that is, between the pixels 10 adjacent in the in-plane direction) in the display region RE1.

### <7 Seventh Embodiment>

[Configuration of display device 107]

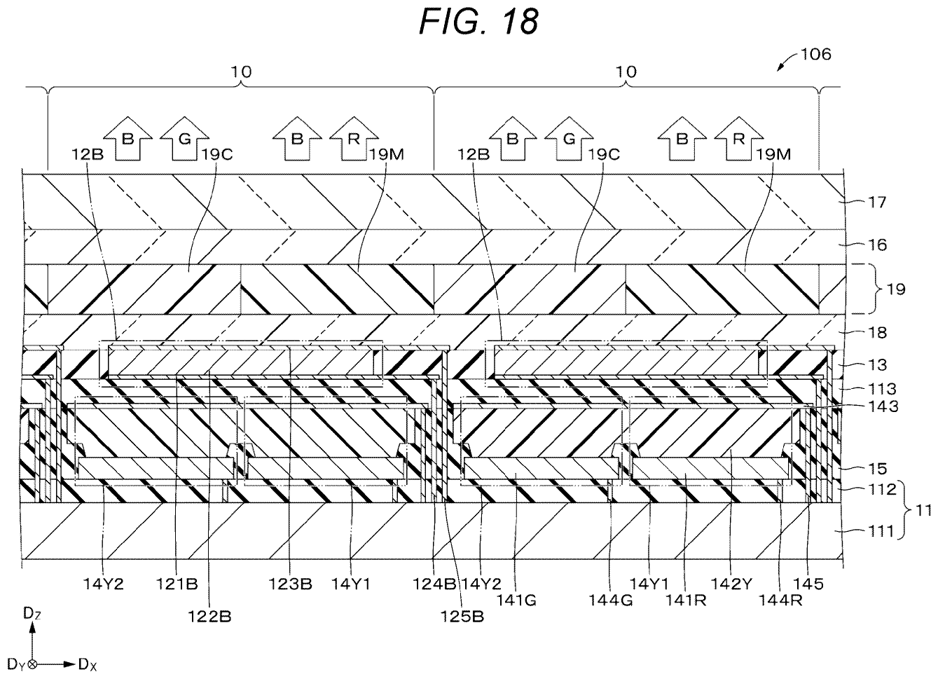

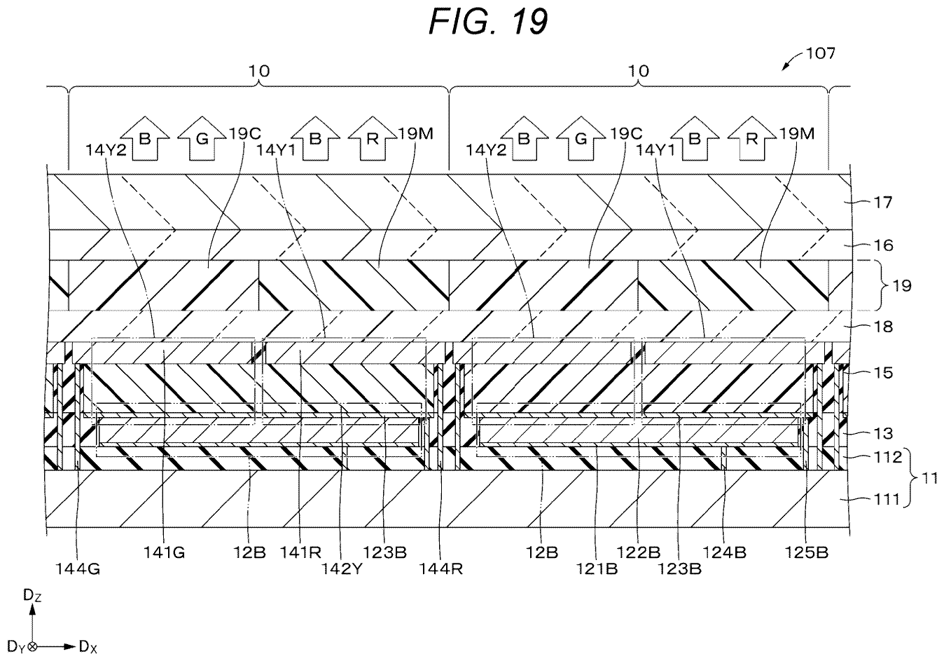

FIG. 19 is a cross-sectional view illustrating an example of a configuration of a display device 107 according to a seventh embodiment. The display device 107 is different from the display device 105 according to the fifth embodiment in that one inorganic LED 12B and two organic LEDs 14Y1 and 14Y2 included in each pixel 10 share the second electrode 123B.

The organic LED 14Y1 includes a second electrode 123B, an organic layer 142Y, and a first electrode 141R in order on the first surface of the inorganic layer 122B. The organic LED 14Y2 includes a second electrode 123B, an organic layer 142Y, and a first electrode 141G in order on the first surface of the inorganic layer 122B. The insulating layer 13 is provided on the first surface of the drive substrate 11 so as to expose the first main surface of the inorganic LED 12B, that is, the first surface of the second electrode 123B.

### [Operations and Effects]

In the display device 107 according to the seventh embodiment, one inorganic LED 12B and two organic LEDs 14Y1 and 14Y2 included in each pixel 10 share the second electrode 123B. As a result, the second electrode 143 in the display device 105 according to the fifth embodiment can be omitted. Therefore, the configuration of the display device 107 can be simplified as compared with the configuration of the display device 105.

### [Modifications]

In the seventh embodiment, as illustrated in FIG. 19, an example in which the second electrode 123B is separately provided in the plurality of pixels 10 in the display region RE1 has been described. However, the configuration of the second electrode 123B is not limited thereto, and for example, as illustrated in FIG. 20, the second electrode 123B may be shared by a plurality of pixels 10 in the display region RE1. That is, the second electrode 123B may be connected between the pixels 10 adjacent in the in-plane direction in the display region RE1.

### 8 Eighth Embodiment

### [Configuration of Display Device 108]

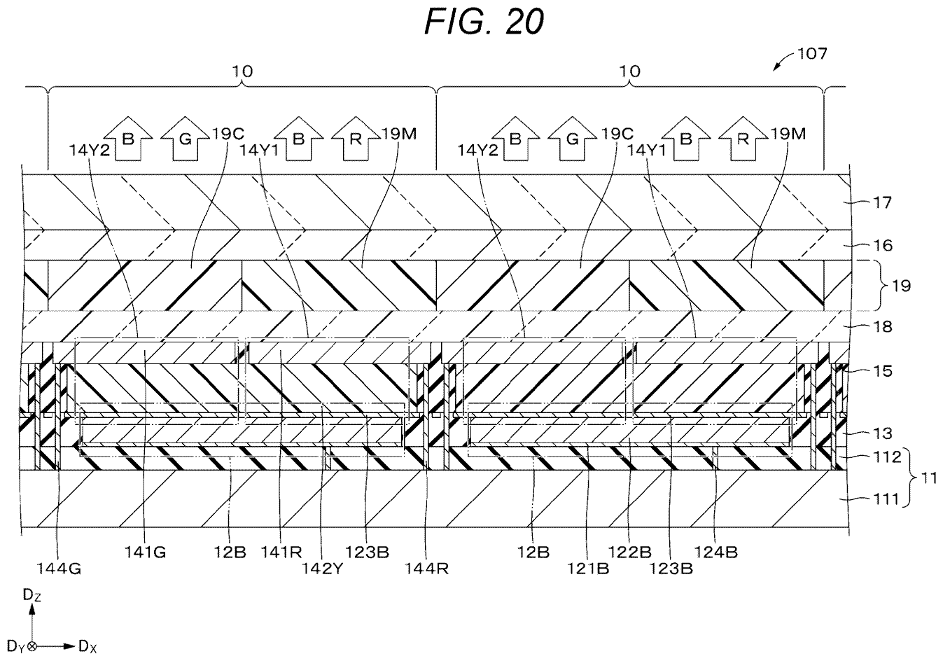

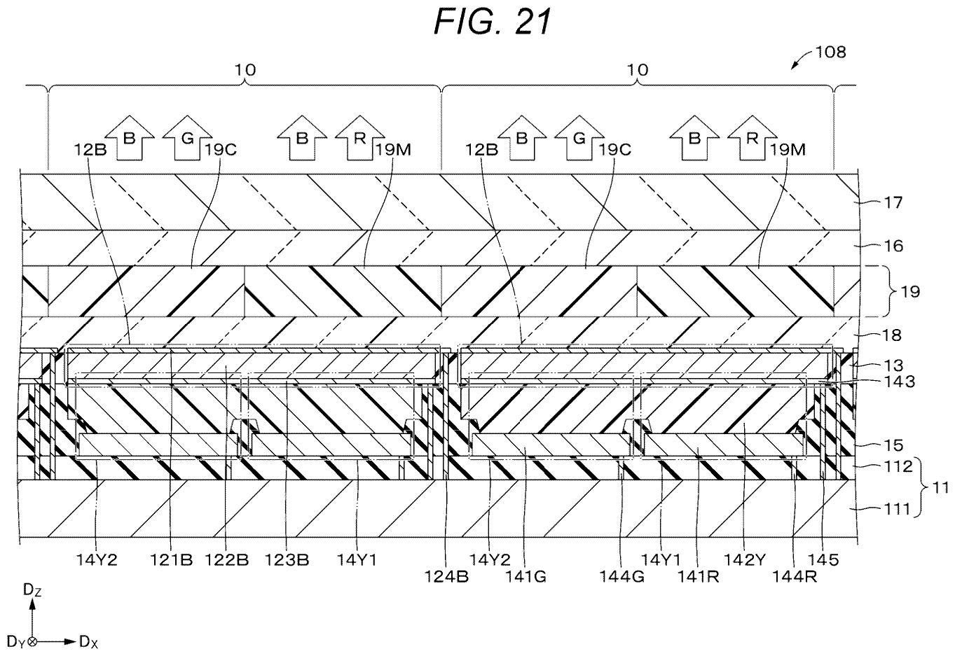

FIG. 21 is a cross-sectional view illustrating an example of a configuration of a display device 108 according to an eighth embodiment. The display device 108 is different from the display device 106 according to the sixth embodiment in that two organic LEDs 14Y1 and 14Y2 and one inorganic LED 12B included in each pixel 10 share the second electrode 143.

The inorganic LED 12B includes a second electrode 143, an inorganic layer 122B, and a first electrode 121B in order on the first surface of the organic layer 142Y.

### [Operations and Effects]

In the display device 108 according to the eighth embodiment, one inorganic LED 12B and two organic LEDs 14Y1 and 14Y2 included in each pixel 10 share the second electrode 123B. As a result, the second electrode 143 in the display device 106 according to the sixth embodiment can be omitted. Therefore, the configuration of the display device 108 can be simplified as compared with the configuration of the display device 106.

### [Modifications]

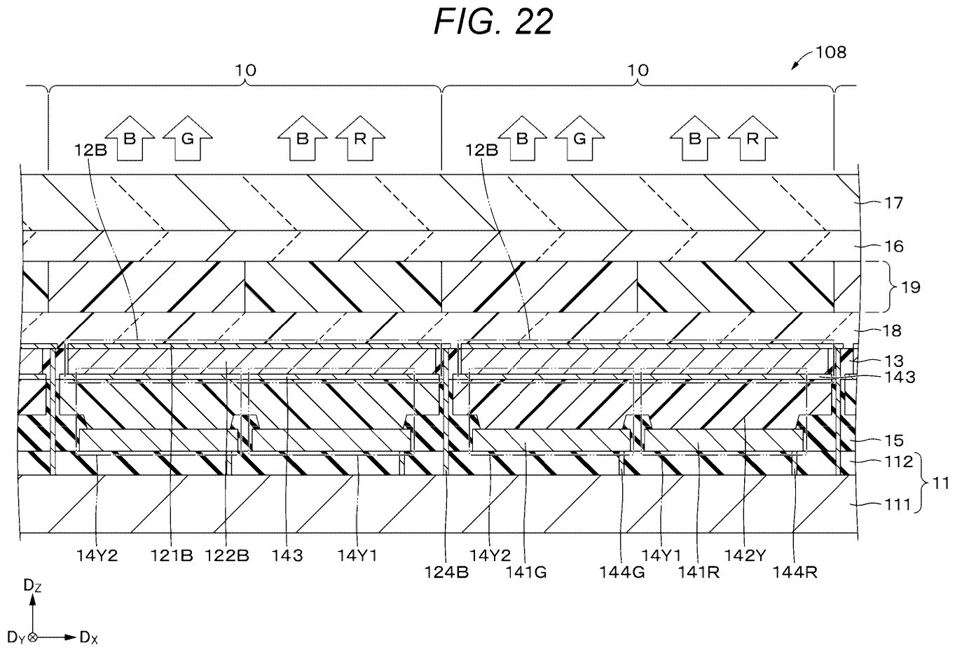

In the eighth embodiment, as illustrated in FIG. 21, an example in which the second electrode 143 is separately provided in the plurality of pixels 10 in the display region RE1 has been described. However, the configuration of the second electrode 123B is not limited thereto, and for example, the second electrode 143 may be shared by a plurality of pixels 10 in the display region RE1 as illustrated in FIG. 22. That is, the second electrode 143 may be connected between the pixels 10 adjacent in the in-plane direction in the display region RE1.

### 9 Ninth Embodiment

[Configuration of display device 109]

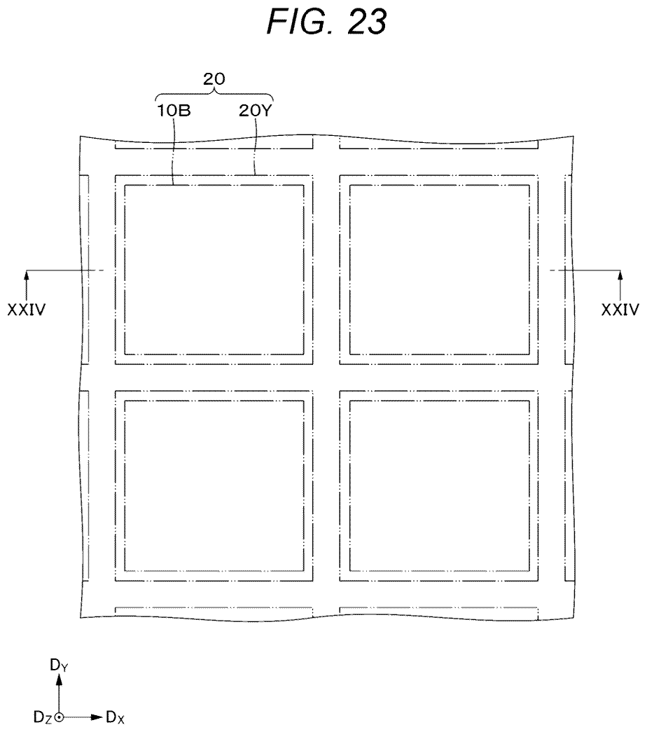

FIG. 23 is an enlarged plan view illustrating a part of a display region RE1 of a display device 109 according to a ninth embodiment. FIG. 24 is a cross-sectional view taken along line XXIV-XXIV of FIG. 23. The display device 109 is different from the display device 101 according to the first embodiment in including a plurality of pixels 10 instead of the plurality of pixels 20.

### (Pixel 20)

Each pixel 20 includes two subpixels of a subpixel 10B and a subpixel 20Y. The subpixel 10B is as described in the first embodiment.

The subpixel 20Y can emit yellow light. The subpixel 20Y includes an organic LED 21Y. The shape and area of the subpixel 20Y may be substantially the same as the shape and area of the subpixel 10B. The subpixel 20Y has, for example, a circular shape, an elliptical shape, or a rectangular shape in plan view. Note that FIG. 23 illustrates an example in which the subpixel 20Y has a rectangular shape in plan view.

### (Organic LED 21Y)

The peak wavelength of the emission light of the organic LED 21Y is longer than the peak wavelength of the emission light of the inorganic LED 12B. The color of the emission light of the organic LED 21Y is different from the color of the emission light of the inorganic LED 12B. The organic LED 21Y can emit yellow light.

The plurality of organic LEDs 21Y are provided in a layer different from the plurality of inorganic LEDs 12B. The plurality of organic LEDs 21Y are two-dimensionally arranged on the first surface of the insulating layer 13 in a prescribed arrangement pattern such as a matrix. One organic LED 21Y is provided above one inorganic LED 12B. The organic LED 21Y can transmit light emitted from the inorganic LED 12B. The area of the organic LED 21Y may be substantially the same as the area of the inorganic LED 21B.

The organic LED 21Y includes a first electrode 211Y, an organic layer 212Y, and a second electrode 213Y in order on the first surface of the insulating layer 13. The shape and area of the first electrode 211Y may be substantially the same as the shape and area of the inorganic LED 12B. The first electrode 211Y may be similar to the first electrodes 141R and 141G in the first embodiment in other points. The organic layer 212Y may be the same as the organic layer 142Y in the fifth embodiment. The second electrode 213Y is shared by the plurality of organic LEDs 21Y in the display region RE1. That is, the second electrode 213Y is connected between the organic LEDs 21Y adjacent in the in-plane direction in the display region RE1. The second electrode 213Y may be similar to the second electrode 143 in the first embodiment in other points.

### (Via 214Y)

The plurality of vias 214Y is provided inside the laminated insulating layers 112 and 13. The via 214Y is a connection member that electrically connects the first electrode 211Y of the organic LED 21Y and the drive circuit or wiring of the drive substrate 11. The via 214Y contains, for example, at least one metal selected from a group including copper (Cu), titanium (Ti), and the like.

### [Operations and Effects]

In the display device 109 according to the ninth embodiment, each pixel 20 includes one inorganic LED 12B and one organic LED 21Y provided above the one inorganic LED 12B. This makes it possible to increase the aperture ratio of the inorganic LED 12B and the organic LED 21Y as compared with a display device in which a plurality of organic LEDs or a plurality of inorganic LEDs is two-dimensionally arranged on the same surface. The aperture ratio of the inorganic LED 12B represents the area ratio of the light emitting region of the inorganic LED 12B per one pixel 20 as viewed from the front direction D_{Z}. The aperture ratio of the organic LED 21Y represents the area ratio of the light emitting region of the organic LED 21Y per pixel 20 as viewed from the front direction D_{Z}.

In addition, since miniaturization of the size of the inorganic LED 12B can also be suppressed, a decrease in the luminous efficiency of the inorganic LED 12B due to end surface damage due to miniaturization can also be suppressed.

### [Modifications]

### (Modification 1)

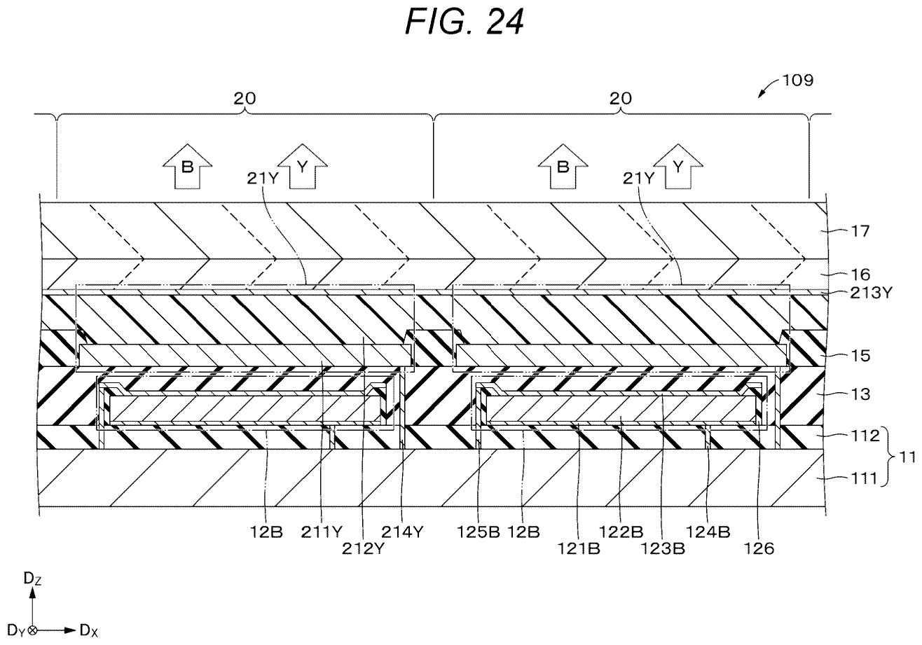

In the ninth embodiment, as illustrated in FIG. 24, an example has been described in which the second electrode 123B is separately provided in the plurality of inorganic LEDs 12B (that is, the plurality of pixels 20) in the display region RE1. However, the configuration of the second electrode 123B is not limited to this example, and for example, as illustrated in FIG. 25, the second electrode 123B may be shared by a plurality of inorganic LEDs 12B (that is, a plurality of pixels 20) in the display region RE1. That is, the second electrode 123B may be connected between the inorganic LEDs 12B adjacent in the in-plane direction (that is, between the pixels 20 adjacent in the in-plane direction) in the display region RE1.

### (Modification 2)

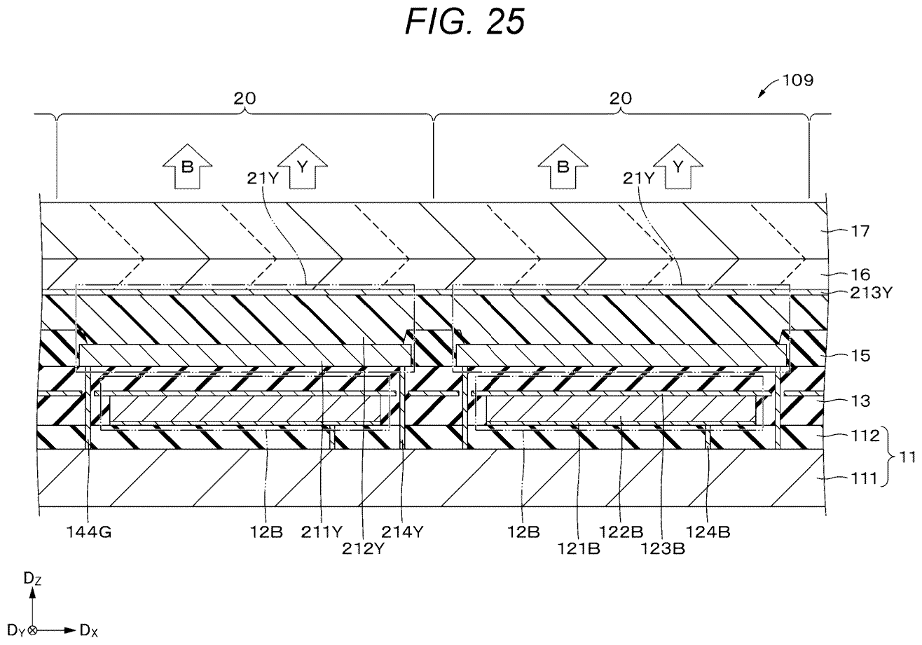

In the ninth embodiment, as illustrated in FIG. 24, the example in which the second electrode 143 is shared by the plurality of organic LEDs 14 in the display region RE1 has been described. However, the configuration of the second electrode 143 is not limited thereto, and for example, as illustrated in FIG. 26, the second electrode 143 may be separately provided in a plurality of pixels in the display region RE1. That is, the second electrode 143 may be divided between the pixels 20 adjacent in the in-plane direction in the display region RE1.

The organic layer 212Y has a plurality of holes. Each hole is provided at a position between the pixels 20 and penetrates in the thickness direction of the organic layer 212Y. The via 145 of each pixel 20 passes through the hole.

### 10 10th Embodiment

[Configuration of display device 110]

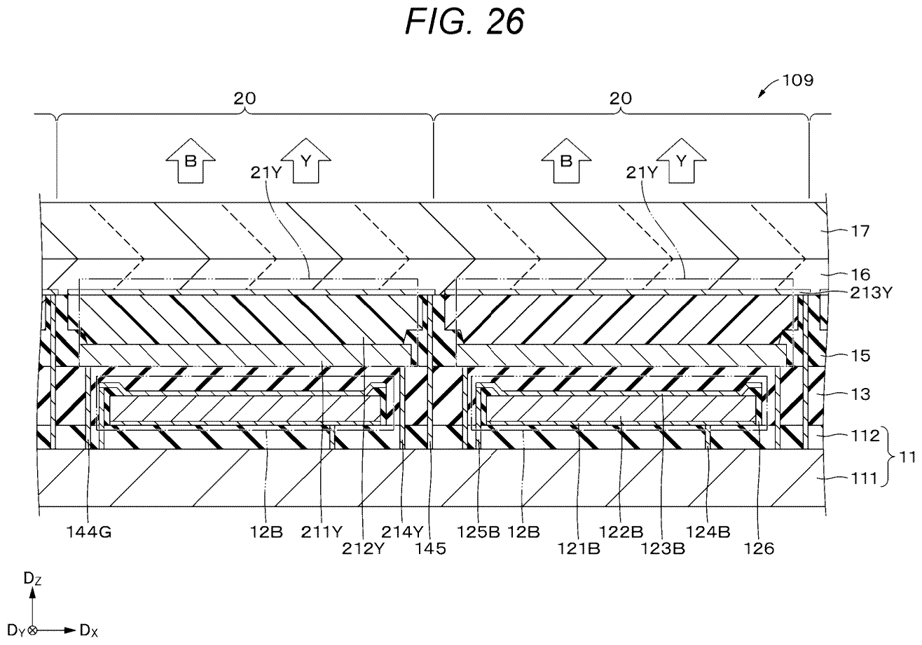

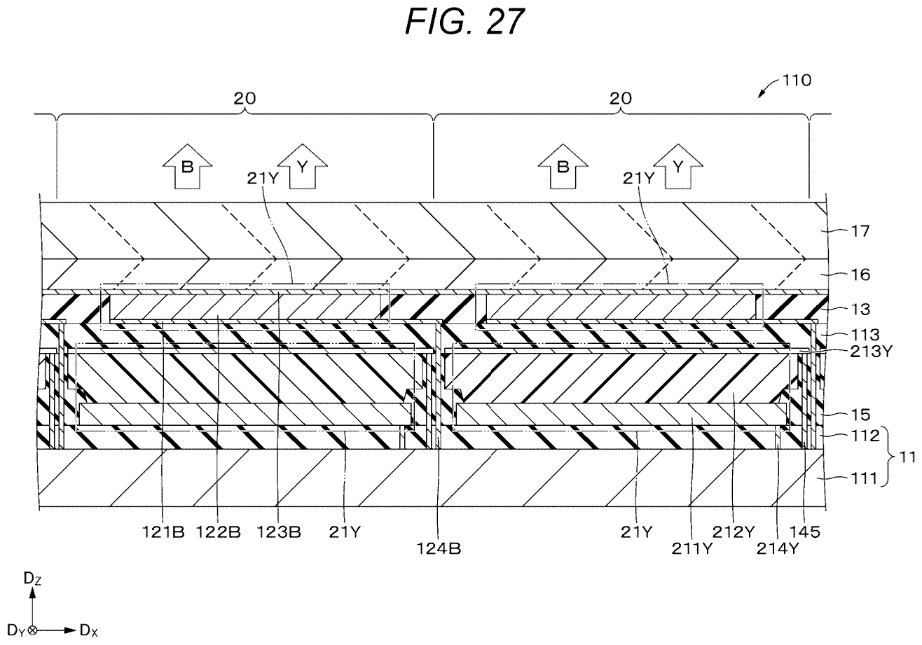

FIG. 27 is a cross-sectional view illustrating an example of a configuration of a display device 110 according to a 10th embodiment. The display device 110 is different from the display device 109 according to the ninth embodiment in that lamination positions of a plurality of inorganic LEDs 12B and a plurality of organic LEDs 21Y are interchanged, and one organic LED 21Y is provided below one inorganic LED 12B.

The inorganic LED 12B has translucency to yellow light emitted from the organic LED 21Y.

The second electrode 123B is shared by the plurality of inorganic LEDs 12B (that is, the pixel 20) in the display region RE1. That is, the second electrode 123B is connected between the inorganic LEDs 12B adjacent in the in-plane direction (that is, between the pixels 20 adjacent in the in-plane direction) in the display region RE1.

The plurality of second electrodes 213Y is separately provided in the plurality of pixels 20 in the display region RE1. That is, the second electrode 213Y is divided between the pixels 20 adjacent in the in-plane direction in the display region RE1.

The organic layer 212Y has a plurality of holes. Each hole is provided at a position between the pixels 20 and penetrates in the thickness direction of the organic layer 212Y. The vias 124B and 145 of each pixel 20 pass through the holes.

### [Operations and Effects]

In the display device 110 according to the 10th embodiment, each pixel 20 includes one inorganic LED 12B and one organic LED 21Y provided below the one inorganic LED 12B. Therefore, an effect similar to that of the display device 109 according to the ninth embodiment can be obtained.

### [Modifications]

### (Modification 1)

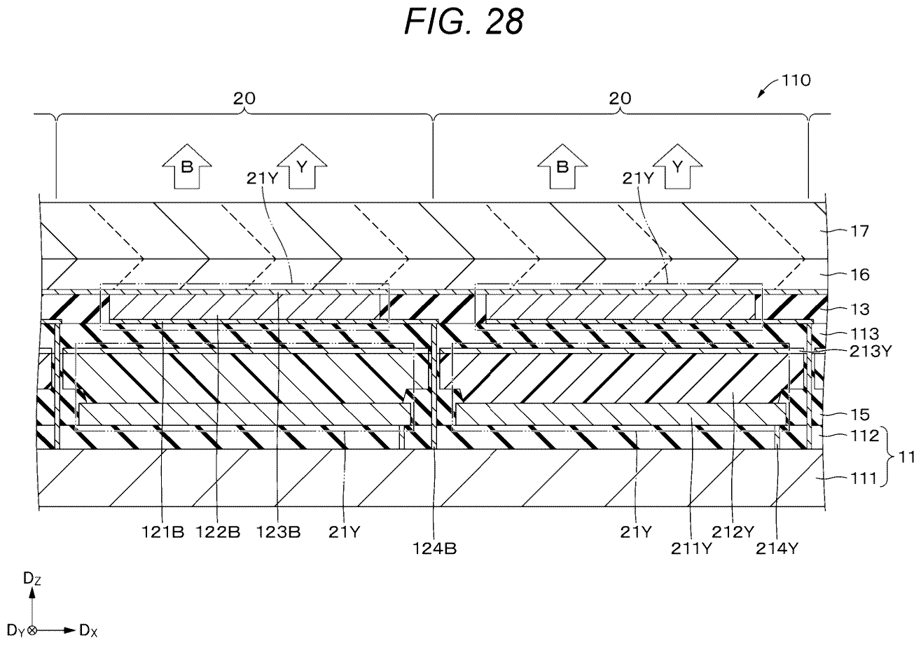

In the 10th embodiment, as illustrated in FIG. 27, an example in which the second electrode 213Y is separately provided in the plurality of pixels 20 in the display region RE has been described. However, the configuration of the second electrode 213Y is not limited to this example, and for example, the second electrode 213Y may be shared by a plurality of pixels 20 in the display region RE1 as illustrated in FIG. 28. That is, the second electrode 213Y may be connected between the pixels 20 adjacent in the in-plane direction in the display region RE1.

### (Modification 2)

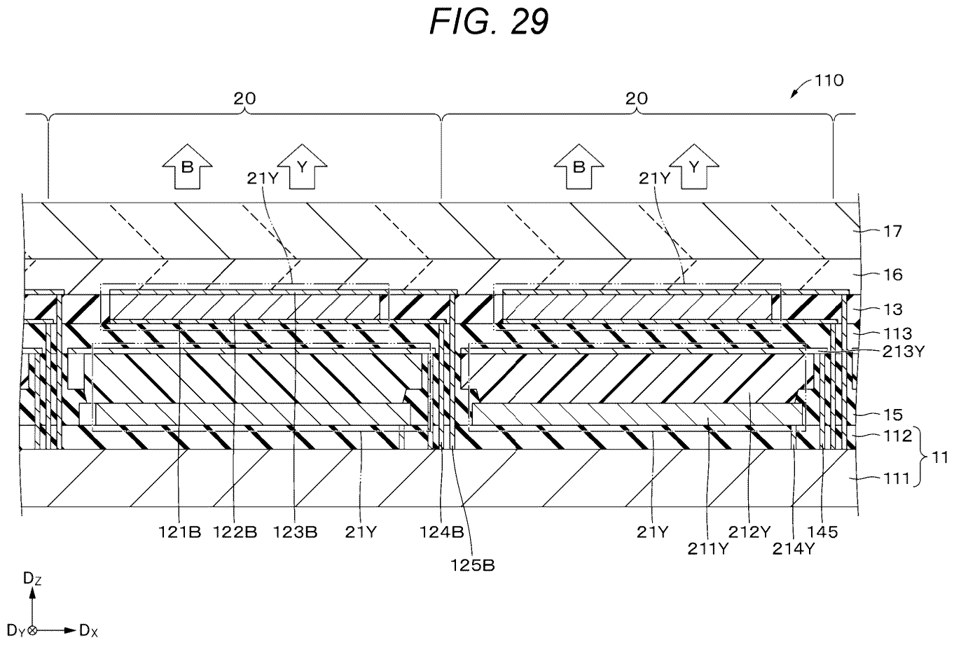

In the 10th embodiment, as illustrated in FIG. 27, an example in which the second electrode 123B is shared by the plurality of inorganic LEDs 12B in the display region RE1 has been described. However, the configuration of the second electrode 123B is not limited to this example, and for example, as illustrated in FIG. 29, the plurality of second electrodes 123B may be separately provided in the plurality of inorganic LEDs 12B (that is, the plurality of pixels 20) in the display region RE1. That is, the second electrode 123B may be divided between the inorganic LEDs 12B adjacent in the in-plane direction (that is, between the pixels 20 adjacent in the in-plane direction) in the display region RE1.

### 11 11th Embodiment

[Configuration of Display Device 110a]

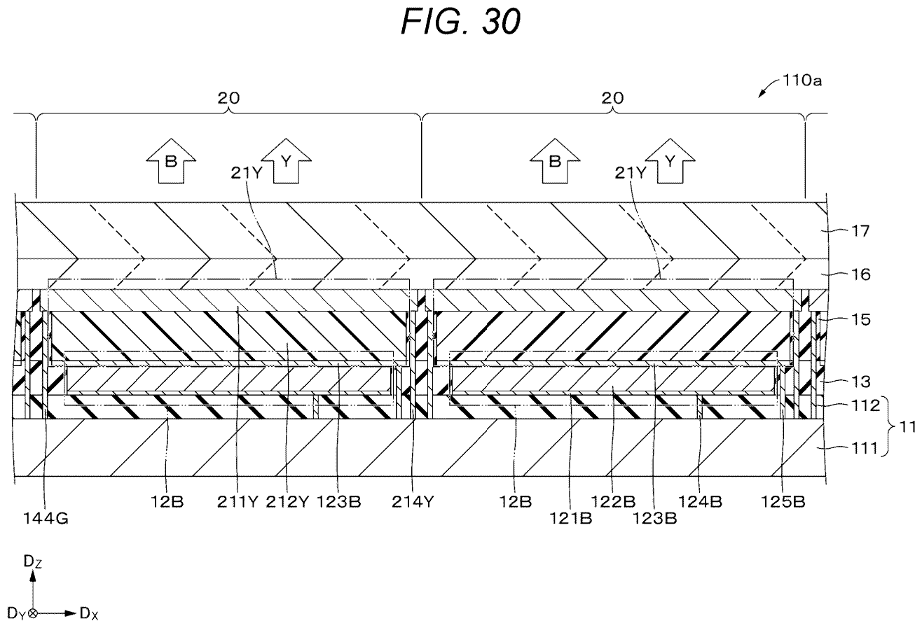

FIG. 30 is a cross-sectional view illustrating an example of a configuration of a display device 110a according to an 11th embodiment. The display device 110a is different from the display device 109 according to the ninth embodiment in that an inorganic LED 12B and an organic LED 21Y included in one pixel 10 share a second electrode 123B.

The organic LED 21Y includes a second electrode 123B, an organic layer 212Y, and a first electrode 211Y in order on the first surface of the inorganic layer 122B. The insulating layer 13 is provided on the first surface of the drive substrate 11 so that the first main surface of the inorganic LED 12B is exposed.

### [Operations and Effects]

In the display device 110a according to the 11th embodiment, one inorganic LED 12B and one organic LED 21Y included in each pixel 10 share the second electrode 123B. As a result, the second electrode 213Y in the display device 109 according to the ninth embodiment can be omitted. Therefore, the configuration of the display device 110a can be simplified as compared with the configuration of the display device 109.

### [Modifications]

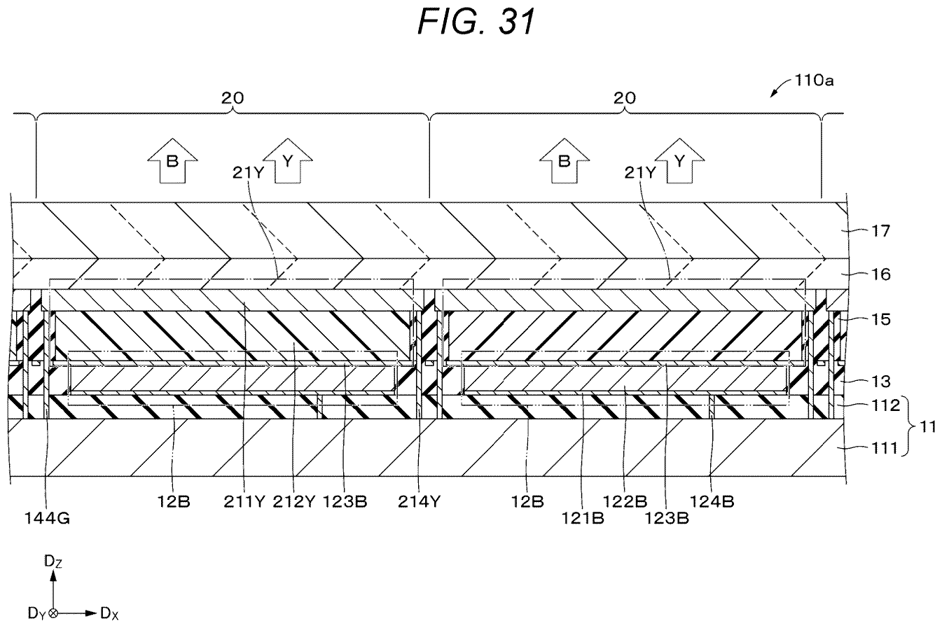

In the 11th embodiment, as illustrated in FIG. 30, an example in which the second electrode 123B is separately provided in the plurality of pixels 20 in the display region RE1 has been described. However, the configuration of the second electrode 123B is not limited thereto, and for example, as illustrated in FIG. 31, the second electrode 123B may be shared by a plurality of pixels 20 in the display region RE1. That is, the second electrode 123B may be connected between the pixels 20 adjacent in the in-plane direction in the display region RE1.

### 12 12th Embodiment

[Configuration of Display Device 110b]

FIG. 32 is a cross-sectional view illustrating an example of a configuration of a display device 110b according to a 12th embodiment. The display device 110b is different from the display device 110 according to the 10th embodiment in that one inorganic LED 12B and one organic LED 21Y included in each pixel 20 share the second electrode 213Y.

The inorganic LED 12B includes a second electrode 213Y, an inorganic layer 122B, and a first electrode 121B in order on the first surface of the organic layer 212Y.

### [Operations and Effects]

In the display device 110b according to the 12th embodiment, one inorganic LED 12B and one organic LED 21Y included in each pixel 20 share the second electrode 213Y. As a result, the second electrode 123B in the display device 110 according to the 10th embodiment can be omitted. Therefore, the configuration of the display device 110b can be simplified as compared with the configuration of the display device 110.

### [Modifications]

In the 12th embodiment, as illustrated in FIG. 32, an example in which the second electrode 213Y is separately provided in the plurality of pixels 20 in the display region RE1 has been described. However, the configuration of the second electrode 213Y is not limited thereto, and for example, as illustrated in FIG. 33, the second electrode 213Y may be shared by a plurality of pixels 20 in the display region RE1. That is, the second electrode 213Y may be connected between the pixels 20 adjacent in the in-plane direction in the display region RE1.

### 13 13th Embodiment

[Configuration of Display Device 110c]

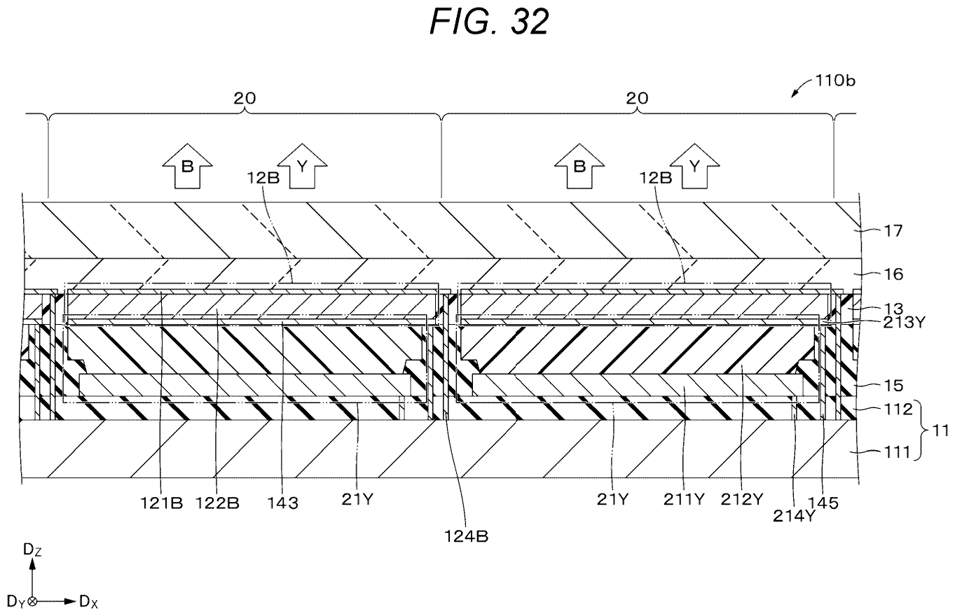

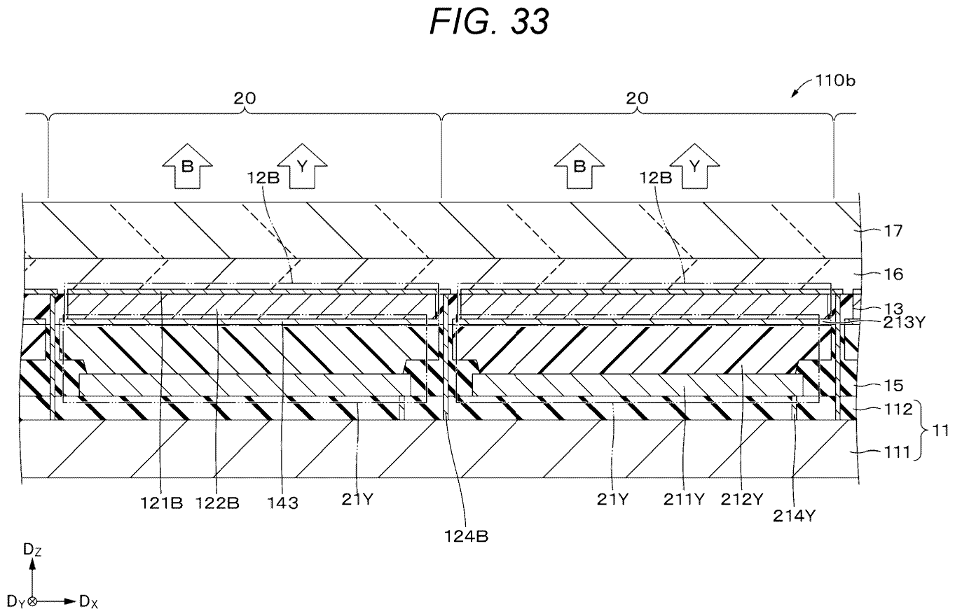

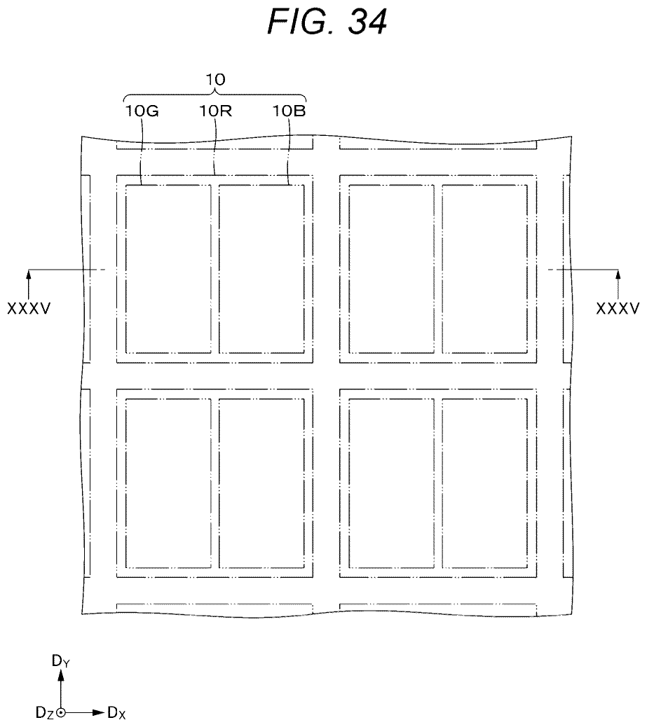

FIG. 34 is an enlarged plan view illustrating a part of a display region of a display device 110c according to a 13th embodiment. FIG. 35 is a cross-sectional view taken along line XXXV-XXXV of FIG. 34.

The display device 110c is different from the display device 105 according to the fifth embodiment in that the plurality of inorganic LEDs 12B, the plurality of organic LEDs 14Y1 and 14Y2, and the color filter 19 are replaced with a plurality of inorganic LEDs 22BG1 and 22BG2, a plurality of organic LEDs 23R, and a color filter 24. In the following description, in a case where the inorganic LEDs 22BG1 and 22BG2 are not particularly distinguished and collectively referred to, they are simply referred to as inorganic LEDs 22BG.

### (Inorganic LEDs 22BG1, 22BG2)

The inorganic LEDs 22BG1 and 22BG2 can simultaneously emit blue light and green light. The emission light of the inorganic LEDs 22BG1 and 22BG2 has two peak wavelengths. The two peak wavelengths of the emission light of the inorganic LEDs 22BG1 and 22BG2 are shorter than the peak wavelength of the emission light of the organic LED 23R. The color of the emission light of the inorganic LEDs 22BG1 and 22BG2 is different from the color of the emission light of the organic LED 23R.

The plurality of inorganic LEDs 22BG1 and 22BG2 is provided in the same layer. The plurality of inorganic LEDs 22BG1 and 22BG2 is two-dimensionally arranged on the first surface of the drive substrate 11 in a prescribed arrangement pattern such as a matrix shape. One pixel 10 includes the two inorganic LEDs 22BG1 and 22BG2. The two inorganic LEDs 22BG1 and 22BG2 are provided below the organic LED 23R. The area of the inorganic LED 22BG1 is smaller than the area of the organic LED 14R, and the area of the inorganic LED 22BG2 is smaller than the area of the organic LED 14R. The area of the inorganic LED 22BG1 and the area of the inorganic LED 22BG2 may be substantially the same.

The inorganic LED 22BG1 has a two-stack structure. The inorganic LED 22BG1 includes a first electrode 221, an inorganic layer 222BG, and a second electrode 223 in order on the first surface of the drive substrate 11. The inorganic LED 22BG1 may include a substrate between the first electrode 221 and the inorganic layer 222BG or between the inorganic layer 222BG and the second electrode 223 as necessary.

The inorganic LED 22BG2 also has a two-stack structure similarly to the inorganic LED 22BG1. Since the inorganic LED 22BG2 has the similar configuration to that of the inorganic LED 22BG1, the description of the configuration of the inorganic LED 22BG2 will be omitted.

### (Inorganic Layer 222BG)

The inorganic layer 222BG includes a first inorganic light emitting layer and a second inorganic light emitting layer. The first inorganic light emitting layer can emit blue light. The second inorganic light emitting layer can emit green light. The inorganic layer 222BG includes a first compound semiconductor laminate 222B, a charge generation layer (not illustrated), and a second compound semiconductor laminate 222G in order on the first surface of the first electrode 221. The first compound semiconductor laminate 222B includes a first inorganic light emitting layer. The second compound semiconductor laminate 222G includes a second inorganic light emitting layer.

### (First Electrode 221)

The first electrode 221 is provided on a second surface side of the inorganic layer 222BG. The first electrode 221 is separately provided in the plurality of inorganic LEDs 22BG in the display region RE1. That is, the first electrode 221 is divided between the inorganic LEDs 22BG adjacent in the in-plane direction in the display region RE1. The first electrode 221 is an anode.

As a material of the first electrode 221, a material similar to that of the first electrode 121B in the first embodiment can be exemplified.

### (Second Electrode 223)

The second electrode 223 is provided on the first surface side of the inorganic layer 122B. The second electrode 223 is shared by the inorganic LED 22BG1 and the inorganic LED 22BG1 included in one pixel 10. That is, the second electrode 223 is divided between the inorganic LED 22BG1 and the inorganic LED 22BG1 included in one pixel 10 (that is, between the subpixels 10B and 10G adjacent in the in-plane direction). The second electrode 223 is a cathode.

As a material of the second electrode 223, a material similar to that of the second electrode 123B in the first embodiment can be exemplified.

### (Inter-Element Separation Layer 226)

The display device 110c includes an inter-element separation layer 226. The inter-element separation layer 226 is provided between the inorganic LED 22BG1 and the inorganic LED 22BG2. The inter-element separation layer 226 is a layer having higher resistance than the inorganic layer 222BG, and is preferably an insulating layer. The inter-element separation layer 226 is formed, for example, by laminating a compound semiconductor such as GaN, fabricating one inorganic layer 222BG, and then implanting low-concentration boron ions into a region corresponding to a formation position of the inter-element separation layer 226.

### (Vias 224, 225)

The plurality of vias 224 is provided inside the insulating layer 112. The plurality of vias 225 is provided inside the laminated insulating layer 112 and insulating layer 13. The via 224 is a connection member that electrically connects the first electrode 221 of the inorganic LEDs 22BG1 and 22BG2 and the drive circuit or wiring of the drive substrate 11. The via 225 is a connection member that electrically connects the second electrode 223 of the inorganic LEDs 22BG1 and 22BG2 and the drive circuit or wiring of the drive substrate 11. The vias 224 and 225 contain, for example, at least one metal selected from a group including copper (Cu), titanium (Ti), and the like.

### (Organic LED 23R)

The peak wavelength of the emission light of the plurality of organic LEDs 23R is longer than the peak wavelength of the emission light of the inorganic LEDs 22BG1 and 22BG2. The color of the emission light of the organic LED 23R is different from the color of the emission light of the inorganic LEDs 22BG1 and 22BG2. The organic LED 23R can emit red light.

The plurality of organic LEDs 23R is two-dimensionally arranged on the first surface of the insulating layer 13 in a prescribed arrangement pattern such as a matrix. The plurality of organic LEDs 23R is provided in a layer different from the inorganic LEDs 22BG1 and 22BG2. One organic LED 23R is provided above the two inorganic LEDs 22BG1 and 22BG2. The organic LED 23R can transmit light emitted from the inorganic LED 12B. The area of the organic LED 23R is, for example, substantially equal to the sum of the area of the inorganic LED 22BG1 and the area of the inorganic LED 22BG2.

The organic LED 23R includes a first electrode 231R, an organic layer 232R, and a second electrode 233R in order on the first surface of the insulating layer 13. The first electrode 231R and the second electrode 233R are similar to the first electrode 211Y and the second electrode 213Y in the ninth embodiment.

The organic layer 232R is similar to the organic layer 212Y in the ninth embodiment except that red light can be emitted. The layer configuration of the organic layer 232R may be similar to that of the organic layer 142R in the first embodiment. FIG. 35 illustrates an example in which the organic layer 232R is divided between the pixels 10 adjacent in the in-plane direction, but the organic layer 232R may be connected between the pixels 10 adjacent in the in-plane direction.

### (Color Filter 24)

The color filter 24 is an example of the color conversion layer. The color filter 24 is provided above the plurality of organic LEDs 23R. More specifically, the color filter 19 is provided on the first surface of the protective layer 18. The color filter 19 includes, for example, a plurality of filter units 24Y and a plurality of filter units 24M.

The plurality of filter units 24Y and 24M are two-dimensionally arranged in the in-plane direction. The filter units 24Y and 24M are examples of color conversion units. The filter unit 24Y has a yellow color. The filter unit 24M has a cyan color. The filter unit 24Y is provided above the inorganic LED 22BG1 out of the two inorganic LEDS 22BG1 and 22BG2 included in the pixel 10. The filter unit 24M is provided above the inorganic LED 22BG2 of the two inorganic LEDs 22BG1 and 22BG2 included in the pixel 10.

The filter unit 24Y transmits red light emitted from the organic LED 22R and green light emitted from the inorganic LED 22GB1, and absorbs blue light emitted from the inorganic LED 22GB1. The filter unit 24M transmits red light emitted from the organic LED 23R and blue light emitted from the inorganic LED 22GB2, and absorbs green light emitted from the inorganic LED 22GB2.

The filter unit 24Y includes, for example, a yellow color resist. The filter unit 24M includes, for example, a magenta color resist.

### (Pixel 10)

Each pixel 10 includes three subpixels of a subpixel 10R, a subpixel 10G, and a subpixel 10B. The area of the subpixel 10R is larger than the area of the subpixel 10B and larger than the area of the subpixel 10G. The area of the subpixel 10R is, for example, substantially equal to the sum of the area of the subpixel 10B and the area of the subpixel 10G. The subpixel 10R includes an organic LED 23R. The subpixel 10G includes an inorganic LED 22GB1 and a filter unit 24Y. The subpixel 10B includes an inorganic LED 22GB2 and a filter unit 24M.

### [Operations and Effects]

In the display device 105 (see FIG. 13) according to the fifth embodiment, it is difficult to separately produce thin film transistors (TFTs) of the inorganic LED 12B and the organic LED 14Y, and thus, a circuit configuration in which the inorganic LED 12B and the organic LED 14Y can be driven at the same voltage is preferable.

However, in general, a voltage V₁ (for example, V₁=3.6 V) necessary for driving the inorganic LED 12B is lower than a voltage V₂ (for example, V₂=6.0 V) necessary for driving the organic LED 14Y. Therefore, when a circuit configuration in which the inorganic LED 12B and the organic LED 14Y are driven at the same voltage V₂ is adopted, power consumption in the inorganic LED 12B is wasted.

On the other hand, in the display device 110c according to the 13th embodiment, inorganic LEDs having a two-stack structure are provided as the inorganic LEDs 22BG1 and 22BG2. As a result, the voltage V₁ necessary for driving the inorganic LEDs 22BG1 and 22BG2 and the voltage V₂ necessary for the organic LED 23R can be made equal or substantially equal. For example, both of the voltages V₁ and V₂ can be set to V₁ and V₂=6.0 V. Therefore, the power consumption of the display device 110c according to the 13th embodiment can be reduced as compared with the display device 105 according to the fifth embodiment.

Table 1 illustrates an example of power consumption of the display device 105 according to the fifth embodiment and the display device 110c according to the 13th embodiment.

TABLE 1

| | FIFTH | | | 13TH | | |
|---|---|---|---|---|---|---|
| | EMBODIMENT | | | EMBODIMENT | | |
| SUBPIXEL | B | G | R | B | G | R |
| LUMINOUS | 1 | 0.5 | 0.5 | 1 | 1 | 1 |
| EFFICIENCY | | | | | | |
| CURRENT [A] | 1 | 2 | 2 | 1 | 1 | 1 |

| | | |
|---|---|---|
| VOLTAGE [V] | 6.0 | 6.0 |
| POWER | 30 | 18 |
| CONSUMPTION | | |
| [V · A] | | |

In the display device 110c according to the 13th embodiment, since the inorganic LEDs 22BG1 and 22BG2 have a two-stack structure, the voltage V₁ necessary for driving the inorganic LEDs 22BG1 and 22BG2 can be equal to the voltage V₂ necessary for the organic LED 23R. Therefore, the power consumption of the display device 105 according to the fifth embodiment can be reduced by 40%.

### [Modifications]

### (Modification 1)

In the 13th embodiment, as shown in FIG. 35, an example in which the inorganic layer 222BG includes the first compound semiconductor laminate 222B, the charge generation layer (not shown), and the second compound semiconductor laminate 222G in order on the first surface of the first electrode 221 has been described, but the order of lamination of the layers is not limited to this example. For example, as illustrated in FIG. 36, the inorganic layer 222BG may include a second compound semiconductor laminate 222G, a charge generation layer (not illustrated), and a first compound semiconductor laminate 222B in order on the first surface of the first electrode 221.

### (Modification 2)

In the 13th embodiment, the example in which one organic LED 23R is provided above the two inorganic LEDs 22BG1 and 22BG2 in each pixel 10 has been described, but one organic LED 23R may be provided below the two inorganic LEDs 22BG1 and 22BG2 in each pixel 10.

### (Modification 3)

In the 13th embodiment, an example in which the inorganic LEDs 22BG1 and 22BG2 include the second electrode 223 and the organic LED 23R includes the second electrode 233R has been described, but the inorganic LEDs 22BG1 and 22BG2 and the organic LED 23R may share the second electrode 223. As in Modification 2, in each pixel 10, in a case where one organic LED 23R is provided below two inorganic LEDs 22BG1 and 22BG2, the organic LED 23R and the inorganic LEDs 22BG1 and 22BG2 may share the second electrode 233R.

### (Modification 4)

In the 13th embodiment, an example in which the display device 110c includes the color filter 24 as the color conversion layer has been described, but the display device 110c may include a dielectric multilayer film or a quantum dot layer as the color conversion layer.

### 14 14th Embodiment

[Configuration of Display Device 110d]

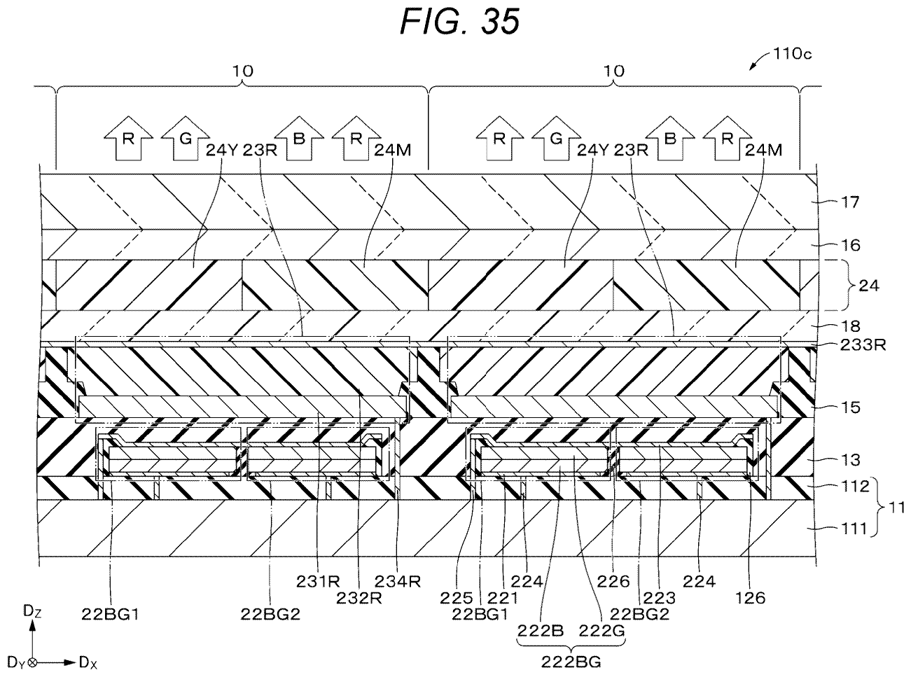

FIG. 37 is a cross-sectional view illustrating an example of a configuration of a display device 110d according to a 14th embodiment. The display device 110d is different from the display device 105 according to the fifth embodiment in including the lens array 25. The lens array 25 is provided between the color filter 19 and the protective layer 16. The display device 110d may further include a flattening layer (not illustrated) between the color filter 19 and the lens array 25.

The lens array 25 includes a plurality of lenses 25L. The lens 25L may be an on-chip microlens (OCL). The plurality of lenses 25L is two-dimensionally arranged on the first surface of the color filter 19 or the flattening layer in a prescribed arrangement pattern. One pixel 10 includes two lenses 25L. One lens 25L of the two lenses 25L included in one pixel 10 is provided on the first surface of the filter unit 19M or above the filter unit 19M, and the other lens 25L is provided on the first surface of the filter unit 19C or above the filter unit 19C. The lens 25L condenses the light emitted upward from the filter units 19M and 19C in the front direction D_{Z}. The lens 25L has, for example, a convex curved surface protruding in the front direction D_{Z}. The convex curved surface has, for example, a dome shape. Here, the dome shape includes shapes such as a substantially parabolic shape, a substantially hemispherical shape, and a substantially semi-elliptical surface.

The lens 25L contains, for example, an inorganic material or a polymer resin transparent to visible light. The inorganic material includes, for example, silicon oxide (SiOₓ). The polymer resin contains, for example, an ultraviolet curable resin.

### [Operations and Effects]

In the display device 110d according to the 14th embodiment, since the lens array 25 is provided on or above the color filter 19, the light emitted from the filter units 19C and 19M can be condensed in the front direction D_{Z} by the lens 25L. Therefore, since the light extraction efficiency can be further improved, the luminance can be further improved.

### [Modification 1]

### (Modification 1)

In the 14th embodiment, an example in which the lens array 25 is provided between the color filter 19 and the protective layer 16 has been described, but the arrangement position of the lens array 25 is not limited to this example.

For example, the lens array 25 may be provided between the plurality of organic LEDs 14Y1 and Y2 and the color filter 19. More specifically, the lens array 25 may be provided on the second surface of the color filter 19, or may be provided on the first surface of the plurality of organic LEDs 14Y1 and Y2. In a case where the lens array 25 is provided on the second surface of the color filter 19, the lens 25L has, for example, a convex curved surface protruding in a direction opposite to the front direction D_{Z}.

For example, the lens array 25 may be provided between the plurality of inorganic LEDs 12B and the organic LEDs 14Y1 and Y2. More specifically, each lens 25L configuring the lens array 25 may be provided on the first surface of the inorganic LED 12B.

### (Modification 2)

In the 14th embodiment, an example in which the lens array 25 is applied to the display device 105 according to the fifth embodiment has been described. However, the lens array 25 may be applied to the display devices 101, 102, . . . , and 110c according to the first to fourth and sixth to 13th embodiments.

### 15 15th Embodiment

In the first embodiment, an example in which the organic layer 142R and the organic layer 142G are individually provided for each pixel 10 has been described (see FIG. 48). In a 15th embodiment, an example in which an organic layer 142R and an organic layer 142G are shared by adjacent pixels 10 will be described.

### [Configuration of Display Device 601]

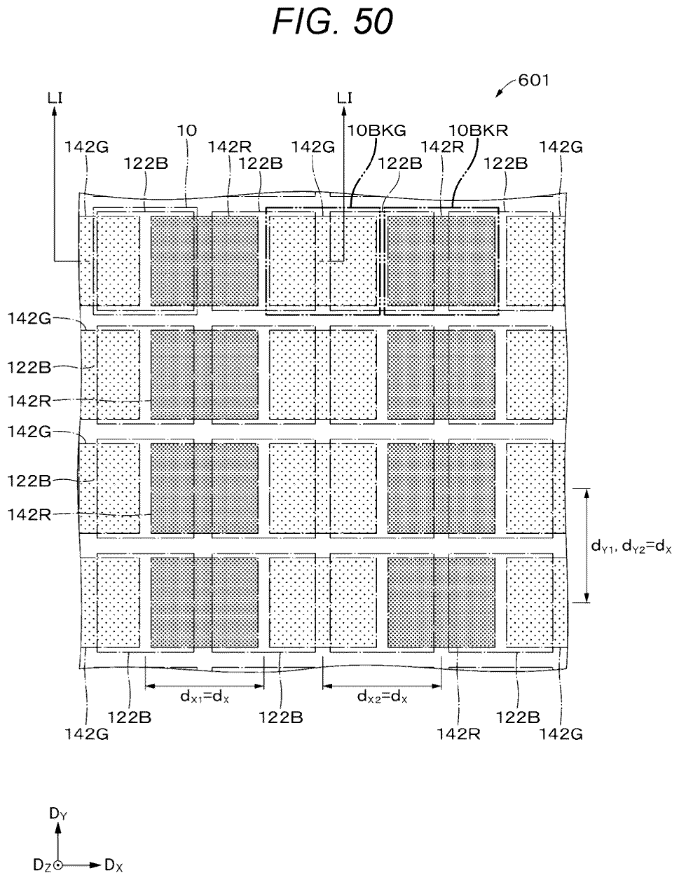

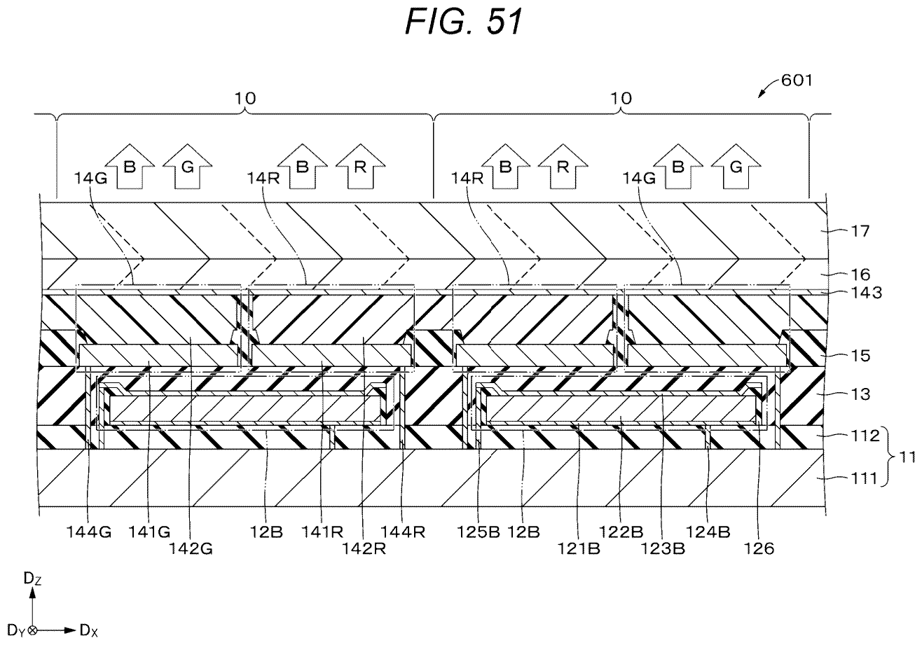

FIG. 50 is an enlarged plan view illustrating a part of the display region RE1 of the display device 601 according to the 15th embodiment. FIG. 51 is a cross-sectional view taken along line LI-LI in FIG. 50. In the present specification, a block including two subpixels 10R in the horizontal direction D_{X} and n subpixels 10R in the vertical direction D_{Y} is referred to as a “(2×n)-subpixel block 10BKR”, and a block including two subpixels 10G in the horizontal direction D_{X} and m subpixels 10G in the vertical direction D_{Y} is referred to as a “(2×m)-subpixel block 10BKG”. For example, a block including two subpixels 10R in the horizontal direction D_{X} and one subpixel 10R in the vertical direction D_{Y} is referred to as a “(2×1)-subpixel block 10BKR”, and a block including two subpixels 10G in the horizontal direction D_{X} and one subpixel 10G in the vertical direction D_{Y} is referred to as a “(2×1)-subpixel block 10BKG”. Hereinafter, a case where the values of n and m are equal will be described as an example, but the values of n and m may be different.

The plurality of (2×1)-subpixel blocks 10BKR is arranged in one column in the vertical direction D_{Y}, and the plurality of (2×1)-subpixel blocks 10BKG is arranged in one column in the vertical direction D_{Y}. The columns of the (2×1)-subpixel block 10BKR and the columns of the (2×1)-subpixel block 10BKG are alternately arranged in the horizontal direction D_{X}.

Two organic LEDs 14R (that is, two subpixels 10R) included in the (2×1)-subpixel block 10BKR share one organic layer 142R. The two organic LEDs 14R (that is, the two subpixels 10R) included in the (2×1)-subpixel block 10BKR are included in the separate pixels 10.

Two organic LEDs 14G (that is, two subpixels 10G) included in the (2×1)-subpixel block 10BKG share one organic layer 142G. The two organic LEDs 14G (that is, the two subpixels 10G) included in the (2×1)-subpixel block 10BKG are included in the separate pixels 10.

Similarly to the first embodiment, each pixel 10 in the 15th embodiment includes three subpixels of a subpixel 10R, a subpixel 10G, and a subpixel 10B.

The plurality of organic layers 142R and the plurality of organic layers 142G are two-dimensionally arranged on the first surface of the drive substrate 11 in a matrix-like arrangement pattern so as to be aligned in the horizontal direction D_{X} and the vertical direction D_{Y}. More specifically, the plurality of organic layers 142R is arranged in one row in the vertical direction D_{Y}, and the plurality of organic layers 142G is arranged in one row in the vertical direction D_{Y}. The columns of the organic layers 142R and the columns of the organic layers 142G are alternately arranged in the horizontal direction D_{X}. As described above, in the present specification, the organic layers 142R and 142G are referred to as the organic layer 142 when being collectively referred without being particularly distinguished. The plurality of inorganic layers 122B is two-dimensionally arranged on the first surface of the drive substrate 11 in a matrix-like arrangement pattern so as to be aligned in the horizontal direction D_{X} and the vertical direction D_{Y}.

An arrangement pitch d_{X1} of the inorganic layer 122B in the horizontal direction D_{X} and an arrangement pitch d_{X2} of the organic layer 142 in the horizontal direction D_{X} are equal to an arrangement pitch d_{X} of the pixels 10 in the horizontal direction D_{X}. An arrangement pitch d_{Y1} of the inorganic layer 122B in the vertical direction D_{Y} and an arrangement pitch d_{Y2} of the organic layer 142 in the vertical direction D_{Y} are equal to an arrangement pitch d_{Y} of the pixels 10 in the vertical direction D_{Y}.

The arrangement position of the inorganic layer 122B in the horizontal direction D_{X} is aligned with the arrangement position of the pixel 10 in the horizontal direction D_{X}. The arrangement position of the organic layer 142 in the horizontal direction D_{X} is shifted by d_{X}/2 (half the arrangement pitch d_{X} of the pixels 10) from the arrangement position of the pixels 10 in the horizontal direction D_{X}. As a result, the organic layer 142 is disposed so as to cross between two pixels 10 adjacent in the horizontal direction D_{X}.

The arrangement position of the inorganic layer 122B in the vertical direction D_{Y} is aligned with the arrangement position of the pixel 10 in the vertical direction D_{Y}. Similarly, the arrangement position of the organic layer 142 in the vertical direction D_{Y} is aligned with the arrangement position of the pixel 10 in the vertical direction D_{Y}.

### [Operations and Effects]

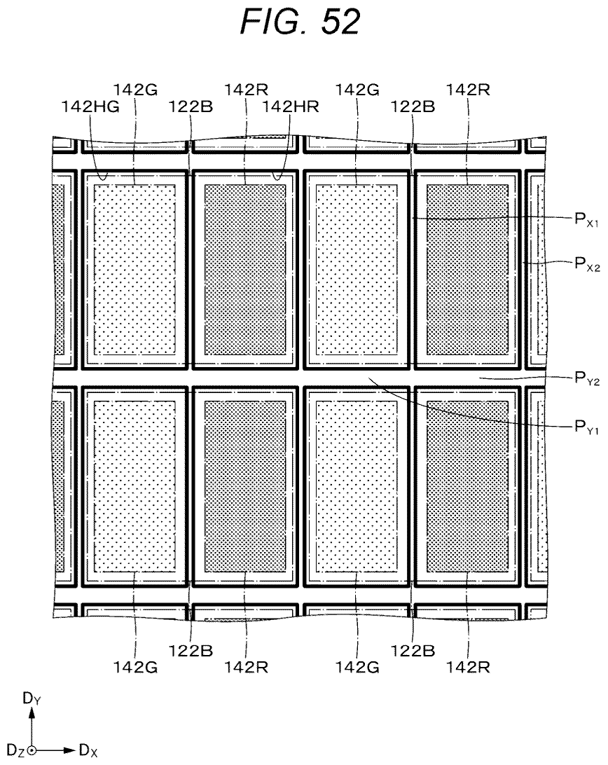

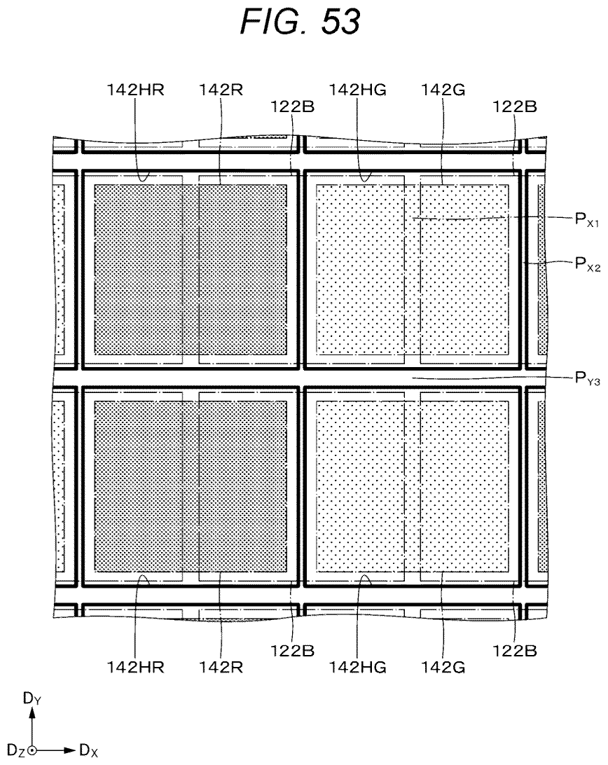

Hereinafter, with reference to FIGS. 52 and 53, processes of forming the organic layer 142R and the organic layer 142G in the first embodiment and the 15th embodiment will be described in comparison.

The organic layer 142R and the organic layer 142G are formed by, for example, a vapor deposition method. In this forming process, a mask is disposed to face the first surface of the drive substrate 11 in order to apply different materials for forming the organic layer 142R and the organic layer 142G. In FIGS. 52 and 53, a thick frame line surrounding the organic layer 142R represents the position of an opening 142HR of the mask at the time of forming the organic layer 142R, and in FIGS. 52 and 53, a thick frame line surrounding the organic layer 142G represents the position of an opening 142HG of the mask at the time of forming the organic layer 142G.

In the process of forming the organic layer 142R and the organic layer 142G in the first embodiment, as illustrated in FIG. 52, alignment of the opening 142HR in units of one subpixel 10R and alignment of the opening 142HG in units of one subpixel 10G are required. That is, alignment is required at each of the positions P_{X1}, P_{X2}, P_{Y1}, and P_{Y2} between the adjacent openings 142HR and 142HG.

On the other hand, in the process of forming the organic layer 142R and the organic layer 142G in the 15th embodiment, as illustrated in FIG. 53, the alignment of the opening 142HR in units of the two subpixels 10R and the alignment of the opening 142HG in units of the two subpixels 10G can be completed, so that the alignment of the position P_{X1} can be omitted. In addition, one alignment of the positions P_{Y3} can be performed instead of the alignment of the two positions P_{Y1} and P_{Y2}. Therefore, the alignment accuracy of the openings 142HR and 142HG in the horizontal direction D_{X} and the vertical direction D_{Y} can be relaxed. The alignment accuracy of the mask is relaxed so that the display device 601 can be made finer. In addition, the life of the display device 601 can be improved by increasing the aperture ratio.

### [Modifications]

### (Modification 1)

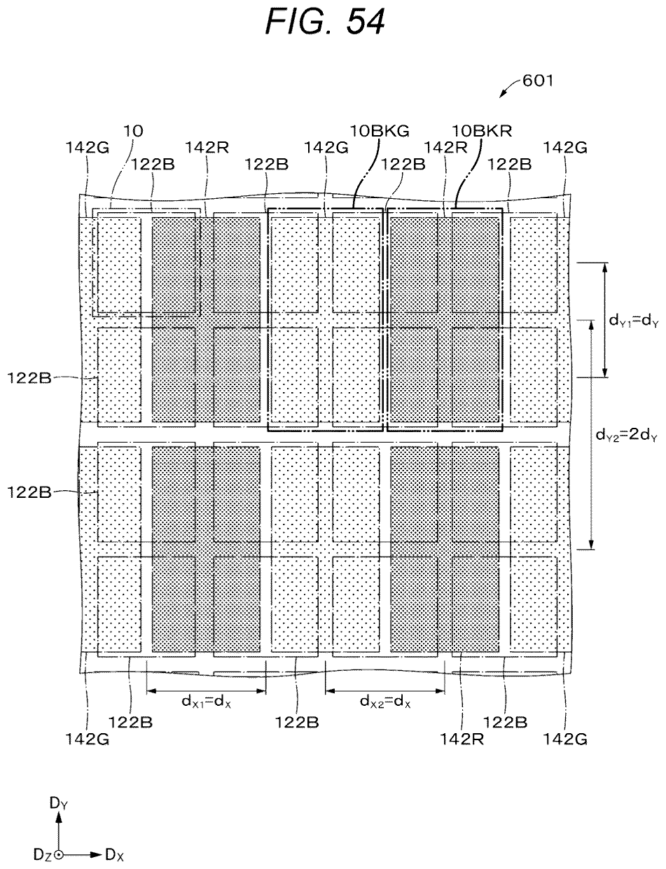

As illustrated in FIG. 54, the four organic LEDs 14R (that is, the four subpixels 10R) included in the (2×2)-subpixel block 10BKR may share one organic layer 142R. The four organic LEDs 14R (that is, the four subpixels 10R) included in the (2×2)-subpixel block 10BKR may be included in separate pixels 10.

As illustrated in FIG. 54, the four organic LEDs 14G (that is, the four subpixels 10G) included in the (2×2)-subpixel block 10BKG may share one organic layer 142G. The four organic LEDs 14G (that is, the four subpixels 10G) included in the (2×2)-subpixel block 10BKG may be included in separate pixels 10.

The arrangement pitch d_{Y1} of the inorganic layer 122B in the vertical direction D_{Y} is equal to the arrangement pitch d_{Y} of the pixels 10 in the vertical direction D_{Y}. On the other hand, the arrangement pitch d_{Y2} of the organic layer 142 in the vertical direction D_{Y} is twice the arrangement pitch d_{Y} of the pixels 10 in the vertical direction D_{Y}. As a result, the organic layer 142 is disposed so as to cross the four adjacent pixels 10.

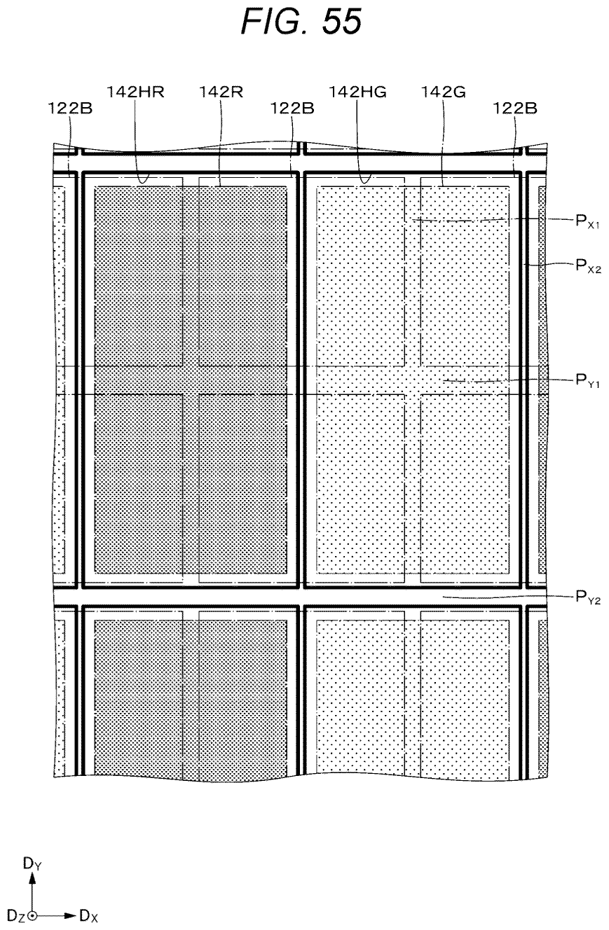

In the process of forming the organic layer 142R and the organic layer 142G in Modification 1, as illustrated in FIG. 55, the alignment of the opening 142HR in units of the four subpixels 10R and the alignment of the opening 142HG in units of the four subpixels 10G can be completed, so that the alignment of the position P_{X1} and the position P_{Y1} can be omitted. Therefore, the alignment accuracy of the openings 142HR and 142HG in the horizontal direction D_{X} and the vertical direction D_{Y} can be relaxed.

### (Modification 2)

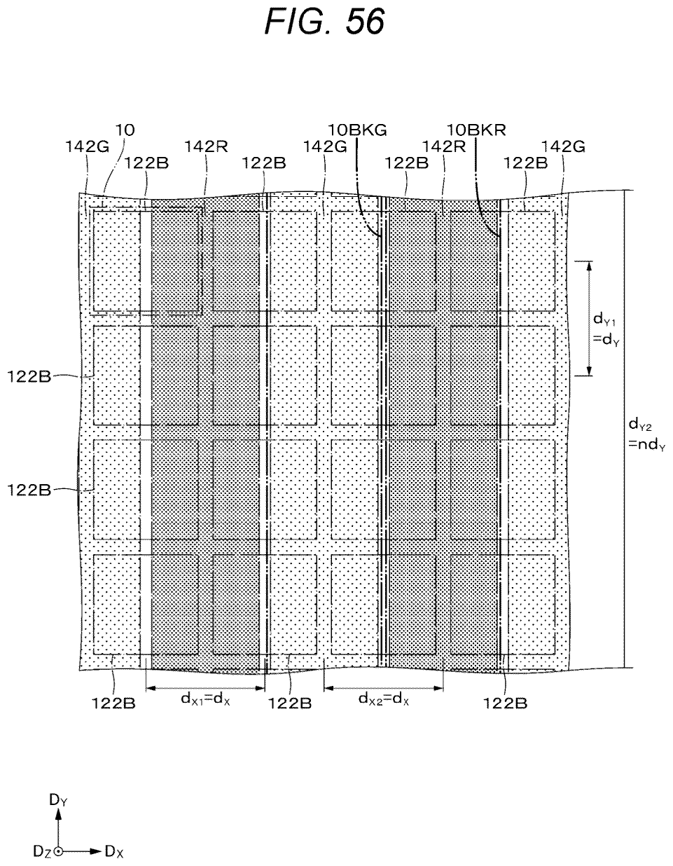

As illustrated in FIG. 56, (2×n) organic LEDs 14R (that is, (2×n) subpixels 10R) included in a (2×n)-subpixel block 10BKR (here, n is the number of pixels in the vertical direction D_{Y} in the display region RE1.) may share one organic layer 142R. The (2×n) organic LEDs 14R (that is, the (2×n) subpixels 10R) included in the (2×n)-subpixel block 10BKR may be included in separate pixels 10.

As illustrated in FIG. 56, (2×n) organic LEDs 14G (that is, (2×n) subpixels 10G) included in the (2×n)-subpixel block 10BKG may share one organic layer 142G. The (2×n) organic LEDs 14G (that is, the (2×n) subpixels 10G) included in the (2×n)-subpixel block 10BKG may be included in separate pixels 10.

The arrangement pitch d_{Y1} of the inorganic layer 122B in the vertical direction D_{Y} is equal to the arrangement pitch d_{Y} of the pixels 10 in the vertical direction D_{Y}. On the other hand, the arrangement pitch d_{Y2} of the organic layer 142 in the vertical direction D_{Y} is n times the arrangement pitch d_{Y} of the pixels 10 in the vertical direction D_{Y}. As a result, the organic layer 142 is disposed so as to cross the adjacent (2×n) pixels 10.

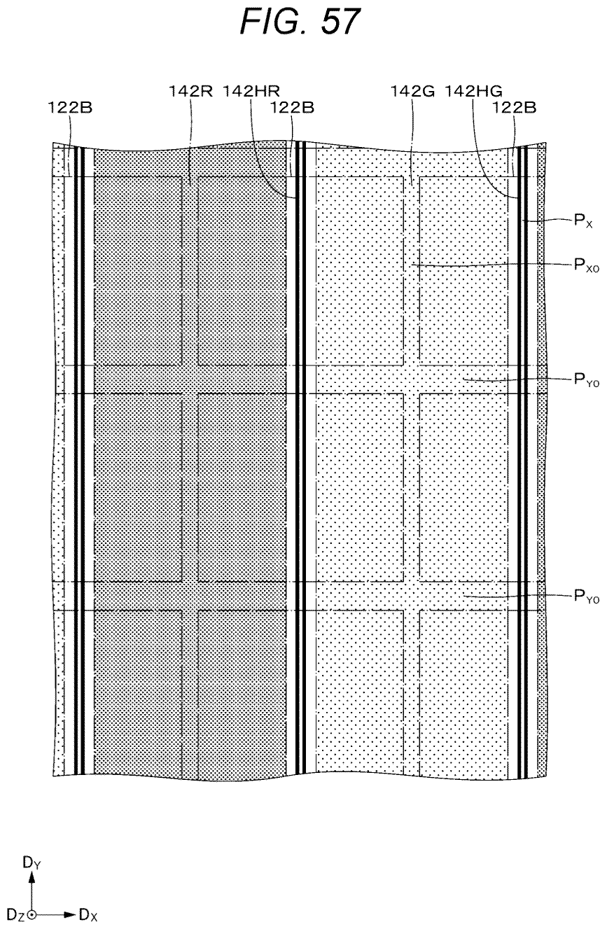

In the process of forming the organic layer 142R and the organic layer 142G in Modification 2, as illustrated in FIG. 57, alignment of the opening 142HR and the opening 142HG in the vertical direction D_{Y} becomes unnecessary. In addition, similarly to the first embodiment, the alignment accuracy of the openings 142HR and 142HG in the horizontal direction D_{X} can be relaxed.

### 16 16th Embodiment

### [Outline]

Hereinafter, a column formed by arranging the plurality of subpixels 10R in the vertical direction D_{Y} will be referred to as a “subpixel column R”, and a column formed by arranging the plurality of subpixels 10G in the vertical direction D_{Y} will be referred to as a “subpixel column G”. In the fifth embodiment, an example has been described in which one filter unit 19M having a linear shape is individually provided for each subpixel column R, and one filter unit 19C having a linear shape is individually provided for each column of one subpixel 10G (see FIGS. 13 and 49). In the 16th embodiment, an example in which one filter unit 19M having a linear shape is shared by two adjacent subpixel columns R, and one filter unit 19C having a linear shape is shared by two adjacent subpixel columns G will be described.

### [Configuration of Display Device 602]

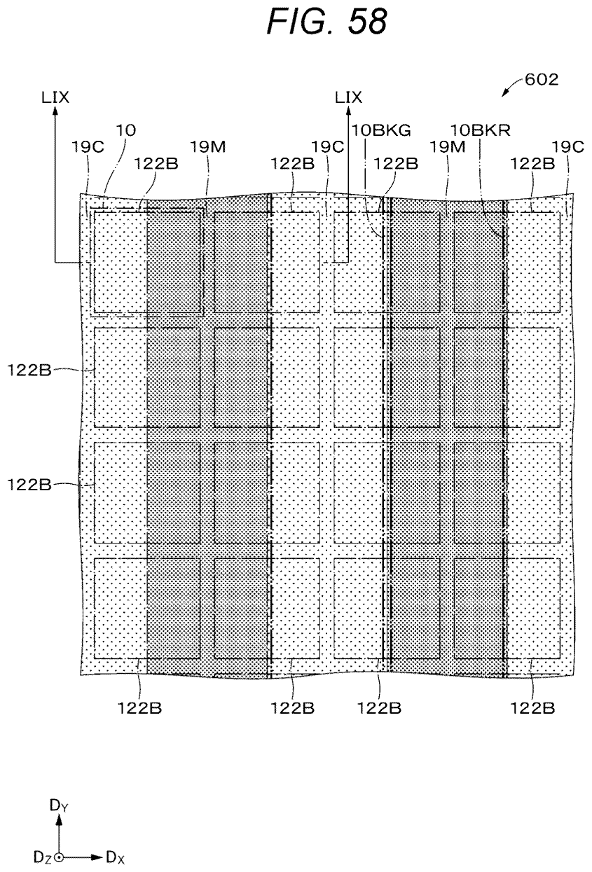

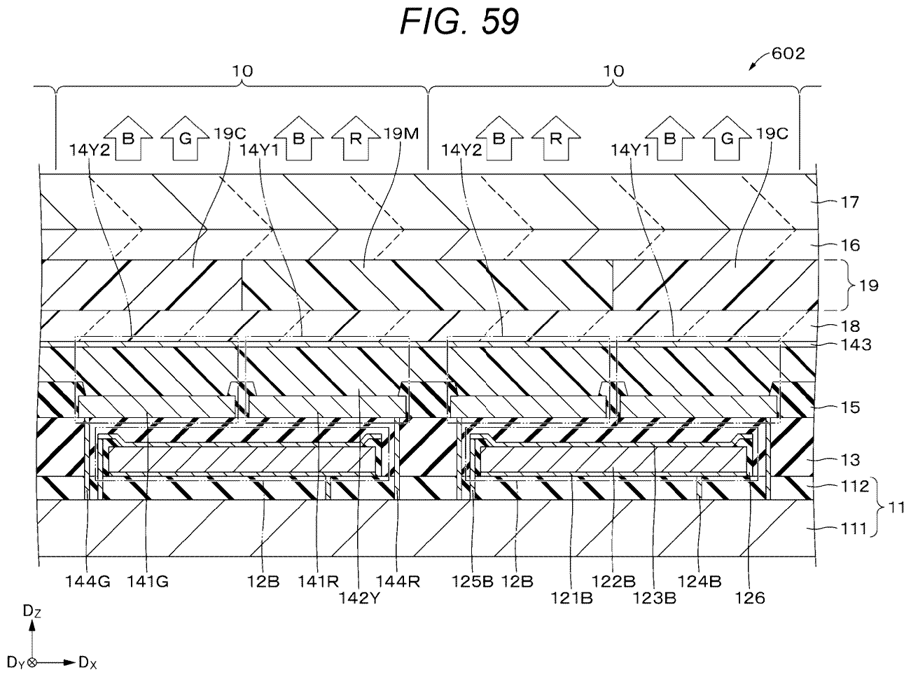

FIG. 58 is an enlarged plan view illustrating a part of a display region RE1 of a display device 602 according to the 16th embodiment. FIG. 59 is a cross-sectional view taken along line LIX-LIX of FIG. 58. The plurality of subpixels 10R configures a plurality of (2×n)-subpixel blocks 10BKR. The plurality of subpixels 10G configures a plurality of (2×n)-subpixel blocks 10BKG. The (2×n)-subpixel blocks 10BKR and the (2×n)-subpixel blocks 10BKG are alternately provided in the horizontal direction D_{X}.

The (2×n) subpixels 10R included in the (2×n)-subpixel block 10BKR share one linear filter unit 19M. The (2×n) subpixels 10R included in the (2×n)-subpixel block 10BKR are included in the separate pixels 10.

The (2×n) subpixels 10G included in the (2×n)-subpixel block 10BKG share one linear filter unit 19C. The (2×n) subpixels 10G included in the (2×n)-subpixel block 10BKG are included in the separate pixels 10.

### [Operations and Effects]

In the display device 105 according to the fifth embodiment, in the process of forming the color filter 19, alignment of the filter unit 19M in units of one subpixel 10R and alignment of the filter unit 19C in units of one subpixel 10G in the horizontal direction D_{X} are required (see FIG. 49).

On the other hand, in the display device 602 according to the 16th embodiment, in the process of forming the color filter 19, the alignment of the filter unit 19M in units of two subpixels 10R in the horizontal direction D_{X} and the alignment of the filter unit 19C in units of two subpixels 10G in the horizontal direction D_{X} can be sufficient (see FIG. 58). Therefore, the alignment accuracy of the filter unit 19M and the filter unit 19C in the horizontal direction D_{X} can be relaxed.

### [Modifications]

In the 16th embodiment, an example has been described in which one linear filter unit 19M is shared by two adjacent subpixel columns R, and one linear filter unit 19C is shared by two adjacent subpixel columns G. However, the configurations of the filter unit 19M and the filter unit 19C of the display device 105 are not limited to this example. For example, one filter unit 19M having a rectangular shape or the like may be shared in the (2×1) or (2×2)-subpixel block 10BKR, and one filter unit 19C having a rectangular shape or the like may be shared in the (2×1) or (2×2)-subpixel block 10BKG.

### 17 17th Embodiment

### [Outline]

The display device 101 according to the first embodiment may have a plurality of first resonator structures. In the first resonator structure, red light emitted from the organic LED 14R can be intensified by a resonance effect (cavity effect), and green light emitted from the organic LED 14G can be intensified by a resonance effect (cavity effect). The first resonator structure includes the first electrode 121B of the inorganic LED 12B and the second electrodes 143 of the organic LEDs 14R and 14G.

In the following description, light emitted from the organic LED 14R toward the inorganic LED 12B, reflected by the first electrode 121B of the inorganic LED 12B, and then returned to the organic layer 142R of the organic LED 14R is referred to as return light L2. Similarly, light emitted from the organic LED 14G toward the inorganic LED 12B, reflected by the first electrode 121B of the inorganic LED 12B, and then returned to the organic layer 142G of the organic LED 14G is referred to as return light L2.

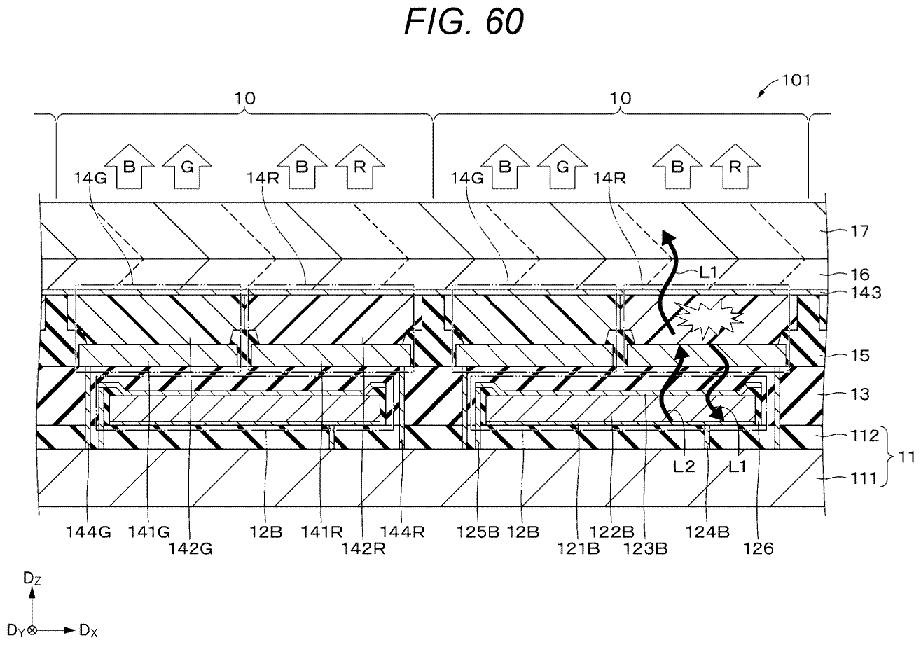

As illustrated in FIG. 60, in order to obtain a resonance effect (cavity effect) in the organic LED 14R, the first resonator structure is preferably configured such that a difference in phase between an emission light L1 and the return light L2 from the organic LED 14R becomes 0. In addition, in the first resonator structure, the organic LED 14G is preferably configured such that a phase difference between the emission light L1 and the return light L2 from the organic LED 14G becomes 0 so that a resonance effect can be obtained in the organic LED 14G.

However, in the display device 101, since a film thickness of the inorganic LED 12B tends to be thick and the insulating layer 13 is provided between the inorganic LED 12B and the organic LED 14R, the distance from the organic LED 14R to the first electrode 121B of the inorganic LED 12B tends to be long. For the same reason, a distance from the organic LED 14G to the first electrode 121B of the inorganic LED 12B tends to be long. Therefore, a design of the first resonator structure is likely to be difficult. Therefore, there is a possibility that the resonance effect of the first resonator structure is reduced.

In the 17th embodiment, a technique capable of suppressing a decrease in the resonance effect of the first resonator structure will be described.

### [Configuration of Display Device 603]

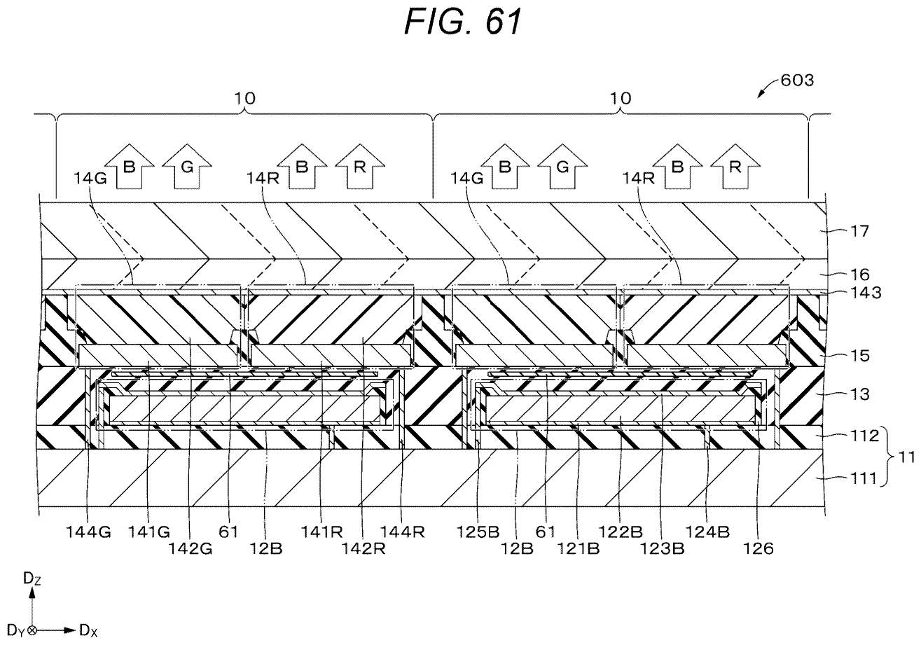

FIG. 61 is a cross-sectional view illustrating an example of a configuration of a display device 603 according to the 17th embodiment. The display device 603 is different from the display device 101 according to the first embodiment in including a reflection layer 61.

The reflection layer 61 is provided between the inorganic LED 12B and the organic LEDs 14R and 14G. More specifically, the reflection layer 61 is buried in the insulating layer 13 located between the inorganic LED 12B and the organic LEDs 14R and 14G. The reflection layer 61 may be connected between the pixels 10 adjacent in the in-plane direction and shared by the plurality of pixels 10, or may be divided between the pixels 10 adjacent in the in-plane direction and provided for each pixel 10. The reflection layer 61 may be connected between the subpixels 10R and 10G included in one pixel 10 and shared by the subpixels 10R and 10G, or may be divided between the subpixels 10R and 10G included in one pixel 10 and provided for each of the subpixels 10R and 10G. FIG. 61 illustrates an example in which the reflection layer 61 is divided between the pixels 10 adjacent in the in-plane direction, is provided for each of the plurality of pixels 10, is connected between the subpixels 10R and 10G included in one pixel 10, and is shared by the subpixels 10R and 10G.

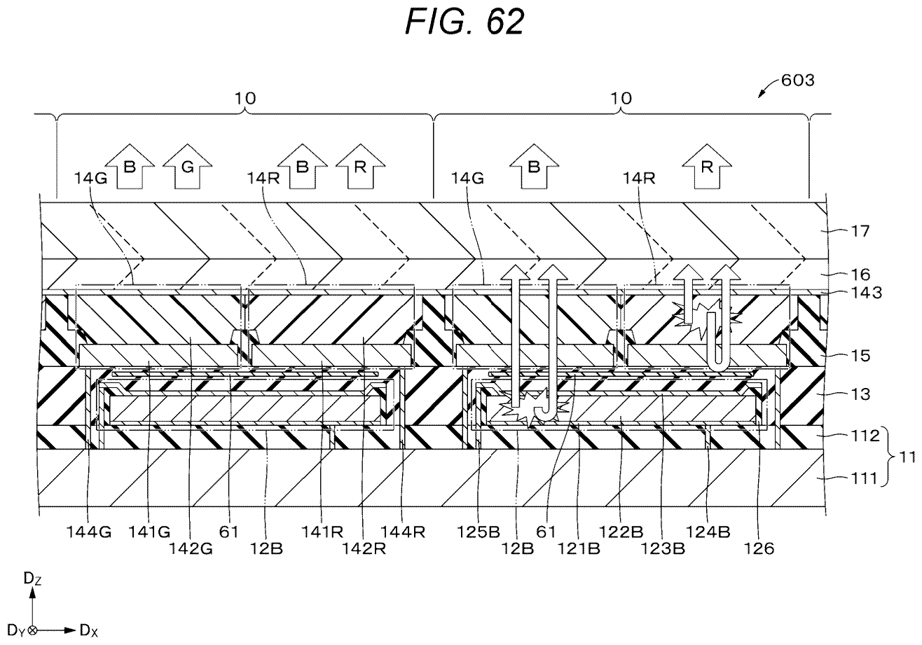

As illustrated in FIG. 62, the reflection layer 61 can reflect red light incident from the organic LED 14R and green light incident from the organic LED 14G while transmitting blue light incident from the inorganic LED 12B.

The reflection layer 61 may include a dielectric multilayer film having wavelength selectivity. The dielectric multilayer film is, for example, a laminate in which a low refractive index layer and a high refractive index layer are alternately laminated. A thickness of the dielectric multilayer film is, for example, 200 nm or more. A thickness of the low refractive index layer is, for example, 50 nm or more. A thickness of the high refractive index layer is, for example, 50 nm or more. A refractive index n_{H} of the high refractive index layer is set higher than a refractive index n_{L} of the low refractive index layer. A refractive index difference Δn (=n_{H}-n_{L}) between the low refractive index layer and the high refractive index layer is preferably 0.1 or more. In the present specification, the refractive index represents a refractive index with respect to light having a wavelength of 589.3 nm (D line of sodium).

The subpixel 10R and the subpixel 10G included in one pixel 10 share the first resonator structure. The first resonator structure can resonate and emphasize red light emitted from the organic layer 142R, and can resonate and emphasize green light emitted from the organic layer 142G. However, the resonance effect of the first resonator structure is not limited to this example, and only one of red light emitted in the organic layer 142R and green light emitted in the organic layer 142G may be resonated and emphasized. The first resonator structure includes the reflection layer 61 and the second electrodes 143 of the organic LEDs 14R and 14G.

The pixel 10 may have a second resonator structure. The second resonator structure can resonate and emphasize the blue light emitted in the inorganic layer 122B. The second resonator structure may include the first electrode 121B of the inorganic LED 12B and the second electrodes 143 of the organic LEDs 14R and 14G, or may include the first electrode 121B of the inorganic LED 12B and the reflection layer 61.

Reflectance of the reflection layer 61 at at least one of a peak wavelength of red light, a peak wavelength of green light, and a peak wavelength of blue light is preferably 50% or more, more preferably 60% or more, further 70% or more, 80% or more, or 90% or more. Here, the red light represents the red light emitted from the organic LED 14R, the green light represents the green light emitted from the organic LED 14G, and the blue light represents the green light emitted from the inorganic LED 12B.

Since the reflectance of the reflection layer 61 at the peak wavelength of red light and/or the peak wavelength of green light is high, the resonance effect of the first resonator structure can be improved.

Since the reflectance of the reflection layer 61 at the peak wavelength of blue light is high, the resonance effect of the second resonator structure can be improved.

The transmittance of the reflection layer 61 at at least one of the peak wavelength of red light, the peak wavelength of green light, and the peak wavelength of blue light may be 50% or more. From the viewpoint of suppressing a decrease in blue light extraction efficiency, the transmittance of the reflection layer 61 at the peak wavelength of red light is preferably 50% or more, more preferably 60% or more, further 70% or more, 80% or more, or 90% or more.

In order to enhance the light extraction efficiency of at least one of the red light and the green light while suppressing the decrease in the blue light extraction efficiency, it is preferable that the reflectance of the reflection layer 61 at the peak wavelength of the blue light is 5% or more and 50% or less, and the reflectance of the reflection layer 61 at at least one peak wavelength of the peak wavelength of the red light and the peak wavelength of the green light is 50% or more.

### [Operations and Effects]

The display device 603 according to the 17th embodiment includes a reflection layer 61 between the inorganic LED 12B and the organic LEDs 14R and 14G. As illustrated in FIG. 62, the reflection layer 61 can reflect red light emitted from the organic LED 14R and green light emitted from the organic LED 14G while transmitting blue light emitted from the inorganic LED 12B. Therefore, it is possible to enhance the extraction efficiency of the red light and the green light while suppressing a decrease in the extraction efficiency of the blue light.

In the 17th embodiment, a distance between the reflection layer 61 and the second electrode 143 configuring the first resonator structure is shorter than a distance between the first electrode 121B and the second electrode 143 configuring the first resonator structure in the first embodiment. Therefore, a design of the first resonator structure in the display device 603 according to the 17th embodiment is easier than the design of the first resonator structure in the display device 101 according to the first embodiment. In the display device 603 according to the 17th embodiment, it is possible to suppress a decrease in the resonance effect of the first resonator structure.

### [Modifications]

### (Modification 1)

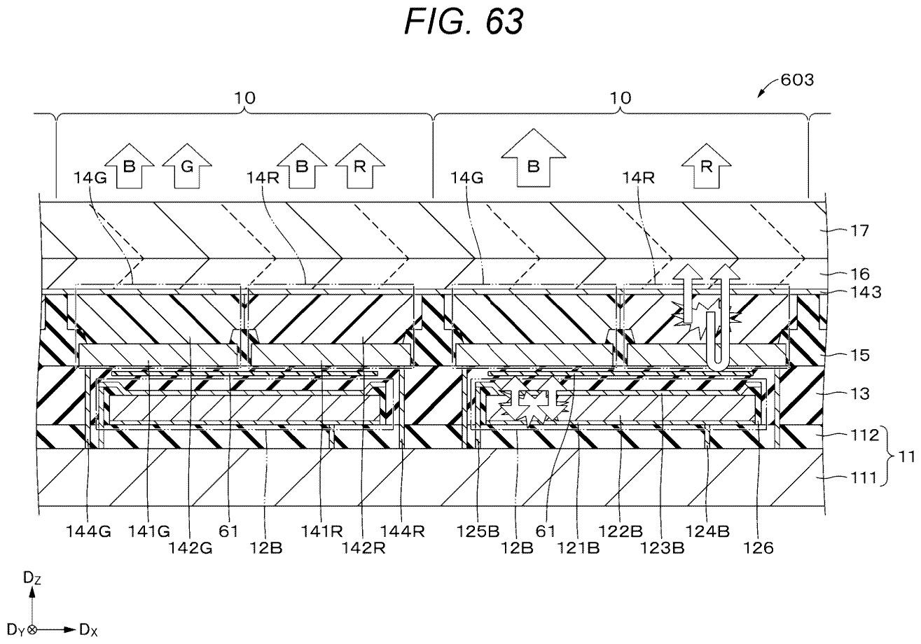

In the 17th embodiment, an example in which the reflection layer 61 is formed of a dielectric multilayer film has been described. However, the reflection layer 61 may be formed of a laminate of a dielectric multilayer film and a metal layer, or the reflection layer 61 may be formed of a metal layer. In Modification 1, as illustrated in FIG. 63, the second resonator structure may include the first electrode 121B of the inorganic LED 12B and the reflection layer 61. The reflection layer 61 in Modification 1 can reflect and transmit blue light incident from the inorganic LED 12B at a certain ratio. Furthermore, the reflection layer 61 in Modification 1 can reflect red light incident from the organic LED 14R and green light incident from the organic LED 14G. In the present specification, reflecting and transmitting light at a constant ratio means reflecting light at a constant ratio and transmitting light at a constant ratio.

The metal layer can reflect and transmit incident visible light at a certain ratio. Specifically, the metal layer can reflect and transmit blue light incident from the inorganic LED 12B at a constant ratio, can reflect and transmit red light incident from the organic LED 14R at a constant ratio, and can reflect and transmit green light incident from the organic LED 14G at a constant ratio. The metal layer may be a so-called half mirror.

The metal layer may be provided on any one of the first surface and the second surface of the dielectric multilayer film, or on both the first surface and the second surface. The metal layer may be provided between a low refractive index layer and a high refractive index layer configuring the dielectric multilayer film. As the material of the metal layer, the similar material to that of the metal layer of the second electrode 143 in the first embodiment can be exemplified.

As described above, the second resonator structure in Modification 1 includes the first electrode 121B of the inorganic LED 12B and the reflection layer 61, and the reflection layer 61 includes a laminate of a dielectric multilayer film and a metal layer or a metal layer. As a result, as illustrated in FIG. 63, the resonance effect of the second resonator structure in Modification 1 is higher than the resonance effect of the second resonator structure in the 17th embodiment. Therefore, blue light extraction efficiency can be enhanced.

### (Modification 2)

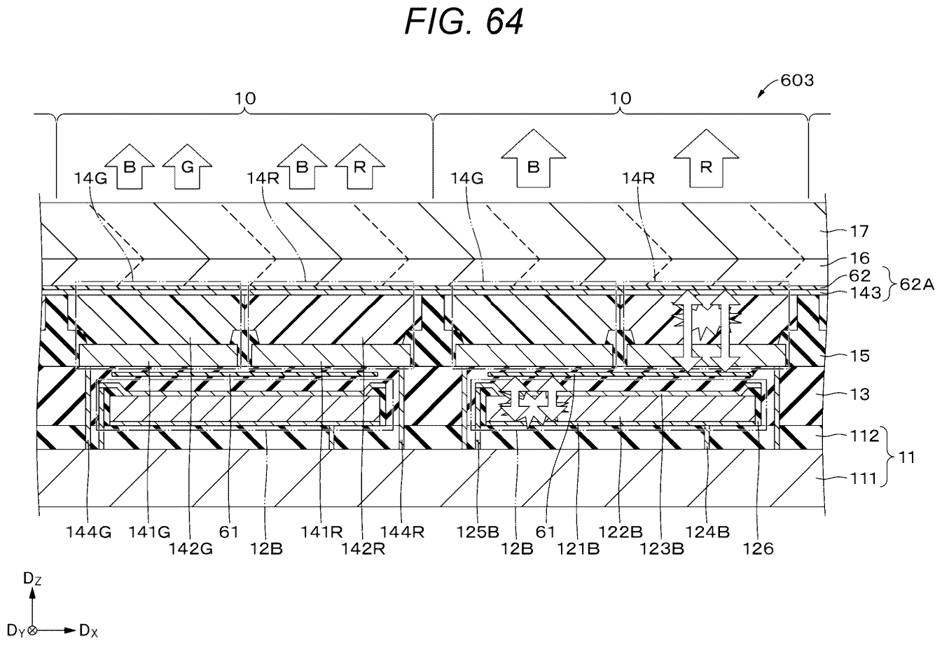

As illustrated in FIG. 64, the display device 603 may further include a reflection layer 62. In a case where the second electrode 143 is formed of a transparent conductive oxide layer, it is particularly preferable that the display device 603 further includes the reflection layer 62 from the viewpoint of improving the resonance effect by the first resonator structure. As illustrated in FIG. 64, the reflection layer 62 may be provided on the first surface of the second electrode 143. The second electrode 143 and the reflection layer 62 may configure a laminate 62A. The first resonator structure may include the reflection layer 61 and the laminate 62A. In this Modification 2, an example in which the reflection layer 62 is provided on the first surface of the second electrode 143 will be described, but the reflection layer 62 may be provided above the second electrode 143 and may be arranged at a predetermined interval from the first surface of the second electrode 143.

The reflection layer 62 can reflect and transmit red light incident from the organic LED 14R at a constant ratio, can reflect and transmit green light incident from the organic LED 14G at a constant ratio, and can transmit blue light incident from the inorganic LED 12B.

The reflection layer 62 includes, for example, one of a dielectric multilayer film and a metal layer having wavelength selectivity, or both of a dielectric multilayer film and a metal layer having wavelength selectivity. From the viewpoint of improving the resonance effect by the first resonator structure, the reflection layer 62 is preferably formed of both the dielectric multilayer film having wavelength selectivity and the metal layer. The metal layer may be provided on any one of the first surface and the second surface of the dielectric multilayer film, or on both the first surface and the second surface. The metal layer may be provided between a low refractive index layer and a high refractive index layer configuring the dielectric multilayer film.

The dielectric multilayer film can reflect and transmit red light incident from the organic LED 14R at a constant ratio, can reflect and transmit red light incident from the organic LED 14G at a constant ratio, and can transmit blue light incident from the inorganic LED 12B.

The metal layer can reflect and transmit incident visible light at a certain ratio. More specifically, the metal layer can reflect and transmit red light incident from the organic LED 14R at a constant ratio, and can reflect and transmit green light incident from the organic LED 14G at a constant ratio. The metal layer may be a so-called half mirror. As the material of the metal layer, the similar material to that of the metal layer of the second electrode 143 in the first embodiment can be exemplified.

In the display device 603 according to Modification 2, the first resonator structure includes the reflection layer 61 and the laminate 62A. The laminate 62A includes the second electrode 143 and the reflection layer 62. As a result, as illustrated in FIG. 64, the resonance effect of the first resonator structure in Modification 2 is higher than the resonance effect of the first resonator structure in the 17th embodiment. Therefore, the extraction efficiency of the red light and the green light can be enhanced.

### (Modification 3)

In the 17th embodiment, an example in which the subpixel 10R and the subpixel 10G included in the pixel share the first resonator structure has been described. However, the subpixel 10R and the subpixel 10G included in the pixel 10 may have different resonator structures. That is, the subpixel 10R and the subpixel 10G may have a third resonator structure and a fourth resonator structure, respectively. The third resonator structure of the subpixel 10R is configured to resonate and emphasize the red light emitted from the organic layer 142R. The fourth resonator structure of the subpixel 10G is configured so that green light emitted from the organic layer 142G can be resonated and emphasized. The third resonator structure includes the reflection layer 61 of the subpixel 10R and the second electrode 143. The fourth resonator structure includes the reflection layer 61 of the subpixel 10G and the second electrode 143.

An optical path length La between the reflection layer 61 and the second electrode 143 in the third resonator structure may be different from an optical path length Lb between the reflection layer 61 and the second electrode 143 in the fourth resonator structure. The optical path length La may be adjusted so that the red light emitted from the organic layer 142R can resonate, and the optical path length Lb may be adjusted so that the green light emitted from the organic layer 142R can resonate. The reflection layer 61 of the subpixel 10R may be capable of reflecting red light emitted from the organic LED 14R while transmitting blue light emitted from the inorganic LED 12B. Furthermore, the reflection layer 61 of the subpixel 10G may be capable of reflecting green light emitted from an organic LED 14G while transmitting blue light emitted from the inorganic LED 12B.

### [Simulation]

The present disclosure will be specifically described hereinafter through simulations, but the present disclosure is not limited to these simulations. Note that, in the following simulation, an organic device simulator (setfos (registered trademark), manufactured by Fluxim) was used as simulation software.

### (Simulations 1 to 5)

The transmittance and reflectance of the intermediate layer in the display device having the structure shown in Table 1 were obtained by simulation. In Simulation 1, an intermediate layer between the inorganic LED and the organic LED is set to a dielectric multilayer film. In Simulations 2 and 3, the intermediate layer between the inorganic LED and the organic LED was set to a laminate of the dielectric multilayer film and a metal layer (Ag). In Simulation 4, the intermediate layer between the inorganic LED and the organic LED was set to a laminate of a protective layer (SiN) and a metal layer (Ag). In Simulation 5, the intermediate layer between the inorganic LED and the organic LED was set as a protective layer (SiN).

TABLE 2

| STRUCTURE OF | | SIMU- | SIMU- | SIMU- | SIMU- | SIMU- |
|---|---|---|---|---|---|---|
| DISPLAY DEVICE | | LATION 1 | LATION 2 | LATION 3 | LATION 4 | LATION 5 |
| ORGANIC LED | ORGANIC | INFINITE (REFLECTION OBSERVATION LAYER) | | | | |
| | LAYER | | | | | |
| | ITO | 20 nm | | | | |
| INTERMEDIATE | DIELECTRIC | ALUMINA: 88 nm | | | SiN: 500 nm | |
| LAYER | MULTILAYER | GaN: 59 nm | | | | |
| | FILM or | ALUMINA: 88 nm | | | | |
| | PROTECTIVE | GaN: 59 nm | | | | |
| | LAYER | ALUMINA: 88 nm | | | | |
| | | GaN: 59 nm | | | | |
| | | ALUMINA: 88 nm | | | | |
| | | GaN: 59 nm | | | | |
| | | ALUMINA: 88 nm | | | | |
| | METAL LAYER | 0 | Ag: 10 nm | Ag: 20 nm | Ag: 10 nm | 0 |

| | | |
|---|---|---|
| INORGANIC | CATHODE | 80 nm |
| LED | EML | 350 nm |
| | ANODE | 0 nm |
| | TRANSMISSION | INFINITE (TRANSMISSION OBSERVATION LAYER) |
| | OBSERVATION | |
| | LAYER (GaN) | |

### (Result of Simulations 1 to 5)

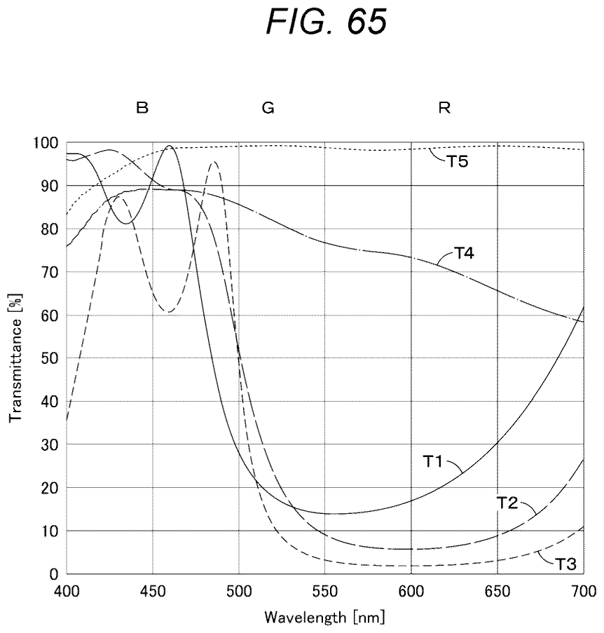

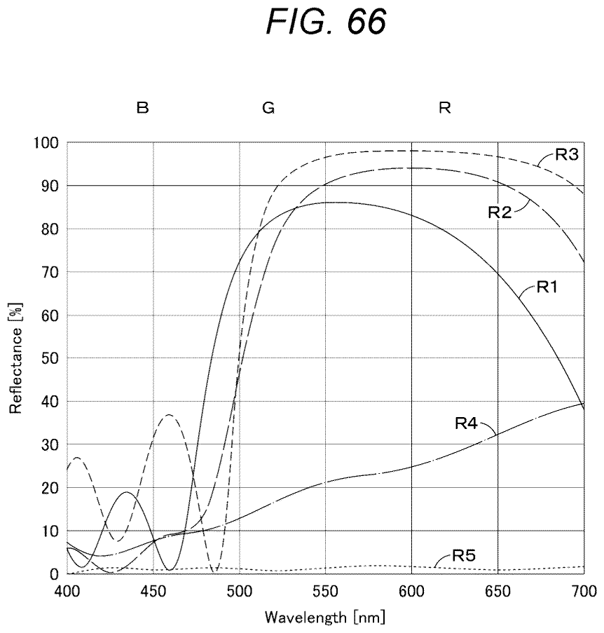

FIG. 65 is a graph showing a calculation result of transmittance by Simulations 1 to 5. FIG. 66 is a graph illustrating a calculation result of reflectance by Simulations 1 to 5. In FIG. 65, transmission spectra T1, T2, T3, T4, and T5 represent calculation results of transmittances by Simulations 1, 2, 3, 4, and 5, respectively. In FIG. 66, reflection spectra R1, R2, R3, R4, and R5 represent calculation results of transmittances by Simulations 1, 2, 3, 4, and 5, respectively.

FIG. 65 shows the following.

With the provision of the dielectric multilayer film or the laminate of the dielectric multilayer film and the metal layer (Ag) between the inorganic LED and the organic LED, blue light can be transmitted, whereas transmission of green light and red light can be suppressed. In a case where the laminate of the dielectric multilayer film and the metal layer (Ag) is provided between the inorganic LED and the organic LED, the transmittance of green light and red light can be particularly suppressed.

In a case where a laminate of a protective layer (SiN) and a metal layer (Ag) is provided between the inorganic LED and the organic LED, the transmittance of green light and red light cannot be largely suppressed, but the transmittance can be reduced as the wavelength is increased in the visible range.

In a case where the protective layer (SiN) is provided between the inorganic LED and the organic LED, substantially the same high transmittance is obtained in the visible region.

FIG. 66 shows the following.

With the provision of the dielectric multilayer film or the laminate of the dielectric multilayer film and the metal layer (Ag) between the inorganic LED and the organic LED, green light and red light can be reflected, whereas reflection of blue light can be suppressed. In a case where a laminate of a dielectric multilayer film and a metal layer (Ag) is provided between the inorganic LED and the organic LED, the reflectance of green light and red light can be particularly increased.

In a case where a laminate of a protective layer (SiN) and a metal layer (Ag) is provided between the inorganic LED and the organic LED, the reflectance of the green light and the red light cannot be rapidly increased, but the reflectance can be increased as the wavelength becomes longer in the visible range.

In a case where the protective layer (SiN) is provided between the inorganic LED and the organic LED, substantially the same low reflectance is obtained in the visible range.

### 18 18th Embodiment

### [Outline]

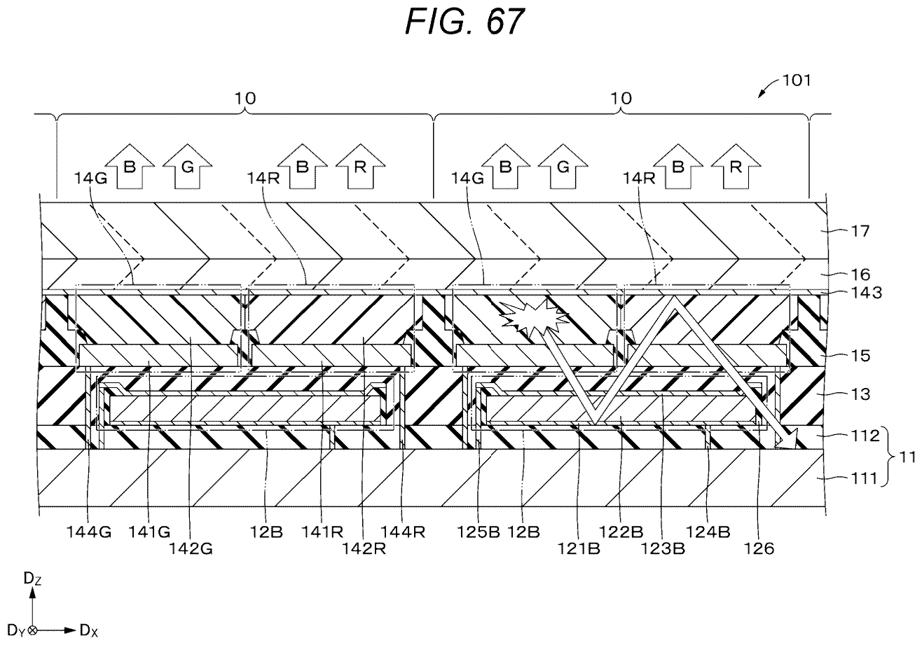

In the display device 101 according to the first embodiment, as illustrated in FIG. 67, the red light emitted from the organic LED 14R is repeatedly reflected between the first electrode 121 and the second electrode 143, and may not be extracted from a front of the display device 101. Similarly, green light emitted from the organic LED 14G and blue light emitted from the inorganic LED 12B may also be reflected back between the first electrode 121 and the second electrode 143, and not extracted from the front of the display device 101. In the 18th embodiment, as described above, a mode in which light emitted from the organic LED 14R, the organic LED 14G, or the inorganic LED 12B is repeatedly reflected between the first electrode 121B and the second electrode 143 is referred to as a waveguide mode.

In the display device 101 according to the first embodiment, as described above, light emitted from the organic LED 14R, the organic LED 14G, or the inorganic LED 12B may not be extracted from the front due to the waveguide mode and may be lost. Hereinafter, this loss of light is referred to as a loss of light due to the waveguide mode. In the 18th embodiment, a technology for improving the extraction efficiency of the display device 101 by controlling the loss of light due to the waveguide mode will be described.

### [Display Device 604]

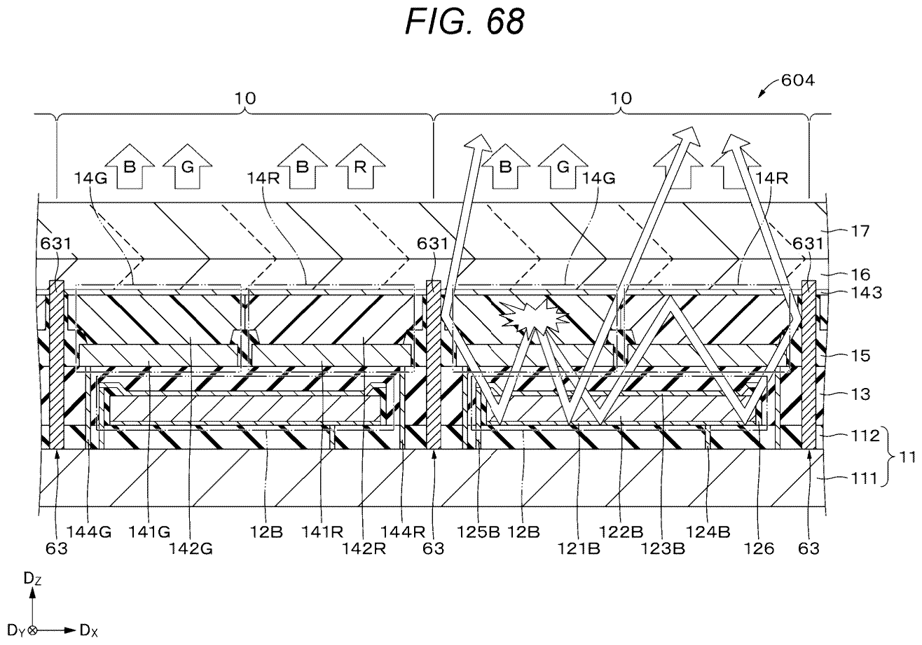

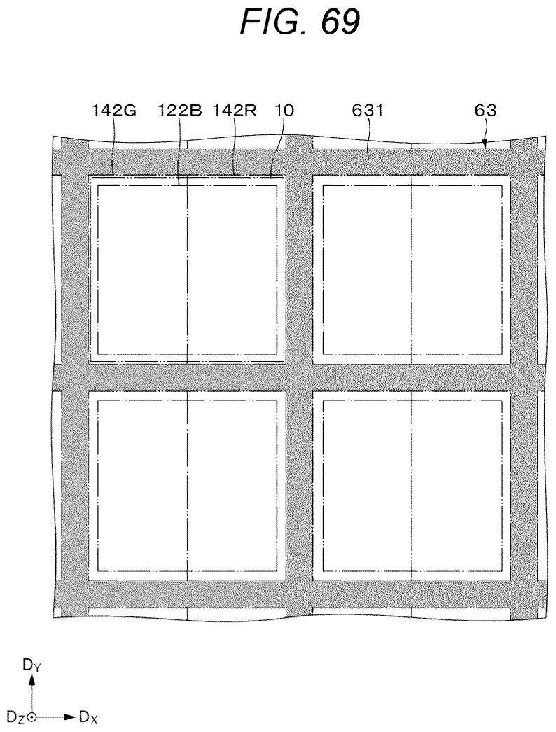

FIG. 68 is a cross-sectional view illustrating an example of a configuration of a display device 604 according to a 18th embodiment. The display device 604 is different from the display device 1010 according to the first embodiment in including a wall portion 63.

The wall portion 63 is configured to be able to reflect visible light on a wall surface.

More specifically, the wall portion 63 is configured to be capable of reflecting the blue light emitted from the inorganic LED 12B, the red light emitted from the organic LED 14R, and the green light emitted from the organic LED 14G on the wall surface. The wall portion 63 may stand perpendicular to the first surface of the drive substrate 11 or the first surface of the drive substrate 11.

FIG. 69 is a plan view illustrating an example of the configuration of the wall portion 63. The wall portion 63 includes a first wall portion 631. The first wall portion 631 is provided between the adjacent pixels 10. The first wall portion 631 preferably surrounds the pixel 10 in plan view. A bottom portion of the first wall portion 631 is located, for example, inside the drive substrate 11, on the first surface of the drive substrate 11, or inside the insulating layer 13. A top portion of the first wall portion 631 is located, for example, inside the insulating layer 15, at an interface between the insulating layer 15 and the protective layer 16, inside the protective layer 16, or at an interface between the protective layer 16 and the substrate 17. FIG. 68 illustrates an example in which the bottom portion of the first wall portion 631 is located inside the drive substrate 11 and the top portion of the first wall portion 631 is located inside the protective layer 16.

The wall portion 63 includes, for example, a low refractive index member or a reflective member. The low refractive index member can totally reflect blue light emitted from the inorganic LED 12B, red light emitted from the organic LED 14R, and green light emitted from the organic LED 14G. The low refractive index member may include a low refractive index material having a refractive index lower than that of a material positioned around a wall surface (side surface) of the low refractive index member. For example, the low refractive index member may include a low refractive index material having a refractive index lower than that of the insulating material included in the insulating layer 13. In a case where the low refractive index member and the organic LED 14R are provided in contact with each other, and the low refractive index member and the organic LED 14G are provided in contact with each other, the low refractive index member may contain a low refractive index material having a refractive index lower than that of the organic material contained in the organic layer 142R and the organic layer 142G. In a case where the insulating layer 15 is provided between the low refractive index member and the organic LED 14R and the insulating layer 15 is provided between the low refractive index member and the organic LED 14G, the low refractive index member may contain a low refractive index material having a refractive index lower than that of the insulating material contained in the insulating layer 15.

The reflective member may have a configuration similar to that of the reflection layer 62 in Modification 2 of the 17th embodiment. That is, the reflective member may include any one of the dielectric multilayer film and the metal layer having wavelength selectivity, or both of the dielectric multilayer film and the metal layer having wavelength selectivity. However, the low refractive index layer and the high refractive index layer configuring the dielectric multilayer film may be laminated in the in-plane direction. Furthermore, in a case where the reflective member includes both the dielectric multilayer film and the metal layer, the dielectric multilayer film and the metal layer may be laminated in the in-plane direction.

The wall surface of the wall portion 63 may be perpendicular to the first surface of the drive substrate 11 or may be inclined with respect to the first surface of the drive substrate 11. The wall surface of the wall portion 63 may be either a flat surface or a curved surface. The cross-sectional shape of the wall portion 63 may be, for example, a rectangular shape, a trapezoidal shape, a triangular shape, or the like. In a case where a cross-sectional shape of the wall portion 63 has a trapezoidal shape, an upper bottom side of the trapezoidal shape may be located on the display surface side, or a lower bottom side of the trapezoidal shape may be located on the display surface side. In a case where the cross-sectional shape of the wall portion 63 has a triangle, one corner of the triangle shape may be located on the display surface side of the display device 604 and one side of the triangle shape may be located on the opposite side to the display surface side (the back surface side of the display device 604), or one side of the triangle shape may be located on the display surface side and one corner of the triangle shape may be located on the opposite side to the display surface side. The rectangular shape, the trapezoidal shape, and the triangular shape include a substantially rectangular shape, a substantially trapezoidal shape, and a substantially triangular shape, respectively.

### [Operations and Effects]

The display device 604 according to the 18th embodiment includes the wall portion 63 between adjacent pixels 10. As a result, the light in the waveguide mode can be reflected by the wall portion 63 and extracted from the front. Therefore, loss of light due to the waveguide mode can be suppressed.

Furthermore, light obliquely emitted from the inorganic LED 12B, the organic LED 14R, and the organic LED 14G toward the adjacent pixel 10 can be reflected by the wall portion 63 and extracted from the front. Therefore, the light extraction efficiency can be improved.

### [Modifications]

### (Modification 1)

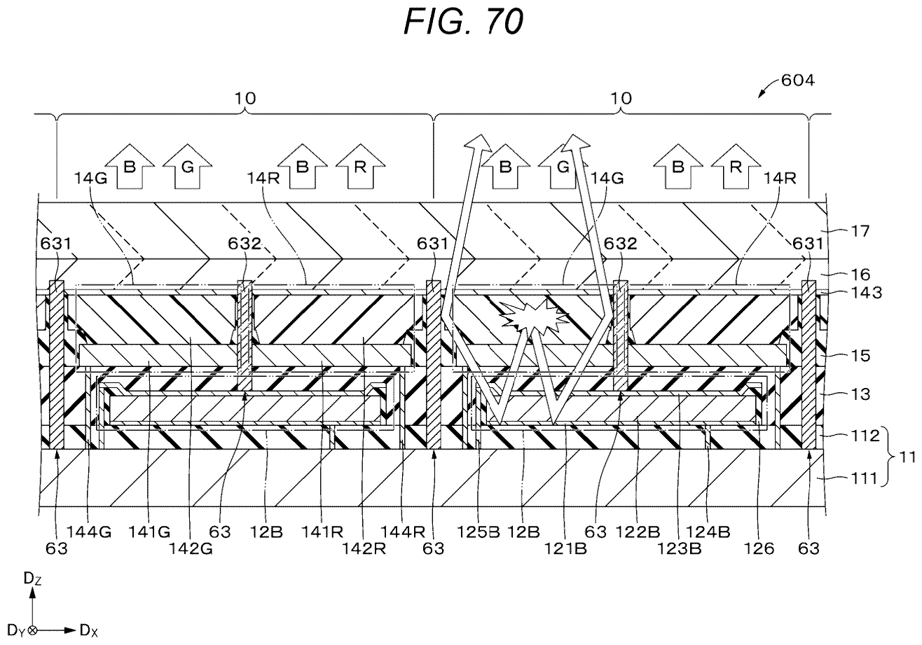

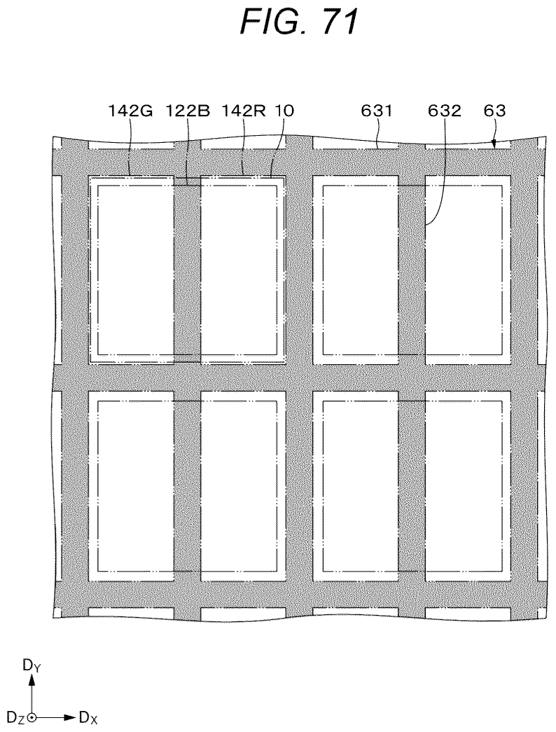

In the 18th embodiment, as illustrated in FIGS. 68 and 69, an example in which the wall portion 63 includes the first wall portion 631 has been described. However, the configuration of the wall portion 63 is not limited to this example, and for example, as illustrated in FIGS. 70 and 71, the wall portion 63 may include a first wall portion 631 and a second wall portion 632.

The second wall portion 632 is provided between the subpixel 10R and the subpixel 10G included in one pixel 10. The wall portion 63 in Modification 1 preferably surrounds the subpixels 10R and 10G in plan view. The second wall portion 632 may have an I shape in plan view.

A bottom portion of the second wall portion 632 is located, for example, on the first surface of the inorganic LED 12B, inside the insulating layer 13 (inside of the insulating layer 13 between the first surface of inorganic LED 12B and the second surfaces of the organic LEDs 14R, 14G), on the first surface of the insulating layer 13, or inside the insulating layer 15. A top portion of the second wall portion 632 is located, for example, inside the insulating layer 15, at an interface between the insulating layer 15 and the protective layer 16, inside the protective layer 16, or at an interface between the protective layer 16 and the substrate 17. FIG. 70 illustrates an example in which the bottom portion of the second wall portion 632 is located on the first surface of the inorganic LED 12B and the top portion of the second wall portion 632 is located inside the protective layer 16. The top portion of the second wall portion 632 may be located at substantially the same height as the top portion of the first wall portion 631.

In the display device 604 according to Modification 1, since the wall portion 63 includes the second wall portion 632, the loss of light due to the waveguide mode can be further suppressed.

Furthermore, since the wall portion 63 includes the second wall portion 632, the wall portion 63 can surround each of the subpixel 10R and the subpixel 10G. As a result, it is possible to suppress a decrease in the symmetry of the viewing angle due to the presence of the wall portion 63.

In the above description, an example in which the second wall portion 632 is provided between the subpixel 10R and the subpixel 10G included in one pixel 10 has been described, but the second wall portion 632 may also be provided inside the subpixel 10R and may also be provided inside the subpixel 10G. More specifically, for example, the second wall portion 632 may have a substantially cross shape in plan view, and each of the subpixels 10R and 10B may be divided into two equal parts.

### (Modification 2)

In the 18th embodiment and Modification 1 thereof, an example in which the wall portion 63 is configured to be able to reflect visible light on the wall surface has been described, but the wall portion 63 may be configured to be able to refract visible light on the wall surface. More specifically, the wall portion 63 may be configured to be capable of refracting the blue light emitted from the inorganic LED 12B, the red light emitted from the organic LED 14R, and the green light emitted from the organic LED 14G toward the front direction D_{Z} on the wall surface. Here, the refraction of light on the wall surface of the wall portion 63 means that light incident from the inorganic LED 12B, the organic LED 14R, or the organic LED 14G is bent on the wall surface of the wall portion 63 such that an angle formed by a perpendicular line of the first surface of the drive substrate 11 and light incident on the wall surface of the wall portion 63 from the inorganic LED 12B, the organic LED 14R, or the organic LED 14G is reduced.

The wall portion 63 includes, for example, a high refractive index member. The high refractive index member includes a high refractive index material having a refractive index higher than that of a material positioned around a wall surface (side surface) of the high refractive index member. For example, the high refractive index member may include a high refractive index material having a refractive index higher than that of the insulating material included in the insulating layer 13. In a case where the high refractive index member and the organic LED 14R are provided in contact with each other and the high refractive index member and the organic LED 14G are provided in contact with each other, the high refractive index member may contain a high refractive index material having a refractive index higher than that of the organic material contained in the organic layer 142R and the organic layer 142G. In a case where the insulating layer 15 is provided between the high refractive index member and the organic LED 14R and the insulating layer 15 is provided between the high refractive index member and the organic LED 14G, the high refractive index member may contain a high refractive index material having a refractive index higher than that of the insulating material contained in the insulating layer 15.

In the display device 604 according to Modification 2, the wall portion 63 can refract the incident light such that an angle formed by a perpendicular line of the first surface of the drive substrate 11 and light incident on the wall surface from the inorganic LED 12B, the organic LED 14R, or the organic LED 14G becomes small. Therefore, similarly to the 18th embodiment, the light extraction efficiency can be improved.

### (Modification 3)

In the first embodiment and Modifications 1 and 2 thereof, an example in which the display device 604 includes the wall portion 63 has been described, but the display device 604 may include a gap instead of the wall portion 63. The refractive index of the gap (specifically, the refractive index of the gas (for example, air) in the gap) is lower than the refractive index of a material located around the gap. Therefore, even in a case where the display device 604 includes the gap instead of the wall portion 63, the light extraction efficiency can be improved similarly to the 18th embodiment.

### (Modification 4)

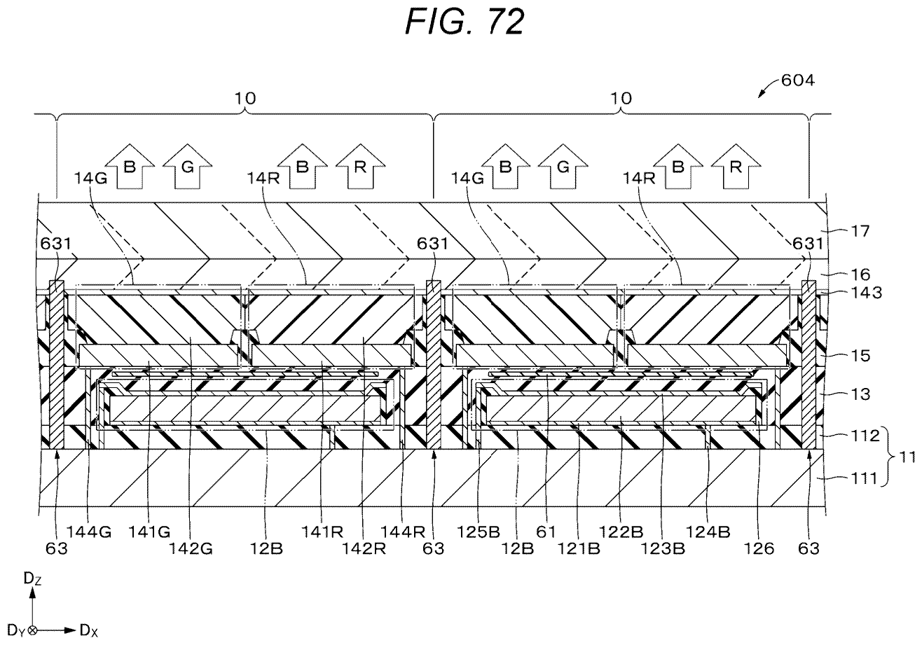

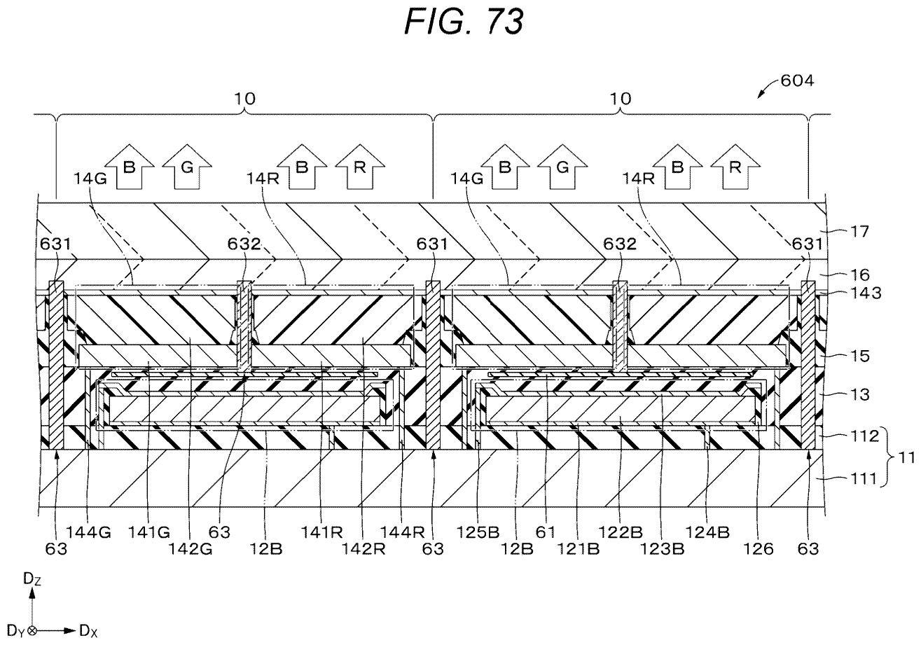

In the 18th embodiment and Modification 1 thereof, an example in which the display device 604 includes the wall portion 63 has been described. However, the configuration of the display device 604 is not limited thereto, and the display device 604 may include the wall portion 63 and the reflection layer 61 as illustrated in FIGS. 72 and 73. The wall portion 63 may include the first wall portion 631 as shown in FIG. 72, or may include the first wall portion 631 and the second wall portion 632 as shown in FIG. 73. As shown in FIG. 73, when the wall portion 63 includes the first wall portion 631 and the second wall portion 632, the bottom portion of the second wall portion 632 may be located on the first surface of the reflection layer 61. In Modification 4, the waveguide mode may be a mode in which light emitted from the inorganic LED 12B is repeatedly reflected between the first electrode 121 and the reflection layer 61, or a mode in which light emitted from the organic LEDs 14R and 14G is repeatedly reflected between the reflection layer 61 and the second electrode 143.

### (Fifth Modification)

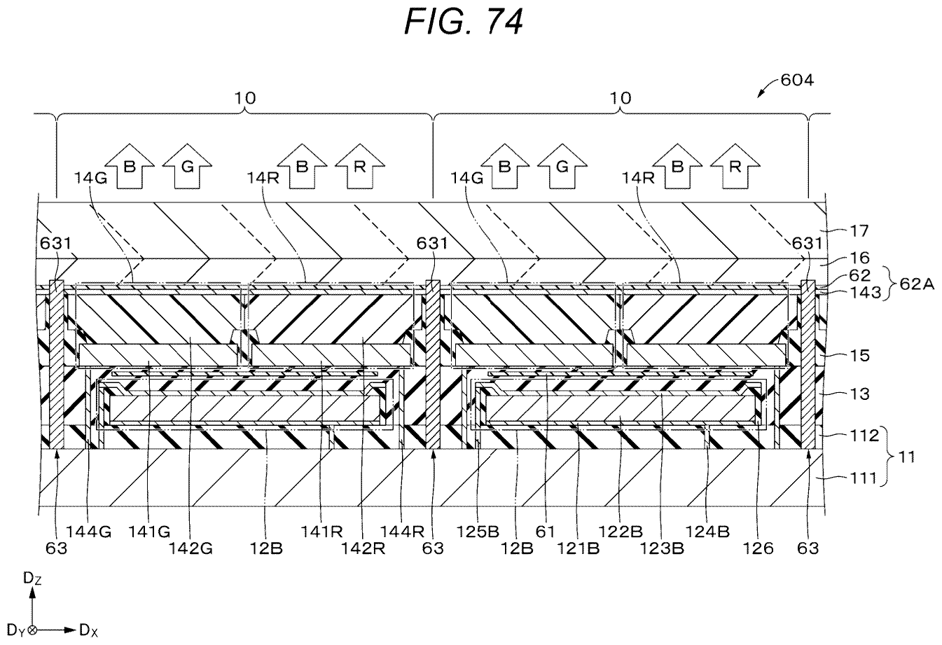

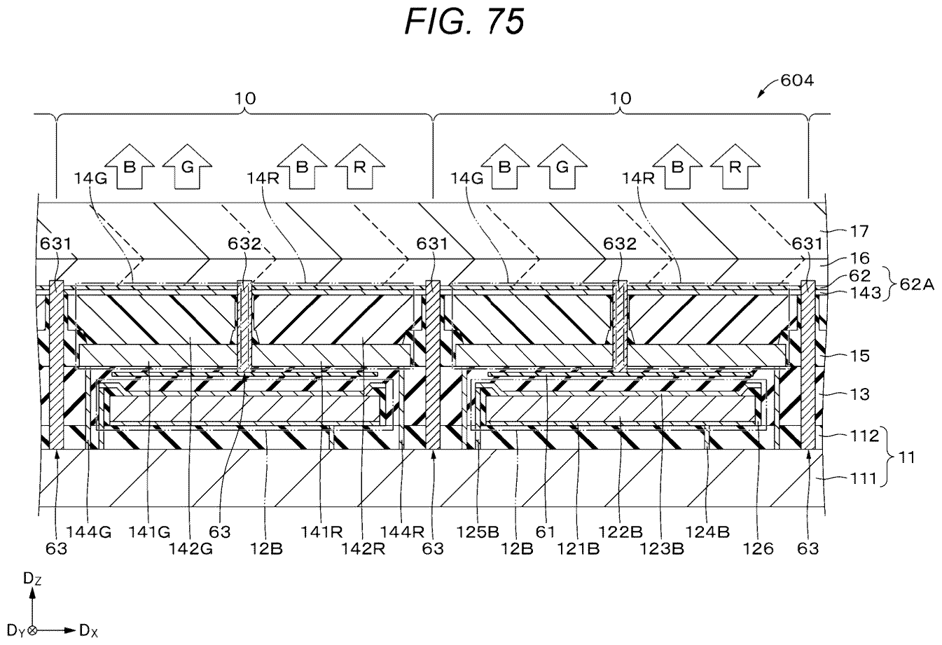

As illustrated in FIGS. 74 and 75, the display device 604 may include a wall portion 63, a reflection layer 61, and a reflection layer 62. The wall portion 63 may include the first wall portion 631 as shown in FIG. 74, or may include the first wall portion 631 and the second wall portion 632 as shown in FIG. 73. As shown in FIG. 75, in a case where the wall portion 63 includes the first wall portion 631 and the second wall portion 632, the bottom portion of the second wall portion 632 may be located on the first surface of the reflection layer 61. In Modification 5, the waveguide mode may be a mode in which light emitted from the inorganic LED 12B is repeatedly reflected between the first electrode 121 and the reflection layer 61, or a mode in which light emitted from the organic LEDs 14R and 14G is repeatedly reflected between the reflection layer 61 and the laminate 62A.

### (Modification 6)

In the 18th embodiment and Modifications 1 to 5 thereof, an example in which the display device 604 includes the wall portion 63 has been described. However, at least one of the vias 144G and 144R as a connection member may have a wall portion shape and also have a function of the wall portion 63. In this case, the wall portion 63 may or may not be provided.

The wall-like vias 144G and 144R preferably surround the inorganic LED 12B. As a material of the wall-like vias 144G and 144R, a material similar to the metal layer of the first electrode 141 in the first embodiment can be exemplified.

In the display device 604 according to Modification 6, at least one of the vias 144G and 144R has a wall portion shape and also has a function of the wall portion 63, and thus, it is possible to obtain an effect similar to that of the 18th embodiment.

### (Modification 7)

In Modification 6, an example in which at least one of the vias 144G and 144R has a wall portion shape and also has the function of the wall portion 63 has been described, but the via 125B may have a wall portion shape and also have the function of the wall portion 63. In this case, at least one of the vias 144G and 144R may have a wall portion shape or may not have a wall portion shape.

The wall-like via 125B preferably surrounds the inorganic LED 12B. As a material of the wall-like via 125B, a material similar to the metal layer of the first electrode 141 in the first embodiment can be exemplified.

In the display device 604 according to Modification 7, since the via 125B has a wall portion shape and also has the function of the wall portion 63, it is possible to obtain the effect similar to that of the 18th embodiment.

### 19 19th Embodiment

In the first embodiment, the configuration in which two layers of LEDs are laminated has been described as an example. In a 19th embodiment, an example in which three layers of LEDs are laminated will be described.

### [Configuration of Display Device 605]

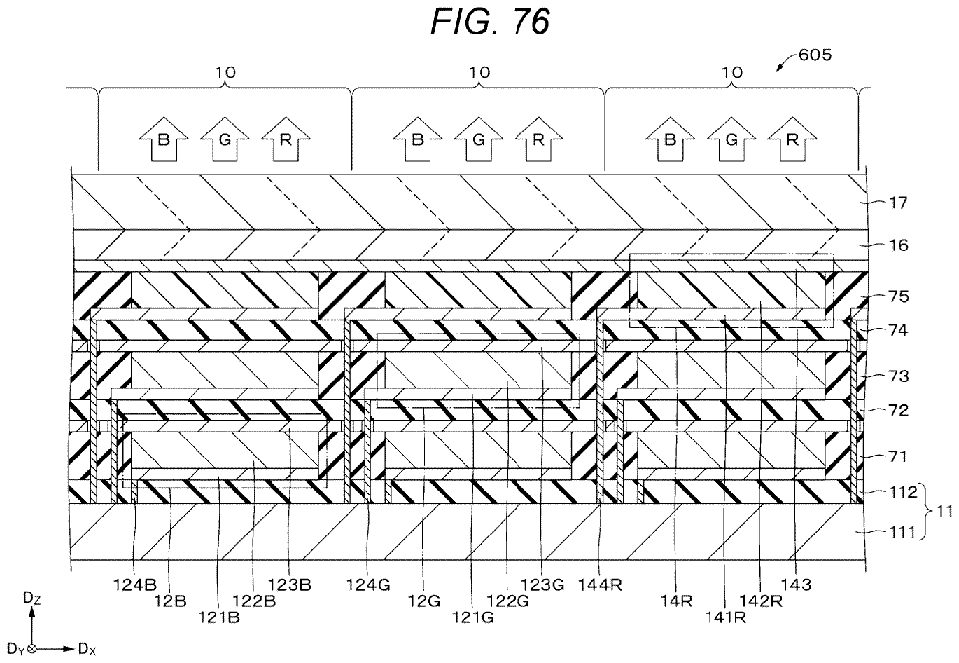

FIG. 76 is a cross-sectional view illustrating an example of a configuration of a display device 605 according to the 19th embodiment. The display device 605 includes a drive substrate 11, a plurality of inorganic LEDs 12B, a plurality of inorganic LEDs 12G, a plurality of organic LEDs 14R, an insulating layer 71, an insulating layer 72, an insulating layer 73, an insulating layer 74, an insulating layer 75, a protective layer 16, a substrate 17, a plurality of vias 124B, a plurality of 124G, and a plurality of vias 144R. The inorganic LED 12B, the insulating layer 72, the inorganic LED 12G, the insulating layer 74, and the organic LED 14R are laminated in this order on the first surface of the drive substrate 11.

### (Inorganic LED 12B)

The inorganic LED 12B is similar to that of the first embodiment except for the following points. That is, the second electrode 123B is shared by the plurality of inorganic LEDs 12B in the display region RE1. That is, the second electrode 143 is connected between the inorganic LEDs 12B adjacent in the in-plane direction in the display region RE1.

### (Inorganic LED 12G)

The inorganic LED 12G configures the subpixel 10G. The inorganic LED 12G can emit green light. The inorganic LED 12G is provided above the inorganic LED 12B. The inorganic LED 12G has translucency to the blue light emitted from the inorganic LED 12B.

The inorganic LED 12G includes a first electrode 121G, an inorganic layer 122G, and a second electrode 123G in order on the first surface of the insulating layer 72. The inorganic LED 12G may include a substrate between the first electrode 121G and the inorganic layer 122G or between the inorganic layer 122G and the second electrode 123G as necessary.

The inorganic layer 122G may be similar to the inorganic layer 122B of the inorganic LED 12B except that the inorganic light emitting layer capable of emitting green light is provided. The first electrode 121G is translucent to blue light emitted from the inorganic LED 12B. The first electrode 121G may be a transparent electrode having transparency to visible light. The second electrode 123G may be similar to the second electrode 123B of the inorganic LED 12B.

### (Organic LED 14R)

The organic LED 14R is provided above the inorganic LED 12G. The organic LED 14R has translucency to blue light emitted from the inorganic LED 12B and green light emitted from the organic LED 14G.

### (Insulating Layer 71, 72, 73, 74, 75)

The insulating layer 71 is provided between the inorganic LEDs 12B adjacent in the in-plane direction on the first surface of the drive substrate 11. The insulating layer 71 insulates between the inorganic LEDs 12B adjacent in the in-plane direction.

The insulating layer 72 is provided on the first surface of the plurality of inorganic LEDs 12B and the first surface of the insulating layer 71. The insulating layer 72 is sandwiched between the inorganic LED 12B and the organic LED 14G adjacent in the front direction D_{Z} (thickness direction of the display device 101), and insulates between the inorganic LED 12B and the organic LED 14G. The insulating layer 72 has translucency to the blue light emitted from the inorganic LED 12B. The insulating layer 72 may have transparency to visible light.

The insulating layer 73 is provided between the inorganic LEDs 12G adjacent in the in-plane direction on the first surface of the insulating layer 72. The insulating layer 72 insulates between the inorganic LEDs 12G adjacent in the in-plane direction.

The insulating layer 74 is provided on the first surface of the plurality of inorganic LEDs 12G and the first surface of the insulating layer 73. The insulating layer 74 is sandwiched between the inorganic LED 12G and the organic LED 14R adjacent in the front direction D_{Z} (thickness direction of the display device 101), and insulates the inorganic LED 12G from the organic LED 14R. The insulating layer 74 has translucency with to blue light emitted from the inorganic LED 12B and green light emitted from the inorganic LED 12G. The insulating layer 74 may have transparency to visible light.

The insulating layer 75 is provided between the organic LEDs 14R adjacent in the in-plane direction on the first surface of the insulating layer 74. The insulating layer 74 insulates between the organic LEDs 14R adjacent in the in-plane direction.

As the material of the insulating layers 71, 72, 73, 74, and 75, a material similar to that of the insulating layer 112 in the first embodiment can be exemplified.

### (Vias 124B, 124G, 144R)

The plurality of vias 124B is provided inside the insulating layer 112 and the like. The plurality of vias 124G is provided inside the insulating layer 112, the insulating layer 71, the insulating layer 72, and the like. The plurality of vias 144R is provided inside the insulating layer 112, the insulating layer 71, the insulating layer 72, the insulating layer 73, the insulating layer 74, and the like. The via 124B is a connection member that electrically connects the first electrode 121B of the inorganic LED 12B and the drive circuit or wiring of the drive substrate 11. The via 124G is a connection member that electrically connects the first electrode 121G of the inorganic LED 12G and the drive circuit or wiring of the drive substrate 11. The via 143R is a connection member that electrically connects the first electrode 141R of the organic LED 14R and the drive circuit or wiring of the drive substrate 11. The vias 124B, 124G, and 144R contain, for example, at least one metal selected from a group including copper (Cu), titanium (Ti), and the like.

### [Operations and Effects]

As the display device, a display device in which inorganic LEDs of three colors of a blue inorganic LED, a green inorganic LED, and a red inorganic LED are laminated can be considered. However, as described in “Outline” in the first embodiment, since the red inorganic LED has low luminous efficiency, the luminous efficiency of the display device having the above configuration may be lowered.

On the other hand, in the display device 605 according to the 19th embodiment, LEDs of three colors of a blue inorganic LED 12B, a green inorganic LED 12G, and a red organic LED 14R are laminated. Therefore, it is possible to suppress a decrease in luminous efficiency of the display device 605.

### [Modifications]

### (Modification 1)

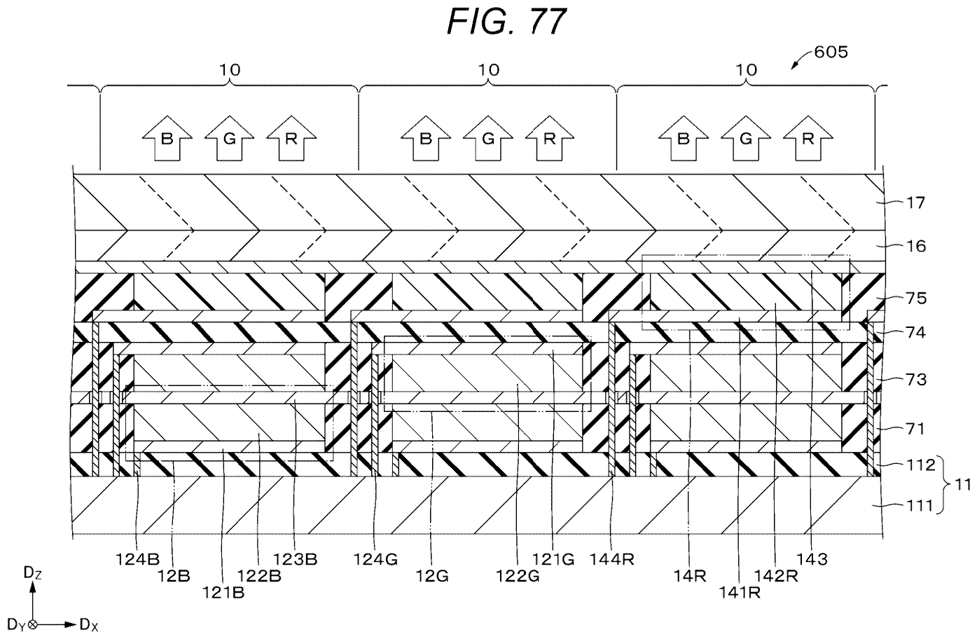

In the 19th embodiment, the example (see FIG. 76) in which the plurality of inorganic LEDs 12B and the plurality of inorganic LEDs 12G separately include the second electrodes 123B and 123G has been described, but as shown in FIG. 77, the plurality of inorganic LEDs 12B and the plurality of inorganic LEDs 12G may share one second electrode 123B. In this case, the inorganic layer 122G and the first electrode 121G are provided on the first surface of the second electrode 123B in this order. According to the display device 605 according to Modification 1, since the second electrodes 123G of the plurality of inorganic LEDs 12G are omitted, the configuration of the display device 605 can be simplified.

### (Modification 2)

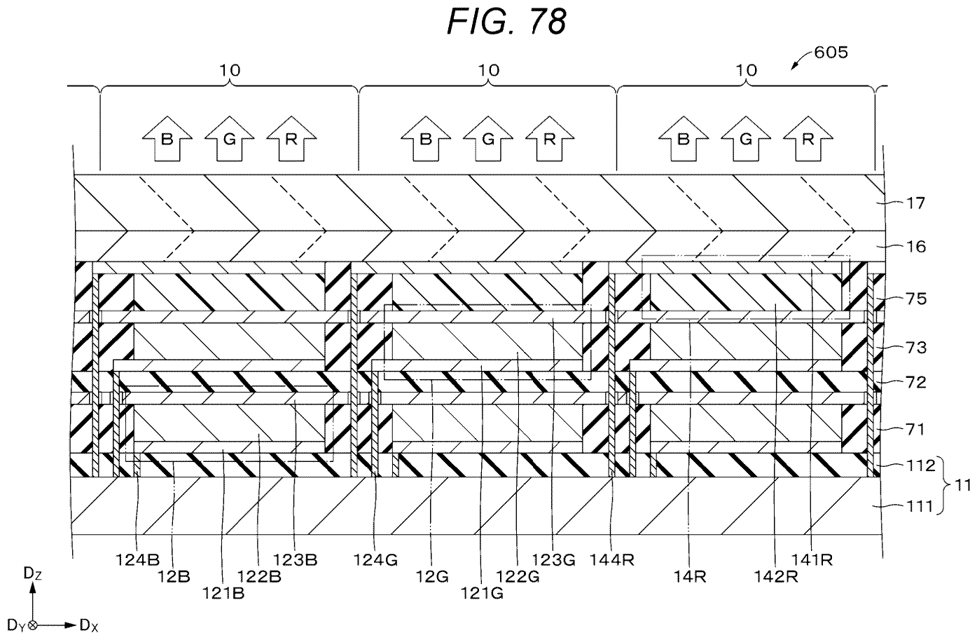

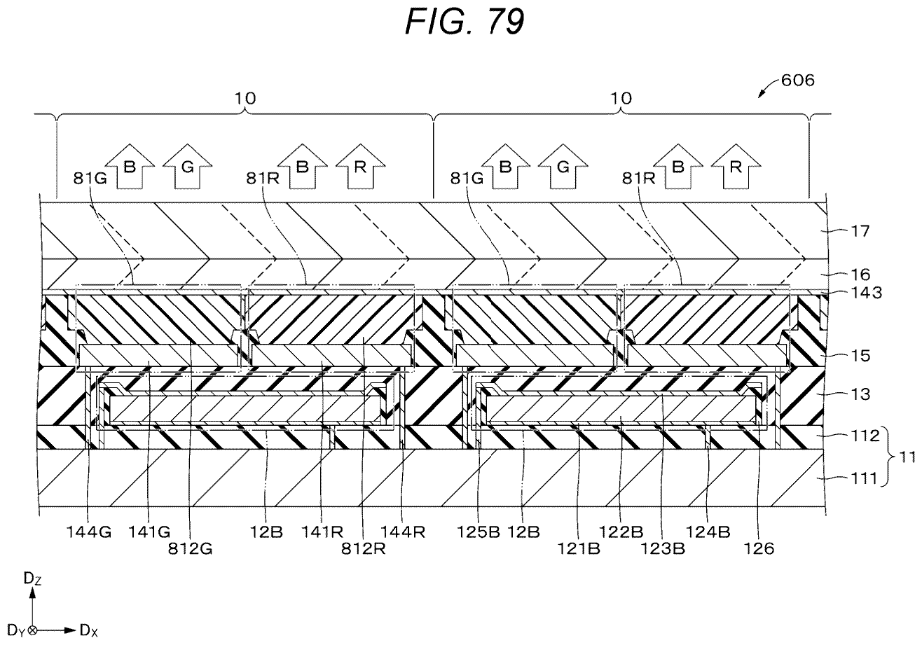

As illustrated in FIG. 78, the plurality of inorganic LEDs 12G and the plurality of organic LEDs 14R may share one second electrode 123G. In this case, the organic layer 142R and the first electrode 141R are provided on the first surface of the second electrode 123G in this order. According to the display device 605 according to Modification 2, since the second electrodes 143 of the plurality of organic LEDs 14R are omitted, the configuration of the display device 605 can be simplified.

### (Modification 3)

In the 19th embodiment and Modifications 1 and 2 thereof, an example in which the display device 605 includes the plurality of inorganic LEDs 12B, the plurality of inorganic LEDs 12G, and the plurality of organic LEDs 14R has been described, but the combination of the types of the organic LED and the inorganic LED is not limited to this example. For example, the display device 605 may include a plurality of inorganic LEDs 12B, a plurality of organic LEDs 14G, and a plurality of organic LEDs 14R.

### (Modification 4)

In the display device 605 according to the 19th embodiment and Modifications 1 and 2 thereof, an example in which the inorganic LED 12B, the inorganic LED 12G, and the organic LED 14R are provided on the first surface of the drive substrate 11 in this order has been described, but the order of lamination of these LEDs is not particularly limited, and these LEDs can be laminated in any order.

### 20 20th Embodiment

As described in “Outline” in the first embodiment, the lengths of the drive lives of the organic LEDs of the three primary colors tend to be shortened in the order of (1) the red organic LED (having the longest drive life), (2) the green organic LED, and (3) the blue organic LED (having the shortest drive life). A quantum dot light emitting diode (QLED) of three primary colors also has a tendency of a light emission lifetime similar to that of an organic LED of three primary colors. Therefore, in a 20th embodiment, a display device in which each pixel includes one blue inorganic LED, one green QLED, and one red QLED will be described.

### [Configuration of Display Device 606]

FIG. 79 is a cross-sectional view illustrating an example of a configuration of the display device 606 according to the 20th embodiment. The display device 606 is different from the display device 101 according to the first embodiment in including a plurality of quantum dot light emitting diodes (QLEDs) 81R and a plurality of QLEDs 81G instead of the plurality of organic LEDs 14R and the plurality of organic LEDs 14G.

The QLED 81R can emit red light. The QLED 81R is different from the organic LED 14R in including a quantum dot light emitting layer (hereinafter, referred to as a “QD layer”) 812R instead of the organic layer 142R. The QD layer 812R includes a quantum dot (QD) light-emitting material capable of emitting red light. The QLED 81R may further include an electron transport layer, a hole transport layer, and the like as necessary.

The QLED 81G can emit green light. The QLED 81G is different from the organic LED 14G in including a QD layer 812G instead of the organic layer 142G. The QD layer 812G includes a quantum dot (QD) light-emitting material capable of emitting green light. The QLED 81G may further include an electron transport layer, a hole transport layer, and the like as necessary.

### [Operations and Effects]

In the display device 606 according to the 20th embodiment, each pixel 10 includes one inorganic LED 12B and two QLEDs 81R and 81G. Therefore, the luminous efficiency can be improved (that is, the power consumption can be reduced) as compared with the display device in which the inorganic LEDs of the three primary colors are two-dimensionally arranged, and the life can be extended as compared with the display device in which the organic LEDs of the three primary colors are two-dimensionally arranged.

### [Modifications]

In the 20th embodiment, the example in which the display device 606 includes the plurality of QLEDs 81R and the plurality of QLEDs 81G has been described, but instead of the plurality of QLEDs 81R and the plurality of QLEDs 81G, a plurality of red perovskite light emitting diodes (PLED) and a plurality of blue PLEDs may be included.

The three primary color PLEDs also have a tendency of light emission lifetime similar to that of the three primary color organic LEDs. Therefore, since each pixel includes one inorganic LED 12B, one red PLED, and one green PLED, it is possible to obtain an effect similar to that of the 20th embodiment.

<21 Relationship among Normal Lines Extending through Centers of Light Emitting Units, Lens Members, and Wavelength Selection Units>

In the description below, the relationship among a normal line LN extending through the center of a light emitting unit, a normal line LN′ extending through the center of a lens member, and a normal line LN″ extending through the center of a wavelength selection unit is described. Here, the light emitting unit is, for example, any of the organic LEDs 14R, 14G, 14Y1, 14Y2, 21Y, and 24R, and the inorganic LEDs 22B, 22BG1, and 22BG2. The lens member is, for example, the lens 25L of the lens array 25. The wavelength selection unit is, for example, filter units 19M, 19C, 24Y, and 24M.

Note that the size of the wavelength selection units may be changed as appropriate in accordance with light emitted from the light emitting units, or, in a case where the light absorbing units (black matrix portions, for example) are provided between the wavelength selection units of adjacent light emitting units, the size of the light absorbing units may be changed as appropriate in accordance with light emitted from the light emitting units. Also, the size of each wavelength selection unit may be changed as appropriate in accordance with the distance (offset amount) do between the normal line extending through the center of the light emitting unit and the normal line extending through the center of the wavelength selection unit. The planar shape of each wavelength selection unit may be the same as, similar to, or different from the planar shape of each lens member.

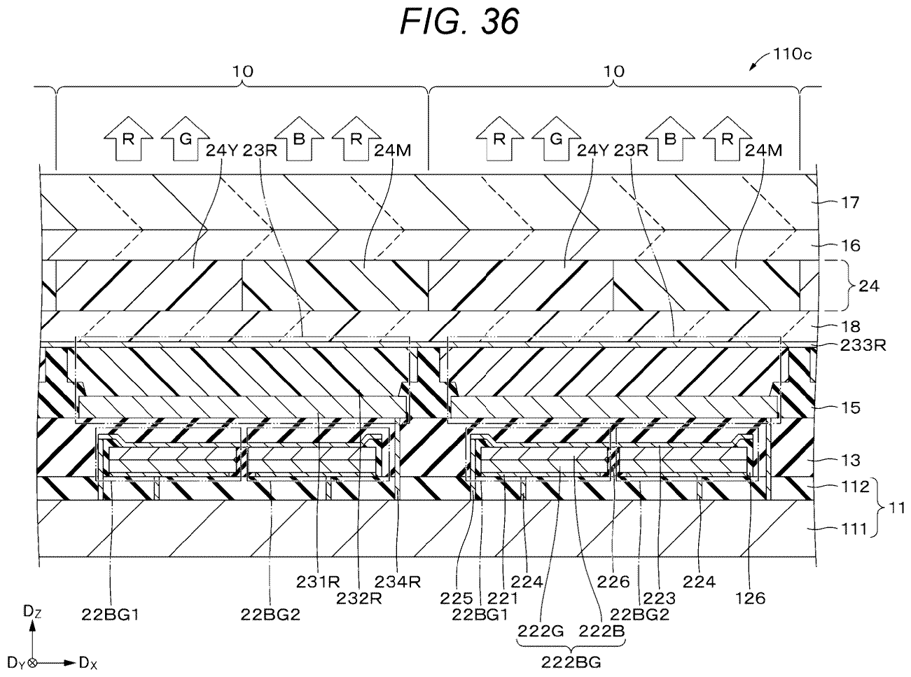

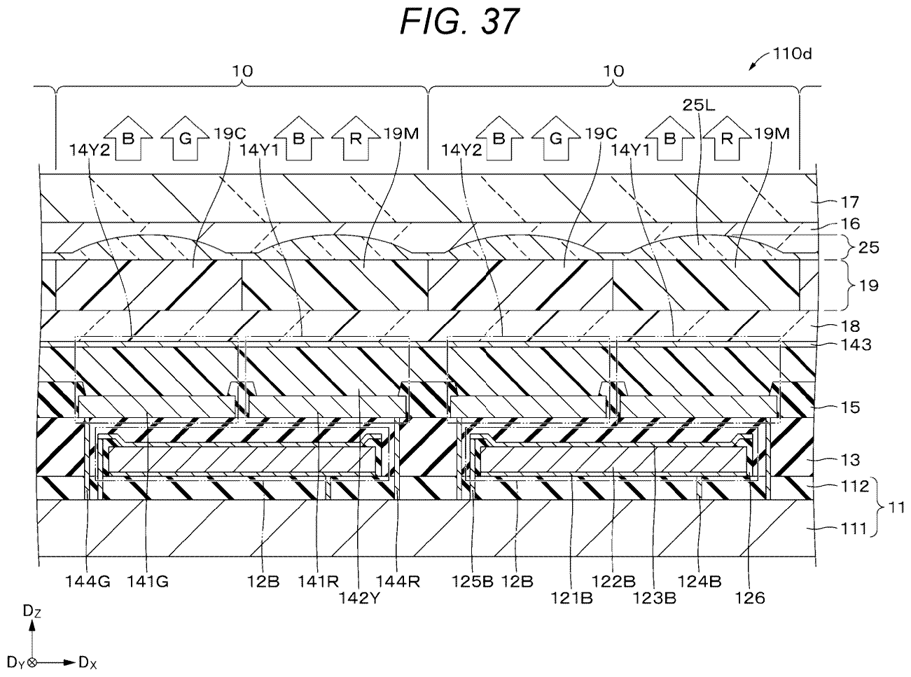

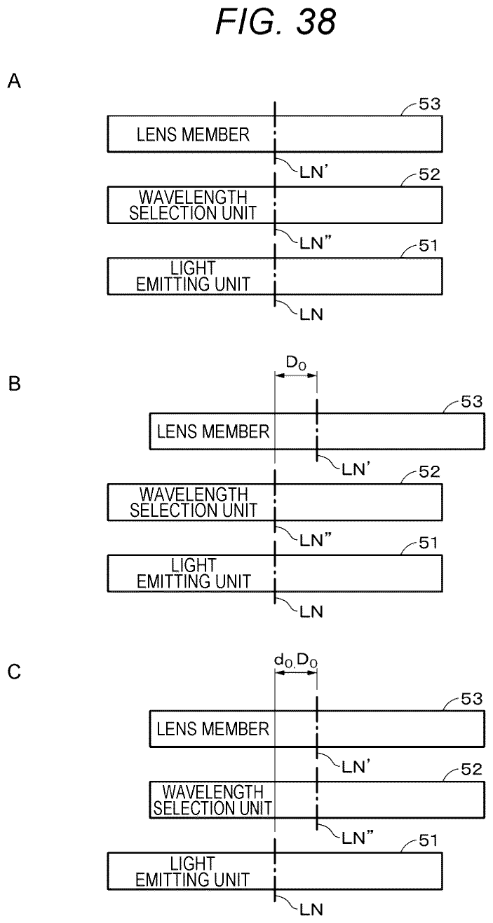

Hereinafter, with reference to FIGS. 38A, 38B, 38 C, and 39, a relationship of a normal line passing through the center of each part in a case where the light emitting unit 51, the wavelength selection unit 52, and the lens member 53 are arranged in this order will be described.

As illustrated in FIG. 38A, the normal line LN extending through the center of the light emitting unit 51, the normal line LN″ extending through the center of the wavelength selection unit 52, and the normal line LN′ extending through the center of the lens member 53 may coincide with one another. That is, D₀=0 and d₀=0 may be satisfied. Here, D₀ represents the distance (offset amount) between the normal line LN extending through the center of the light emitting unit 51 and the normal line LN′ extending through the center of the lens member 53, and do represents the distance (offset amount) between the normal line LN extending through the center of the light emitting unit 51 and the normal line LN″ extending through the center of the wavelength selection unit 52.

As illustrated in a configuration in FIG. 38B, the normal line LN extending through the center of the light emitting unit 51 and the normal line LN″ extending through the center of the wavelength selection unit 52 may coincide with each other, but the normal line LN extending through the center of the light emitting unit 51 and the normal line LN″ extending through the center of the wavelength selection unit 52 may not coincide with the normal line LN′ extending through the center of the lens member 53. That is, D₀>0 and d₀=0 may be satisfied.

As illustrated in a configuration in FIG. 38C, the normal line LN extending through the center of the light emitting unit 51 may not coincide with the normal line LN″ extending through the center of the wavelength selection unit 52 and the normal line LN′ extending through the center of the lens member 53, and the normal line LN″ extending through the center of the wavelength selection unit 52 may coincide with the normal line LN′ extending through the center of the lens member 53. That is, D₀>0, d₀>0, and D₀=d₀ may be satisfied.

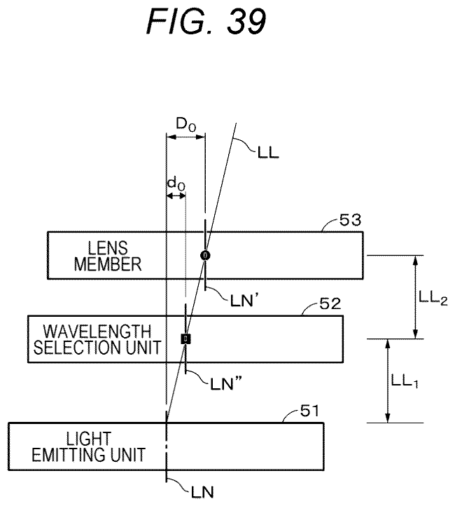

As illustrated in a configuration in FIG. 39, the normal line LN extending through the center of the light emitting unit 51, the normal line LN″ extending through the center of the wavelength selection unit 52, and the normal line LN′ extending through the center of the lens member 53 may not coincide with one another. That is, D₀>0, d₀>0, and D₀≠d₀ may be satisfied. Here, the center of the wavelength selection unit 52 (the position indicated by a black square in FIG. 39) is preferably located on the straight line LL connecting the center of the light emitting unit 51 and the center of the lens member 53 (the position indicated by a black circle in FIG. 39). Specifically, where the distance in the thickness direction (the vertical direction in FIG. 39) between the center of the light emitting unit 51 and the center of the wavelength selection unit 52 is represented by LL₁, and the distance in the thickness direction between the center of the wavelength selection unit 52 and the center of the lens member 53 is represented by LL₂,
the following is preferably satisfied,

D₀>d₀>0
and, with manufacturing variations being taken into consideration, the following is preferably satisfied,

d₀: D₀=LL₁:(LL₁+LL₂)

Here, the thickness direction indicates the thickness direction of the light emitting unit 51, the wavelength selection unit 52, and the lens member 53.

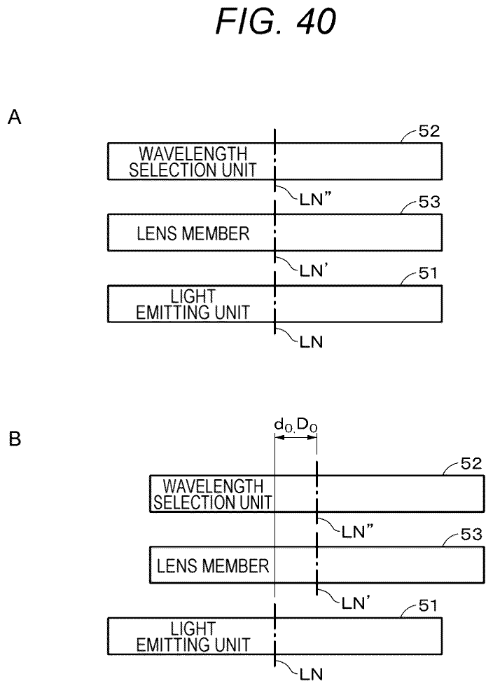

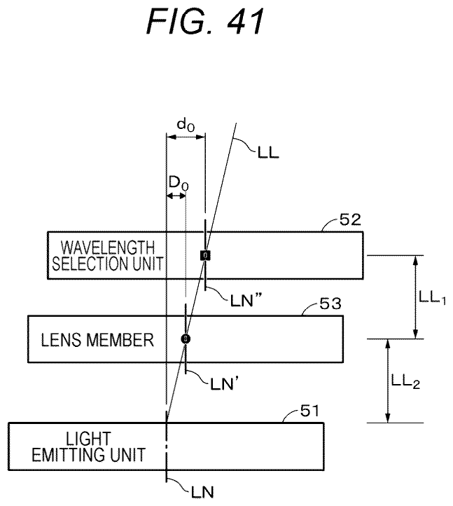

In the description below, referring to FIGS. 40A, 40B, and 41, the relationship among the normal lines extending through the center of the respective members in a case where the light emitting unit 51, the lens member 53, and the wavelength selection unit 52 are arranged in this order will be described.

As illustrated in a configuration in FIG. 40A, the normal line LN extending through the center of the light emitting unit 51, the normal line LN″ extending through the center of the wavelength selection unit 52, and the normal line LN′ extending through the center of the lens member 53 may coincide with one another. That is, D₀>0 and d₀=0 may be satisfied.

As illustrated in a configuration in FIG. 40B, the normal line LN extending through the center of the light emitting unit 51 may not coincide with the normal line LN″ extending through the center of the wavelength selection unit 52 and the normal line LN′ extending through the center of the lens member 53, and the normal line LN″ extending through the center of the wavelength selection unit 52 may coincide with the normal line LN′ extending through the center of the lens member 53. That is, D₀>0, d₀>0, and D₀=d₀ may be satisfied.

As illustrated in a configuration in FIG. 41, the normal line LN extending through the center of the light emitting unit 51, the normal line LN″ extending through the center of the wavelength selection unit 52, and the normal line LN′ extending through the center of the lens member 53 may not coincide with one another. Here, the center of the lens member 53 (the position indicated by a black circle in FIG. 41) is preferably located on the straight line LL connecting the center of the light emitting unit 51 and the center of the wavelength selection unit 52 (the position indicated by a black square in FIG. 41). Specifically, where the distance in the thickness direction (the vertical direction in FIG. 41) between the center of the light emitting unit 51 and the center of the lens member 53 is represented by LL₂, and the distance in the thickness direction between the center of the lens member 53 and the center of the wavelength selection unit 52 is represented by LL₁,
the following expression is preferably satisfied,

d₀>D₀>0
and, with manufacturing variations being taken into consideration, the following expression is preferably satisfied,

D₀: d₀=LL₂:(LL₁+LL₂)

Here, the thickness direction indicates the thickness direction of the light emitting unit 51, the wavelength selection unit 52, and the lens member 53.

### 22 Example of Resonator Structure

In the above embodiment, from the viewpoint of improving the light extraction efficiency and/or improving the color purity, the organic LED (for example, organic LEDs 14R, 14G, 14Y, 21Y, 24R, and the like) and the inorganic LED (for example, inorganic LEDs 12B, 22BG, and the like) may have a resonator structure. In the present specification, the term “and/or” means “at least one”, and for example, in a case where the term is used in a phrase “X and/or Y”, this phrase means three cases of “only X”, “only Y”, and “X and Y”.

In a case where the first electrode is a reflective electrode having a function as a reflection layer, a resonator structure may be configured by the first electrode and the second electrode. In this case, an optical distance between the first electrode and the second electrode may be set by the thickness of the organic layer or the inorganic layer, may be set by selecting the material of the first electrode, or may be set by a combination thereof.

In a case where the first electrode is a transparent electrode, a reflection layer may be provided below the transparent electrode, and the reflection layer and the second electrode may configure a resonator structure. In this case, the optical distance between the reflection layer and the second electrode may be set by the thickness of the organic layer or the inorganic layer, may be set by selecting the material of the reflection layer, may be set by the thickness of the insulating layer provided between the first electrode (transparent electrode) and the reflection layer, or may be set by a combination of two or more thereof.

### 23 Application Example

### (Electronic Apparatus)

The display devices 101, 102, 103, 104, 105, 106, 107, 108, 109, 110, 110a, 110b, 110c, and 110d (hereinafter, referred to as a “display device 101 and the like”) according to the above-described embodiments and modifications thereof may be provided in various electronic apparatuses. Similarly, the display devices 601, 602, 603, 604, 605, and 606 according to the above-described embodiments and modifications thereof are also referred to as various electronic apparatuses (hereinafter, the display device 601 and the like).). The display device 101 and the like and the display device 601 and the like are suitable especially for an electronic view finder of a video camera or a single-lens reflex camera, a head-mounted display, or the like requiring high resolution and used near the eyes in an enlarged manner.

### Specific Example 1

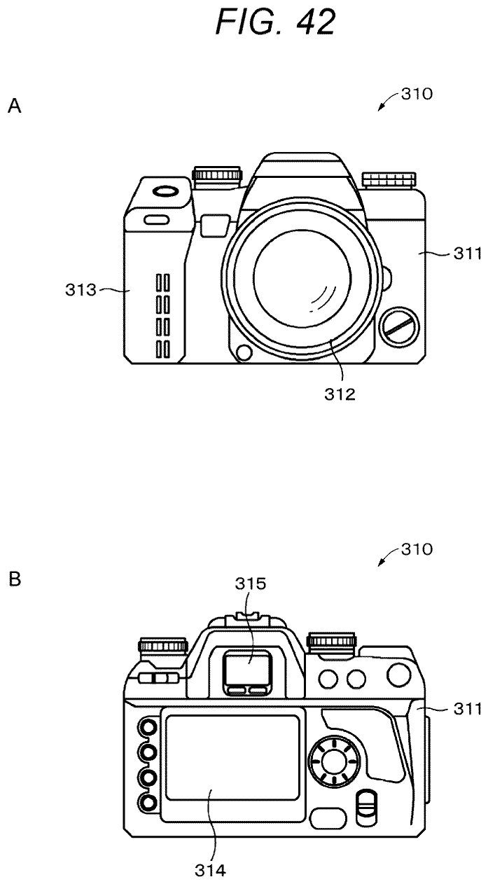

FIGS. 42A and 42B illustrate an example of an external appearance of a digital still camera 310. The digital still camera 310 is of a lens interchangeable single-lens reflex type, and includes an interchangeable imaging lens unit (interchangeable lens) 312 substantially at the center on the front surface of a camera main body (camera body) 311, and a grip 313 to be held by the photographer on the front left side.

A monitor 314 is provided at a position shifted to the left side from the center of the rear surface of the camera main body 311. An electronic view finder (eyepiece window) 315 is provided above the monitor 314. By looking through the electronic view finder 315, the photographer can visually recognize an optical image of the subject guided from the imaging lens unit 312, and determine a picture composition. The electronic view finder 315 includes any of the above-described display device 101 and the like. The electronic view finder 315 may include any of the above-described display device 601 and the like.

### Specific Example 2

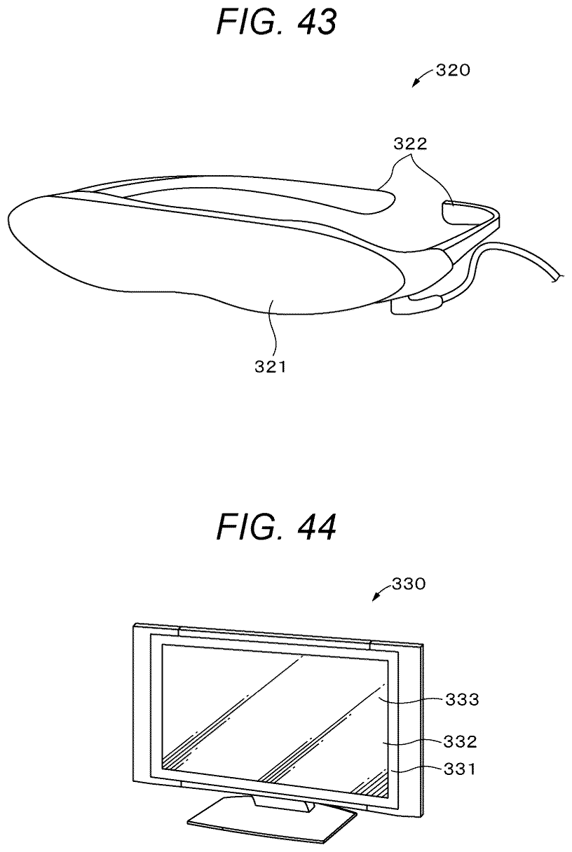

FIG. 43 illustrates an example of an external appearance of a head-mounted display 320. The head-mounted display 320 includes ear hooking portions 322 to be worn on the head of the user on both sides of a display unit 321 in the shape of eyeglasses, for example. The display unit 321 includes any one of the above-described display device 101 and the like. The display unit 321 may include any of the above-described display device 601 and the like.

### Specific Example 3

FIG. 44 illustrates an example of an external appearance of a television device 330. The television device 330 includes, for example, a video display screen unit 331 including a front panel 332 and a filter glass 333, and the video display screen unit 331 includes any one of the display device 101 described above and the like. The video display screen unit 331 may include any of the above-described display device 601 and the like.

### Specific Example 4

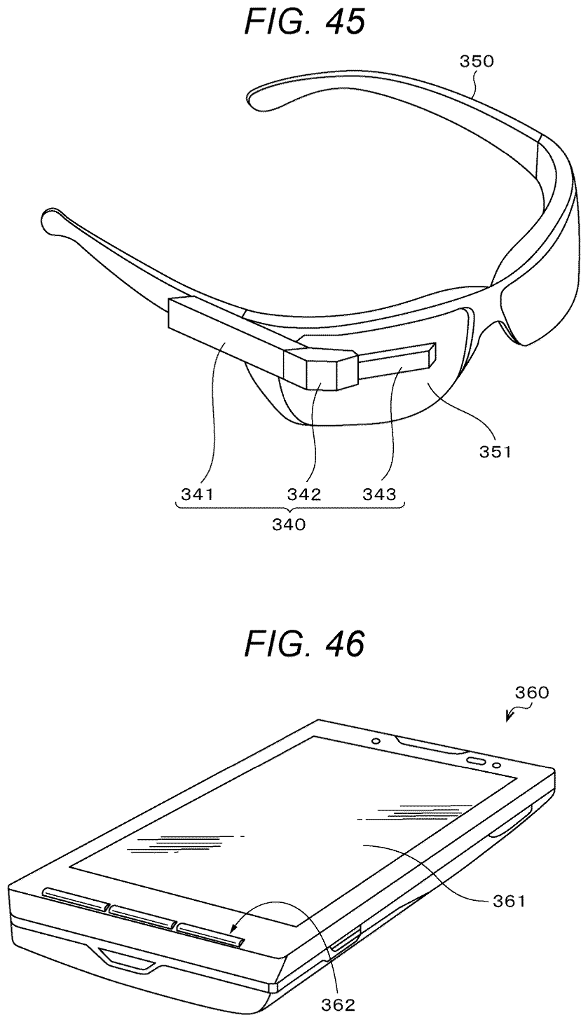

FIG. 45 illustrates an example of an external appearance of a see-through head-mounted display 340. The see-through head-mounted display 340 includes a main body 341, an arm 342, and a lens barrel 343.

The main body 341 is connected to the arm 342 and eyeglasses 350. Specifically, an end portion of the main body 341 in the long side direction is coupled to the arm 342, and one side of a side surface of the main body 341 is coupled to the eyeglasses 350 via a connecting member. Note that the main body 341 may be directly mounted on the head of the human body.

The main body 341 incorporates a control board for controlling operation of the see-through head-mounted display 340, and a display unit. The arm 342 connects the main body 341 and the lens barrel 343, and supports the lens barrel 343. Specifically, the arm 342 is coupled to an end portion of the main body 341 and an end portion of the lens barrel 343, and secures the lens barrel 343. Furthermore, the arm 342 incorporates a signal line for communicating data related to an image to be provided from the main body 341 to the lens barrel 343.

The lens barrel 343 projects image light provided from the main body 341 through the arm 342 toward the eyes of the user wearing the see-through head-mounted display 340 through an eyeglass 351. In this see-through head-mounted display 340, the display unit of the main body 341 includes one of the above display device 101 and the like. The display unit of the main body 341 may include any of the above-described display device 601 and the like.

### Specific Example 5

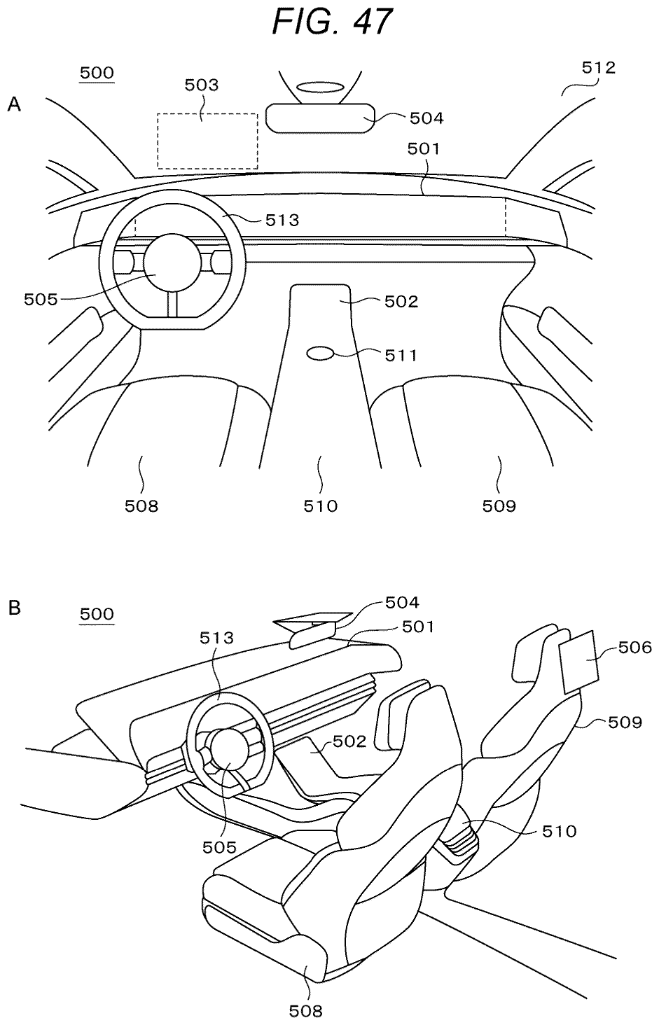

FIG. 46 illustrates an example of an external appearance of a smartphone 360. The smartphone 360 includes a display unit 361 for displaying various types of information, an operation unit 362 including a button for receiving an operation input by the user, and the like. The display unit 361 includes any one of the above-described display devices 101 and the like. The display unit 361 may include any of the above-described display devices 601 and the like.

### Specific Example 6

The display device 101 and the like described above may be included in a vehicle or in various kinds of displays. Similarly, the above-described display device 601 and the like may also be provided in various displays provided in the vehicle.

FIGS. 47A and 47B are diagrams illustrating an example of an internal configuration of a vehicle 500 provided with various displays. Specifically, FIG. 47A is a diagram illustrating an example of an internal state of the vehicle 500 as viewed from the rear side to the front side of the vehicle 500. FIG. 47B is a diagram illustrating an example of an internal state of the vehicle 500 as viewed obliquely from the rear side to the front side of the vehicle 500.

The vehicle 500 includes a center display 501, a console display 502, a head-up display 503, a digital rearview mirror 504, a steering wheel display 505, and a rear entertainment display 506. At least one of these displays includes any one of the above display device 101 and the like. Alternatively, at least one of these displays includes any one of the display device 101 and the like and the display device 601 and the like described above. For example, all of these displays may include one of the above display device 101 and the like. All of these displays may include any one of the display device 101 and the like and the display device 601 and the like described above.

The center display 501 is disposed on the dashboard at a location facing a driver's seat 508 and a passenger seat 509. FIGS. 47A and 47B illustrate an example of the center display 501 having a horizontally long shape extending from the side of the driver's seat 508 to the side of the passenger seat 509, but any screen size and installation location for the center display 501 may be adopted. The center display 501 can display information sensed by various sensors. As a specific example, the center display 501 can display an image captured by an image sensor, an image of the distance to an obstacle in front of or on a side of the vehicle 500, the distance being measured by a ToF sensor, a passenger's body temperature detected by an infrared sensor, and the like. The center display 501 can be used to display at least one piece of safety-related information, operation-related information, lifelogs, health-related information, authentication/identification-related information, or entertainment-related information, for example.

The safety-related information is information about doze sensing, looking-away sensing, sensing of mischief of a child riding together, presence or absence of wearing of a seat belt, sensing of leaving of an occupant, and the like, and is information sensed by a sensor disposed to overlap with the back surface side of the center display 501, for example. The operation-related information senses a gesture related to an operation performed by an occupant, using a sensor. Gestures to be sensed may include an operation of various kinds of equipment in the vehicle 500. For example, operations of air conditioning equipment, a navigation device, an audiovisual (AV) device, an illuminating device, and the like are detected. The lifelogs include lifelogs of all the occupants. For example, the lifelogs include an action record of each occupant in the vehicle. By acquiring and storing the lifelogs, it is possible to check the state of each occupant at the time of an accident. The health-related information senses the body temperature of an occupant, using a sensor such as a temperature sensor, and estimates the health condition of the occupant on the basis of the sensed body temperature. Alternatively, the face of the occupant may be imaged with an image sensor, and the health condition of the occupant may be estimated from the imaged facial expression. Further, a conversation may be made with an occupant in automatic voice, and the health condition of the occupant may be estimated on the basis of the contents of a response from the occupant. The authentication/identification-related information includes a keyless entry function of performing face authentication using a sensor, and a function of automatically adjusting a seat height and position through face identification. The entertainment-related information includes a function of detecting, with a sensor, operation information about an AV device being used by an occupant, and a function of recognizing the face of the occupant with sensor and providing content suitable for the occupant through the AV device.

The console display 502 can be used to display lifelog information, for example. The console display 502 is disposed near a shift lever 511 of a center console 510 between the driver's seat 508 and the passenger seat 509. The console display 502 can also display information detected by various sensors. Furthermore, the console display 502 may display an image of the surroundings of the vehicle captured with an image sensor, or may display an image of the distance to an obstacle present in the surroundings of the vehicle.

The head-up display 503 is virtually displayed behind a windshield 512 in front of the driver's seat 508. The head-up display 503 can be used to display at least one piece of the safety-related information, the operation-related information, the lifelogs, the health-related information, the authentication/identification-related information, or the entertainment-related information, for example. Being virtually disposed in front of the driver's seat 508 in many cases, the head-up display 503 is suitable for displaying information directly related to operations of the vehicle 500, such as the speed, the remaining amount of fuel (battery), and the like of the vehicle 500.

The digital rearview mirror 504 can not only display the rear of the vehicle 500 but also display the state of an occupant in the rear seat, and thus, can be used to display the lifelog information by disposing a sensor on the back surface side of the digital rearview mirror 504 in an overlapping manner, for example.

The steering wheel display 505 is disposed near the center of a steering wheel 513 of the vehicle 500. The steering wheel display 505 can be used to display at least one piece of the safety-related information, the operation-related information, the lifelogs, the health-related information, the authentication/identification-related information, or the entertainment-related information, for example. In particular, being located close to the driver's hands, the steering wheel display 505 is suitable for displaying the lifelog information such as the body temperature of the driver, or for displaying information regarding operations of the AV device, the air conditioning equipment, or the like.

The rear entertainment display 506 is attached to the back side of the driver's seat 508 or the passenger seat 509, and is for an occupant in the rear seat to enjoy viewing/listening. The rear entertainment display 506 can be used to display at least one piece of the safety-related information, the operation-related information, the lifelogs, the health-related information, the authentication/identification-related information, or the entertainment-related information, for example. In particular, as the rear entertainment display 506 is located in front of an occupant in the rear seat, information related to the occupant in the rear seat is displayed. For example, information regarding an operation of the AV device or the air conditioning equipment may be displayed, or a result of measurement of the body temperature or the like of an occupant in the rear seat with a temperature sensor may be displayed.

A sensor may be disposed on the back surface side of the display device 101 or the like or the display device 606 or the like, and a distance to an object existing in the surroundings may be measured. Optical distance measurement methods are roughly classified into a passive type and an active type. By a method of the passive type, distance measurement is performed by receiving light from an object, without projecting light from a sensor to the object. Methods of the passive type include a lens focus method, a stereo method, and a monocular vision method. Methods of the active type include distance measurement that is performed by projecting light onto an object, and receiving reflected light from the object with a sensor to measure the distance. Methods of the active type include an optical radar method, an active stereo method, an illuminance difference stereo method, a moire topography method, and an interference method. The display device 101 and the like or the display device 606 and the like can be applied to any of these types of distance measurement. With a sensor disposed on the back surface side of the above display device 101 or the like in an overlapping manner, distance measurement of the passive type or the active type described above can be performed.

Although the first to 14th embodiments, the 15th to 20th embodiments, and modifications thereof of the present disclosure have been specifically described above, the present disclosure is not limited to the first to 14th embodiments, the 15th to 20th embodiments, and modifications thereof, and various modifications based on the technical idea of the present disclosure can be made.

For example, the configurations, methods, processes, shapes, materials, numerical values, and the like described in the first to 14th embodiments, the 15th to 20th embodiments, and the modifications thereof are merely examples, and configurations, methods, steps, shapes, materials, numerical values, and the like different therefrom may be used as necessary.

For example, the configurations, methods, steps, shapes, materials, numerical values, and the like of the first to 14th embodiments, the 15th to 20th embodiments, and modifications thereof can be combined with each other without departing from the gist of the present disclosure.

For example, the materials exemplified in the first to 14th embodiments, the 15th to 20th embodiments, and the modifications thereof can be used alone or in combination of two or more unless otherwise specified.

In the third, fourth, seventh, eighth, 11th, and 12th embodiments, an example in which one or two organic LEDs and one inorganic LED share the second electrode (cathode) has been described, but one or two organic LEDs and one inorganic LED may share the first electrode (anode) instead of the second electrode (cathode). In this case, the second electrode (cathode) may be separately provided by a plurality of organic LEDs in the display region. In addition, the second electrode (cathode) side may be connected to the drive circuit.

Further, the present disclosure can also adopt the following configurations.
(1)
A display device including:
a plurality of inorganic light emitting diodes arranged two-dimensionally; and
a plurality of organic light emitting diodes arranged two-dimensionally, in which
at least one of the organic light emitting diodes is provided on an upper portion of or above at least one of the inorganic light emitting diodes or on a lower portion of or below at least one of the inorganic light emitting diodes.
(2)

The display device according to (1), in which
light emission colors of the inorganic light emitting diodes and the organic light emitting diodes are different.
(3)

The display device according to (1) or (2), in which
at least two of the organic light emitting diodes are provided on an upper portion of or above one of the inorganic light emitting diodes or on a lower portion of or below one of the inorganic light emitting diodes.
(4)

The display device according to any one of (1) to (3), in which
a peak wavelength of emission light of the inorganic light emitting diodes is shorter than a peak wavelength of emission light of the organic light emitting diodes.
(5)

The display device according to any one of (1) to (4), further including
a color conversion layer, in which
the color conversion layer is capable of performing color conversion on light emitted from the plurality of organic light emitting diodes.
(6)

The display device according to (5), in which
the color conversion layer can transmit light emitted from the plurality of inorganic light emitting diodes without color conversion.
(7)

The display device according to (5) or (6), in which
the color conversion layer is a color filter or a dielectric multilayer film structure.
(8)

The display device according to any one of (1) to (4), in which
the plurality of organic light emitting diodes includes a plurality of first organic light emitting diodes and a plurality of second organic light emitting diodes,
one of the first organic light emitting diodes and one of the second organic light emitting diodes are provided on an upper portion of or above one of the inorganic light emitting diodes or on a lower portion of or below one of the inorganic light emitting diodes, and
the first organic light emitting diodes, the second organic light emitting diodes, and the inorganic light emitting diodes have different light emission colors.
(9)

The display device according to (8), further including
a color conversion layer, in which
the color conversion layer includes a plurality of first color conversion units and a plurality of second color conversion units, and
the first color conversion units are capable of performing color conversion on light emitted from the first organic light emitting diodes, and
the second color conversion units are capable of performing color conversion on light emitted from the second organic light emitting diodes.
(10)

The display device according to any one of (1) to (4), further including
a color conversion layer, in which
the color conversion layer is capable of performing color conversion on light emitted from the plurality of organic light emitting diodes, and
the plurality of organic light emitting diodes share an organic layer including a light emitting layer.
(11)

The display device according to (1) or (2), in which
the inorganic light emitting diodes are capable of emitting a first light having a first peak wavelength and a second light having a second peak wavelength, and
the organic light emitting diodes are capable of emitting a third light having a third peak wavelength.
(12)

The display device according to (1) or (2), in
which
the inorganic light emitting diode includes:
a first light emitting layer capable of emitting a first light having a first peak wavelength; and
a second light emitting layer capable of emitting a second light having a second peak wavelength.
(13)

The display device according to (11) or (12), in which
at least two of the inorganic light emitting diodes are provided on an upper portion of or above one of the organic light emitting diodes or on a lower portion of or below one of the organic light emitting diodes.
(14)

The display device according to any one of (11) to (13), further including
a color conversion layer, in which
the color conversion layer is capable of performing color conversion on the first light and the second light emitted from the plurality of inorganic light emitting diodes.
(15)

The display device according to (14), in which
the color conversion layer is capable of transmitting light emitted from the plurality of organic light emitting diodes without color conversion.
(16)

The display device according to any one of (11) to (15), in which
at least two of the inorganic light emitting diodes share one cathode.
(17)

The display device according to any one of (1) to (15), in which
the plurality of organic light emitting diodes share one cathode.
(18)

The display device according to any one of (1) to (15), in which
the plurality of inorganic light emitting diodes share one cathode.
(19)

The display device according to any one of (1) to (15), in which
the organic light emitting diodes and the inorganic light emitting diodes share a cathode or an anode.
(20)

The display device according to any one of (1) to (19), in which
the plurality of organic light emitting diodes includes a plurality of first organic light emitting diodes and a plurality of second organic light emitting diodes,
the first organic light emitting diodes included in adjacent pixels share one first light emitting layer, and
the second organic light emitting diodes included in adjacent pixels share one second light emitting layer.
(21)

The display device according to any one of (1) to (20), further including
a color conversion layer including a plurality of color conversion units, in which
adjacent pixels share one of the color conversion units.
(22)

The display device according to any one of (1) to (21), further including
a first reflection layer, in which
the first reflection layer is provided between the at least one inorganic light emitting diode and the at least one organic light emitting diode, and
the organic light emitting diode includes a first electrode, an organic light emitting layer, and a second electrode, and
the second electrode of the organic light emitting diode and the first reflection layer configure a first resonator structure that resonates light emitted from the organic light emitting diodes.
(23)

The display device according to (22), in which
the inorganic light emitting diode includes a first electrode, an inorganic light emitting layer, and a second electrode,
the first electrode of the inorganic light emitting diode and the first reflection layer configure a second resonator structure that resonates light emitted from the inorganic light emitting diode.
(24)

The display device according to (22) or (23), in which
the first reflection layer includes a dielectric multilayer film, a metal layer, or a laminate thereof.
(25)

The display device according to any one of (22) to (24), further including
a second reflection layer, in which
the second reflection layer is provided on an upper portion or above a light emitting diode provided on an upper side of the organic light emitting diode and the inorganic light emitting diode, and
the second reflection layer includes a dielectric multilayer film, a metal layer, or a laminate thereof.
(26)

The display device according to any one of (1) to (25), further including
a wall portion provided between the pixels or between the subpixels, in which
the wall portion is configured to be capable of reflecting or refracting light.
(27)

The display device according to (26), further including
a drive substrate, in which
the wall portion also serves as a connection member that connects an upper side light emitting diode of the organic light emitting diode or the inorganic light emitting diode to the drive substrate.
(28)

A display device including:
a plurality of first light emitting diodes arranged two-dimensionally; and
a plurality of second light emitting diodes arranged two-dimensionally, in which
the plurality of first light emitting diodes includes a plurality of inorganic light emitting diodes,
the plurality of second light emitting diodes include at least one type of a plurality of organic light emitting diodes, a plurality of quantum dot light emitting diodes, and a plurality of perovskite light emitting diodes, and
at least one of the second light emitting diodes is provided on an upper portion of or above at least one of the first light emitting diodes, or on a lower portion of or below at least one of the first light emitting diodes.
(29)
A display device including:
a plurality of first light emitting diodes arranged two-dimensionally;
a plurality of second light emitting diodes arranged two-dimensionally; and
a plurality of third light emitting diodes arranged two-dimensionally, in which
the second light emitting diodes are provided on an upper portion of or above the first light emitting diodes,
the third light emitting diodes are provided on an upper portion of or above the second light emitting diodes, and
at least one kind of light emitting diodes among three kinds of light emitting diodes including the first light emitting diodes, the second light emitting diodes, and the third light emitting diodes are inorganic light emitting diodes, and the remaining light emitting diodes among the three kinds of light emitting diodes are at least one kind of organic light emitting diodes, quantum dot light emitting diodes, and perovskite light emitting diodes.
(30)

An electronic apparatus including the display device according to any one of (1) to (19).
(31)

An electronic apparatus including the display device according to any one of (1) to (29).

### REFERENCE SIGNS LIST

10, 20 Pixel
10R, 10G, 10B, 10Y, 20Y Subpixel
10BKR, 10BKG Subpixel block
11 Circuit substrate
111 Substrate
112 Insulating layer
113 Pad
12B, 12G, 22BG1, 22BG2 Inorganic LED
13 Insulating layer
14R, 14G, 14Y1, 14Y2, 21Y, 23R Organic LED
15 Insulating layer
16 Protective layer
17 Substrate
18 Protective layer
19 Color filter
19M, 19C, 24M, 24Y filter unit
61, 62 Reflection layer
63 Wall portion
81G, 81R QLED
101, 102, 103, 104, 105, 106, 107, 108, 109, 110, 110a, 110b, 110c, 110d, 601, 602, 603, 604, 605, 606 Display device
121B, 121G First electrode
122B, 122G Inorganic layer
123B, 123G Second electrode
124B, 125B, 124G Via
141R, 141G First electrode
142R, 142G, 142Y Organic layer
143 Second electrode
144G, 144R, 145 Via
211Y First electrode
212Y Organic layer
213Y Second electrode
221 First electrode
222BG Inorganic layer
222B First compound semiconductor laminate
222G Second compound semiconductor laminate
223 Second electrode
231R First electrode
232R Organic layer
310 Digital still camera
320 Head-mounted display
330 Television device
340 See-through head-mounted display
360 Smartphone
500 Vehicle
233R Second electrode
631 First wall portion
632 Second wall portion
812G, 812R Quantum dot light emitting layer
RE1 Display region
RE2 Peripheral region

1. A display device comprising:
a plurality of inorganic light emitting diodes arranged two-dimensionally; and
a plurality of organic light emitting diodes arranged two-dimensionally, wherein
at least one of the organic light emitting diodes is provided on an upper portion of or above at least one of the inorganic light emitting diodes or on a lower portion of or below at least one of the inorganic light emitting diodes.

2. The display device according to claim 1, wherein
light emission colors of the inorganic light emitting diodes and the organic light emitting diodes are different.

3. The display device according to claim 1, wherein
at least two of the organic light emitting diodes are provided on an upper portion of or above one of the inorganic light emitting diodes or on a lower portion of or below one of the inorganic light emitting diodes.

4. The display device according to claim 1, wherein
a peak wavelength of emission light of the inorganic light emitting diodes is shorter than a peak wavelength of emission light of the organic light emitting diodes.

5. The display device according to claim 1, further comprising
a color conversion layer, wherein
the color conversion layer is capable of performing color conversion on light emitted from the plurality of organic light emitting diodes.

6. The display device according to claim 5, wherein
the color conversion layer can transmit light emitted from the plurality of inorganic light emitting diodes without color conversion.

7. The display device according to claim 5, wherein
the color conversion layer is a color filter or a dielectric multilayer film structure.

8. The display device according to claim 1, wherein
the plurality of organic light emitting diodes includes a plurality of first organic light emitting diodes and a plurality of second organic light emitting diodes,
one of the first organic light emitting diodes and one of the second organic light emitting diodes are provided on an upper portion of or above one of the inorganic light emitting diodes or on a lower portion of or below one of the inorganic light emitting diodes, and
the first organic light emitting diodes, the second organic light emitting diodes, and the inorganic light emitting diodes have different light emission colors.

9. The display device according to claim 8, further comprising
a color conversion layer, wherein
the color conversion layer includes a plurality of first color conversion units and a plurality of second color conversion units, and
the first color conversion units are capable of performing color conversion on light emitted from the first organic light emitting diodes, and
the second color conversion units are capable of performing color conversion on light emitted from the second organic light emitting diodes.

10. The display device according to claim 1, further comprising
a color conversion layer, wherein
the color conversion layer is capable of performing color conversion on light emitted from the plurality of organic light emitting diodes, and
the plurality of organic light emitting diodes share an organic layer including a light emitting layer.

11. The display device according to claim 1, wherein
the inorganic light emitting diodes are capable of emitting a first light having a first peak wavelength and a second light having a second peak wavelength, and
the organic light emitting diodes are capable of emitting a third light having a third peak wavelength.

12. The display device according to claim 1, wherein
the inorganic light emitting diode includes:
a first light emitting layer capable of emitting a first light having a first peak wavelength; and
a second light emitting layer capable of emitting a second light having a second peak wavelength.

13. The display device according to claim 11, wherein
at least two of the inorganic light emitting diodes are provided on an upper portion of or above one of the organic light emitting diodes or on a lower portion of or below one of the organic light emitting diodes.

14. The display device according to claim 11, further comprising
a color conversion layer, wherein
the color conversion layer is capable of performing color conversion on the first light and the second light emitted from the plurality of inorganic light emitting diodes.

15. The display device according to claim 14, wherein
the color conversion layer is capable of transmitting light emitted from the plurality of organic light emitting diodes without color conversion.

16. The display device according to claim 11, wherein
at least two of the inorganic light emitting diodes share one cathode.

17. The display device according to claim 1, wherein
the plurality of organic light emitting diodes share one cathode.

18. The display device according to claim 1, wherein
the plurality of inorganic light emitting diodes share one cathode.

19. The display device according to claim 1, wherein
the organic light emitting diodes and the inorganic light emitting diodes share a cathode or an anode.

20. The display device according to claim 1, wherein
the plurality of organic light emitting diodes includes a plurality of first organic light emitting diodes and a plurality of second organic light emitting diodes,
the first organic light emitting diodes included in adjacent pixels share one first light emitting layer, and
the second organic light emitting diodes included in adjacent pixels share one second light emitting layer.

21. The display device according to claim 1, further comprising
a color conversion layer including a plurality of color conversion units, wherein
adjacent pixels share one of the color conversion units.

22. The display device according to claim 1, further comprising
a first reflection layer, wherein
the first reflection layer is provided between the at least one inorganic light emitting diode and the at least one organic light emitting diode, and
the organic light emitting diode includes a first electrode, an organic light emitting layer, and a second electrode, and
the second electrode of the organic light emitting diode and the first reflection layer configure a first resonator structure that resonates light emitted from the organic light emitting diodes.

23. The display device according to claim 22, wherein
the inorganic light emitting diode includes a first electrode, an inorganic light emitting layer, and a second electrode,
the first electrode of the inorganic light emitting diode and the first reflection layer configure a second resonator structure that resonates light emitted from the inorganic light emitting diode.

24. The display device according to claim 22, wherein
the first reflection layer includes a dielectric multilayer film, a metal layer, or a laminate thereof.

25. The display device according to claim 22, further comprising
a second reflection layer, wherein
the second reflection layer is provided on an upper portion or above a light emitting diode provided on an upper side of the organic light emitting diode and the inorganic light emitting diode, and
the second reflection layer includes a dielectric multilayer film, a metal layer, or a laminate thereof.

26. The display device according to claim 1, further comprising
a wall portion provided between the pixels or between the subpixels, wherein
the wall portion is configured to be capable of reflecting or refracting light.

27. The display device according to claim 26, further comprising
a drive substrate, wherein
the wall portion also serves as a connection member that connects an upper side light emitting diode of the organic light emitting diode or the inorganic light emitting diode to the drive substrate.

28. A display device comprising:
a plurality of first light emitting diodes arranged two-dimensionally; and
a plurality of second light emitting diodes arranged two-dimensionally, wherein
the plurality of first light emitting diodes includes a plurality of inorganic light emitting diodes, the plurality of second light emitting diodes include at least one type of a plurality of organic light emitting diodes, a plurality of quantum dot light emitting diodes, and a plurality of perovskite light emitting diodes, and
at least one of the second light emitting diodes is provided on an upper portion of or above at least one of the first light emitting diodes, or on a lower portion of or below at least one of the first light emitting diodes.

29. A display device comprising:
a plurality of first light emitting diodes arranged two-dimensionally;
a plurality of second light emitting diodes arranged two-dimensionally; and
a plurality of third light emitting diodes arranged two-dimensionally, wherein
the second light emitting diodes are provided on an upper portion of or above the first light emitting diodes,
the third light emitting diodes are provided on an upper portion of or above the second light emitting diodes, and
at least one kind of light emitting diodes among three kinds of light emitting diodes including the first light emitting diodes, the second light emitting diodes, and the third light emitting diodes are inorganic light emitting diodes, and the remaining light emitting diodes among the three kinds of light emitting diodes are at least one kind of organic light emitting diodes, quantum dot light emitting diodes, and perovskite light emitting diodes.

30. An electronic apparatus comprising the display device according to claim 1.
